(19) United States
(12) Patent Application Publication
(10) Pub. No.: US 2020/0105883 A1
(43) Pub. Date: Apr. 2, 2020

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Naoto YAMADE, Isehara, Kanagawa (JP); Hiroshi FUJIKI, Kudamatsu, Yamaguchi (JP); Tsutomu MURAKAWA, Isehara, Kanagawa (JP); Toshihiko TAKEUCHI, Atsugi, Kanagawa (JP)

(73) Assignee: SEMICONDUCTOR ENERGY LABORATORY CO., LTD., ATSUGI-SHI, KANAGAWA-KEN (JP)

(21) Appl. No.: 16/497,832

(22) PCT Filed: Mar. 20, 2018
(86) PCT No.: PCT/IB2018/051840

§ 371 Date: Sep. 26, 2019

(30) Foreign Application Priority Data
Mar. 31, 2017 (JP) 2017-071683
Mar. 31, 2017 (JP) 2017-071861

(51) Int. Cl. H01L 29/26; H01L 27/108

(52) U.S. Cl. CPC H01L 29/26; H01L 27/10855; H01L 27/10873; H01L 27/10805

(57) ABSTRACT

A highly integrated semiconductor device is provided.

The semiconductor device includes an oxide semiconductor including a first region, a second region, a third region adjacent to the first region and the second region, and a fourth region adjacent to the second region; a first insulator over the oxide semiconductor; a first conductor over the first insulator; a second insulator over the oxide semiconductor, the first insulator, and the first conductor; a third insulator provided to overlap with a side surface of the first insulator and a side surface of the first conductor with the second insulator therebetween; a fourth insulator over the second insulator and the third insulator; and a second conductor in contact with the oxide semiconductor. The first region is in contact with the first insulator and overlaps with the third insulator with the first insulator and the conductor therebetween; the second region is in contact with the second insulator and overlaps with the third insulator with the second insulator therebetween; the third region is in contact with the second insulator and overlaps with the third insulator with the second insulator and the third insulator therebetween; and the fourth region is in contact with the second conductor.

### TECHNICAL FIELD

One embodiment of the present invention relates to a semiconductor device and a method for fabricating the semiconductor device. Another embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another one embodiment of the present invention relates to a process, a machine, manufacture, or a composition of matter.

### BACKGROUND ART

In recent years, semiconductor devices have been developed and an LSI, a CPU, or a memory are widely used. A CPU is an aggregation of semiconductor elements in which an electrode which is a connection terminal is formed, which includes a semiconductor integrated circuit (including at least a transistor and a memory) separated from a semiconductor wafer.

A semiconductor circuit (IC chip) of an LSI, a CPU, a memory, or the like is mounted on a circuit board, for example, a printed wiring board, to be used as one of components of a variety of electronic devices.

In addition, a technique for forming a transistor by using a semiconductor thin film formed over a substrate having an insulating surface has attracted attention. The transistor is used in a wide range of electronic devices such as an integrated circuit (IC) and an image display device (also simply referred to as a display device). A silicon-based semiconductor material is widely known as a material for a semiconductor thin film that can be used in a transistor, and as another material, an oxide semiconductor has attracted attention.

It is known that a transistor using an oxide semiconductor has an extremely low leakage current in a non-conduction state. For example, a low-power-consumption CPU utilizing a characteristic of low leakage current of the transistor that uses an oxide semiconductor is disclosed (see Patent Document 1).

In addition, a technique in which oxide semiconductor layers with different electron affinities (or conduction band minimum states) are stacked to increase the carrier mobility of a transistor is disclosed (see Patent Document 2 and Patent Document 3).

In recent years, demand for an integrated circuit in which transistors and the like are integrated with high density has risen with reductions in the size and weight of an electronic device. Furthermore, the productivity of a semiconductor device including an integrated circuit is required to be improved.

In addition, a silicon-based semiconductor material is widely known as a material for a semiconductor thin film that can be used in a transistor, and as another material, an oxide semiconductor has attracted attention. As the oxide semiconductor, not only single-component metal oxides, such as indium oxide and zinc oxide, but also multi-component metal oxides are known. Among the multi-component metal oxides, in particular, an In—Ga—Zn oxide (hereinafter also referred to as IGZO) has been actively studied.

From the studies on IGZO, a CAAC (c-axis aligned crystalline) structure and an nc (nanocrystalline) structure, which are not single crystal nor amorphous, have been found in an oxide semiconductor (see Non-Patent Document 1 to Non-Patent Document 3). In Non-Patent Document 1 and Non-Patent Document 2, a technique for fabricating a transistor using an oxide semiconductor having a CAAC structure is also disclosed. Moreover, Non-Patent Document 4 and Non-Patent Document 5 show that a fine crystal is included even in an oxide semiconductor which has lower crystallinity than an oxide semiconductor having the CAAC structure or the nc structure.

In addition, a transistor that uses IGZO for an active layer has an extremely low off-state current (see Non-Patent Document 6), and an LSI and a display utilizing the characteristics have been reported (see Non-Patent Document 7 and Non-Patent Document 8).

### PRIOR ART DOCUMENTS

### Patent Documents

[Patent Document 1] Japanese Published Patent Application No. 2012-257187
[Patent Document 2] Japanese Published Patent Application No. 2011-124360
[Patent Document 3] Japanese Published Patent Application No. 2011-138934

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.
[Non-Patent Document 3] S. Ito et al., “The Proceedings of AM-FPD'13 Digest of Technical Papers”, 2013, pp. 151-154.
[Non-Patent Document 4] S. Yamazaki et al., “ECS Journal of Solid State Science and Technology”, 2014, volume 3, issue 9, pp. Q3012-Q3022.
[Non-Patent Document 5] S. Yamazaki, “ECS Transactions”, 2014, volume 64, issue 10, pp. 155-164.
[Non-Patent Document 6] K. Kato et al., “Japanese Journal of Applied Physics”, 2012, volume 51, pp. 021201-1-021201-7.
[Non-Patent Document 7] S. Matsuda et al., “2015 Symposium on VLSI Technology Digest of Technical Papers”, 2015, pp. T216-T217.
[Non-Patent Document 8] S. Amano et al., “SID Symposium Digest of Technical Papers”, 2010, volume 41, issue 1, pp. 626-629.

### SUMMARY OF THE INVENTION

### Problems to be Solved by the Invention

An object of one embodiment of the present invention is to provide a semiconductor device having favorable electrical characteristics. An object of one embodiment of the present invention is to provide a semiconductor device that can be miniaturized or highly integrated. An object of one embodiment of the present invention is to provide a semiconductor device with high productivity.

An object of one embodiment of the present invention is to provide a semiconductor device capable of retaining data for a long time. An object of one embodiment of the present invention is to provide a semiconductor device capable of high-speed data writing. An object of one embodiment of the present invention is to provide a semiconductor device with high design flexibility. An object of one embodiment of the present invention is to provide a semiconductor device in which power consumption can be reduced. An object of one embodiment of the present invention is to provide a novel semiconductor device.

Note that the descriptions of these objects do not disturb the existence of other objects. In one embodiment of the present invention, there is no need to achieve all the objects. Objects other than these will be apparent from and can be derived from the descriptions of the specification, the drawings, the claims, and the like.

### Means for Solving the Problems

One embodiment of the present invention is a semiconductor device including an oxide semiconductor including a first region, a second region, a third region adjacent to the first region and the second region, and a fourth region adjacent to the second region; a first insulator over the oxide semiconductor; a first conductor over the first insulator; a second insulator over the oxide semiconductor, the first insulator, and the first conductor; a third insulator provided to overlap with a side surface of the first insulator and a side surface of the first conductor with the second insulator therebetween; a fourth insulator over the second insulator and the third insulator; and a second conductor provided in contact with the oxide semiconductor. The first region is in contact with the first insulator and overlaps with the third insulator with the first insulator and the first conductor therebetween; the second region is in contact with the second insulator and overlaps with the third insulator with the second insulator therebetween; the third region is in contact with the second insulator and overlaps with the third insulator with the second insulator and the third insulator therebetween; the fourth region is in contact with the second conductor; the second insulator is a metal oxide; and the third insulator is a film containing hydrogen or nitrogen.

In the above embodiment, the second insulator may be aluminum oxide.

In the above embodiment, the fourth insulator may be silicon nitride.

In the above embodiment, in the second insulator, a film thickness in a region overlapping with the second region may be smaller than a film thickness in a region overlapping with the third region.

In the above embodiment, the film thickness of the second insulator in the region overlapping with the third region may be greater than or equal to 3.0 nm and the film thickness of the second insulator in the region overlapping with the second region may be less than or equal to 3.0 nm.

One embodiment of the present invention is a semiconductor including a first transistor including a first oxide semiconductor including a first region, a second region, a third region adjacent to the first region and the second region, and a fourth region adjacent to the second region, a first insulator over the first oxide semiconductor, and a first conductor over the first insulator; a second transistor including a second oxide semiconductor including a fifth region, a sixth region, a seventh region adjacent to the fifth region and the sixth region, and an eighth region adjacent to the sixth region, a second insulator overlapping with the fifth region, and a second conductor over the second insulator; a third insulator over the first oxide semiconductor, the second oxide semiconductor, the first insulator, the second insulator, the first conductor, and the second conductor; a fourth insulator provided to overlap with a side surface of the first insulator and a side surface of the first conductor with the third insulator therebetween; a fifth insulator provided to overlap with a side surface of the second insulator and a side surface of the second conductor with the third insulator therebetween; and a sixth insulator over the third insulator, the fourth insulator, and the fifth insulator. The first region is in contact with the first insulator and overlaps with the third insulator with the first insulator and the first conductor therebetween; the second region and the sixth region are in contact with the third insulator and overlap with the sixth insulator with the third insulator therebetween; the third region is in contact with the third insulator and overlaps with the sixth insulator with the third insulator and the fourth insulator therebetween; the seventh region is in contact with the third insulator and overlaps with the sixth insulator with the third insulator and the fifth insulator therebetween; the fourth region is in contact with a third conductor; the eighth region is in contact with a fourth conductor; the fifth region includes a single-layer region; the third insulator is a metal oxide, and the sixth insulator is a film containing hydrogen or nitrogen.

In the above embodiment, the third insulator is aluminum oxide.

In the above embodiment, the sixth insulator is silicon nitride.

In the above embodiment, in the third insulator, a film thickness in regions overlapping with each of the second region and the sixth region is smaller than a film thickness in regions overlapping with each of the third region and the seventh region.

In the above embodiment, the film thickness of the third insulator in the regions overlapping with each of the third region and the seventh region is greater than or equal to 3.0 nm and the film thickness of the third insulator in the regions overlapping with each of the second region and the sixth region is less than or equal to 3.0 nm.

### Effect of the Invention

According to one embodiment of the present invention, a semiconductor device having favorable electrical characteristics can be provided. According to one embodiment of the present invention, a semiconductor device that can be miniaturized or highly integrated can be provided. According to one embodiment of the present invention, a semiconductor device with high productivity can be provided.

Alternatively, a semiconductor device capable of retaining data for a long time can be provided. Alternatively, a semiconductor device capable of high-speed data writing can be provided. Alternatively, a semiconductor device with high design flexibility can be provided. Alternatively, a semiconductor device in which power consumption can be reduced can be provided. Alternatively, a novel semiconductor device can be provided.

Note that the descriptions of these effects does not disturb the existence of other effects. Note that one embodiment of the present invention does not necessarily have all of these effects. Effects other than these will be apparent from and can be derived from the descriptions of the specification, the drawings, the claims, and the like.

### BRIEF DESCRIPTION OF DRAWINGS

FIG. 1 A top view and cross-sectional views of a semiconductor device of one embodiment of the present invention.

FIG. 2 A cross-sectional view of a semiconductor device of one embodiment of the present invention.

FIG. 3 A top view and cross-sectional views illustrating a method for fabricating a semiconductor device of one embodiment of the present invention.

FIG. 4 A top view and cross-sectional views illustrating a method for fabricating a semiconductor device of one embodiment of the present invention.

FIG. 5 A top view and cross-sectional views illustrating a method for fabricating a semiconductor device of one embodiment of the present invention.

FIG. 6 A top view and cross-sectional views illustrating a method for fabricating a semiconductor device of one embodiment of the present invention.

FIG. 7 A top view and cross-sectional views illustrating a method for fabricating a semiconductor device of one embodiment of the present invention.

FIG. 8 A top view and cross-sectional views illustrating a method for fabricating a semiconductor device of one embodiment of the present invention.

FIG. 9 A top view and cross-sectional views illustrating a method for fabricating a semiconductor device of one embodiment of the present invention.

FIG. 10 A top view and cross-sectional views illustrating a method for fabricating a semiconductor device of one embodiment of the present invention.

FIG. 11 A top view and cross-sectional views illustrating a method for fabricating a semiconductor device of one embodiment of the present invention.

FIG. 12 A top view and cross-sectional views illustrating a method for fabricating a semiconductor device of one embodiment of the present invention.

FIG. 13 A top view and cross-sectional views illustrating a method for fabricating a semiconductor device of one embodiment of the present invention.

FIG. 14 A top view and cross-sectional views of a semiconductor device of one embodiment of the present invention.

FIG. 15 A top view and cross-sectional views of a semiconductor device of one embodiment of the present invention.

FIG. 16 A top view and cross-sectional views of a semiconductor device of one embodiment of the present invention.

FIG. 17 A top view and cross-sectional views of a semiconductor device of one embodiment of the present invention.

FIG. 18 A top view and cross-sectional views of a semiconductor device of one embodiment of the present invention.

FIG. 19 A circuit diagram and a cross-sectional view of a semiconductor device of one embodiment of the present invention.

FIG. 20 A circuit diagram and a cross-sectional view of a semiconductor device of one embodiment of the present invention.

FIG. 21 A cross-sectional view illustrating a structure of a memory device of one embodiment of the present invention.

FIG. 22 A cross-sectional view illustrating a structure of a memory device of one embodiment of the present invention.

FIG. 23 A cross-sectional view illustrating a structure of a memory device of one embodiment of the present invention.

FIG. 24 A circuit diagram and a cross-sectional view illustrating a structure of a memory device of one embodiment of the present invention.

FIG. 25 A cross-sectional view of a semiconductor device of one embodiment of the present invention.

FIG. 26 A top view of a semiconductor device of one embodiment of the present invention.

FIG. 27 Cross-sectional views illustrating a method for fabricating a semiconductor device of one embodiment of the present invention.

FIG. 28 Cross-sectional views illustrating a method for fabricating a semiconductor device of one embodiment of the present invention.

FIG. 29 Cross-sectional views illustrating a method for fabricating a semiconductor device of one embodiment of the present invention.

FIG. 30 Cross-sectional views illustrating a method for fabricating a semiconductor device of one embodiment of the present invention.

FIG. 31 Cross-sectional views illustrating a method for fabricating a semiconductor device of one embodiment of the present invention.

FIG. 32 Cross-sectional views illustrating a method for fabricating a semiconductor device of one embodiment of the present invention.

FIG. 33 A circuit diagram and a cross-sectional view of a memory device of one embodiment of the present invention.

FIG. 34 Cross-sectional views of a semiconductor device of one embodiment of the present invention.

FIG. 35 A cross-sectional view of a memory device of one embodiment of the present invention.

FIG. 36 A cross-sectional view illustrating a structure of a memory device of one embodiment of the present invention.

FIG. 37 A block diagram illustrating a configuration example of a memory device of one embodiment of the present invention.

FIG. 38 Circuit diagrams illustrating a configuration example of a memory device of one embodiment of the present invention.

FIG. 39 A block diagram illustrating a configuration example of a memory device of one embodiment of the present invention.

FIG. 40 Block diagrams and a circuit diagram illustrating a configuration example of a memory device of one embodiment of the present invention.

FIG. 41 Block diagrams illustrating a configuration example of a semiconductor device of one embodiment of the present invention.

FIG. 42 A block diagram and a circuit diagram illustrating a configuration example of a semiconductor device of one embodiment of the present invention, and a timing chart showing an operation example of the semiconductor device.

FIG. 43 A block diagram illustrating a configuration example of a semiconductor device of one embodiment of the present invention.

FIG. 44 A circuit diagram illustrating a configuration example of a semiconductor device of one embodiment of the present invention and a timing chart showing an operation example of the semiconductor device.

FIG. 45 A block diagram illustrating a configuration example of an AI system of one embodiment of the present invention.

FIG. 46 Block diagrams each illustrating an application example of an AI system of one embodiment of the present invention.

FIG. 47 A perspective schematic view illustrating a structure example of an IC into which an AI system of one embodiment of the present invention is incorporated.

FIG. 48 Diagrams each illustrating an electronic device of one embodiment of the present invention.

FIG. 49 Photographs each showing a cross-sectional TEM image of Samples of Example.

### MODE FOR CARRYING OUT THE INVENTION

Hereinafter, embodiments will be described with reference to drawings. However, the embodiments can be implemented with many different modes, and it will be readily appreciated by those skilled in the art that modes and details thereof can be changed in various ways without departing from the spirit and scope thereof. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. Note that in drawings, the same reference numerals are used, in different drawings, for the same portions or portions having similar functions, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. Furthermore, the description of some hidden lines and the like might be omitted.

Note that in this specification and the like, the ordinal numbers such as first and second are used for convenience and do not denote the order of steps or the stacking order of layers. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In this specification, terms for describing arrangement, such as “over” and “under”, are used for convenience in describing a positional relationship between components with reference to drawings. Furthermore, the positional relationship between components is changed as appropriate in accordance with a direction in which each component is described. Thus, without limitation to terms described in this specification, the description can be changed appropriately depending on the situation.

In the case where there is an explicit description, X and Y are connected, in this specification and the like, for example, the case where X and Y are electrically connected, the case where X and Y are functionally connected, and the case where X and Y are directly connected are disclosed in this specification and the like. Accordingly, without being limited to a predetermined connection relationship, for example, a connection relation shown in drawings or texts, a connection relationship other than one shown in drawings or texts is included in the drawings or the texts.

Here, X and Y denote an object (e.g., a device, an element, a circuit, a wiring, an electrode, a terminal, a conductive film, or a layer).

An example of the case where X and Y are directly connected is the case where an element that allows electrical connection between X and Y (e.g., a switch, a transistor, a capacitor, an inductor, a resistor, a diode, a display element, a light-emitting element, or a load) is not connected between X and Y, and is the case where X and Y are connected without an element that allows electrical connection between X and Y (e.g., a switch, a transistor, a capacitor, an inductor, a resistor, a diode, a display element, a light-emitting element, or a load) placed therebetween.

In an example of the case where X and Y are electrically connected, at least one element that allows electrical connection between X and Y (e.g., a switch, a transistor, a capacitor, an inductor, a resistor, a diode, a display element, a light-emitting element, or a load) can be connected between X and Y. Note that a switch has a function of being controlled to be turned on or off. That is, a switch has a function of being in a conduction state (on state) or non-conduction state (off state) to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. Note that even if another circuit is sandwiched between X and Y, for example, X and Y are regarded as being functionally connected when a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Functions of a source and a drain might be switched when transistors having different polarities are employed or a direction of current is changed in circuit operation. Therefore, the terms “source” and “drain” is used interchangeably in this specification and the like in some cases.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

A channel width refers to, for example, the length of a portion where a source and a drain face each other in a region where a semiconductor (or a portion where current flows in a semiconductor when a transistor is in an on state) and a gate electrode overlap with each other, or a region where a channel is formed. Note that in one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter, referred to as an “effective channel width”) is different from a channel width shown in a top view of a transistor (hereinafter, referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in this specification, the simple term “channel width” refers to a surrounded channel width or an apparent channel width in some cases. Alternatively, in this specification, the simple term “channel width” refers to an effective channel width in some cases. Note that values of a channel length, a channel width, an effective channel width, an apparent channel width, a surrounded channel width, and the like can be determined, for example, by analyzing a cross-sectional TEM image and the like.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also functions as an impurity in some cases. In addition, in the case of an oxide semiconductor, oxygen vacancies are formed by entry of impurities, for example. Furthermore, in the case where the semiconductor is silicon, examples of an impurity which changes the characteristics of the semiconductor include oxygen, Group 1 elements except hydrogen, Group 2 elements, Group 13 elements, and Group 15 elements.

Note that in this specification and the like, “silicon oxynitride film” is a film in which oxygen content is higher than nitrogen content in its composition. A silicon oxynitride film preferably contains, for example, oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. Moreover, “silicon nitride oxide film” is a film in which nitrogen content is higher than oxygen content in its composition. A silicon nitride oxide film preferably contains nitrogen, oxygen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

Moreover, in this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In addition, in this specification and the like, the term “insulator” can be replaced with an insulating film or an insulating layer. Moreover, the term “conductor” can be replaced with a conductive film or a conductive layer. Furthermore, the term “semiconductor” can be replaced with a semiconductor film or a semiconductor layer.

Furthermore, unless otherwise specified, transistors described in this specification and the like are field-effect transistors. Furthermore, unless otherwise specified, transistors described in this specification and the like are n-channel transistors. Thus, unless otherwise specified, the threshold voltage (also referred to as “Vₜₕ”) is higher than 0 V.

In this specification and the like, “parallel” indicates a state where the angle formed between two straight lines is greater than or equal to −10° and less than or equal to 10°. Thus, the case where the angle is greater than or equal to −5° and less than or equal to 5° is also included. Furthermore, the term “substantially parallel” indicates a state where the angle formed between two straight lines is greater than or equal to −30° and less than or equal to 30°. Moreover, “perpendicular” indicates a state where the angle formed between two straight lines is greater than or equal to 80° and less than or equal to 100°. Thus, the case where the angle is greater than or equal to 85° and less than or equal to 95° is also included. In addition, “substantially perpendicular” indicates a state where the angle formed between two straight lines is greater than or equal to 60° and less than or equal to 120°.

Furthermore, in this specification, in the case where a crystal is a trigonal crystal or a rhombohedral crystal, the crystal is regarded as a hexagonal crystal system.

Note that in this specification, a barrier film means a film having a function of inhibiting the passage of oxygen and impurities such as hydrogen, and the barrier film having conductivity is referred to as a conductive barrier film in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in the case where an OS FET is stated, it can also be referred to as a transistor including an oxide or an oxide semiconductor.

### Embodiment 1

An example of a semiconductor device including a transistor 200 of one embodiment of the present invention will be described below.

### <Structure Example of Semiconductor Device>

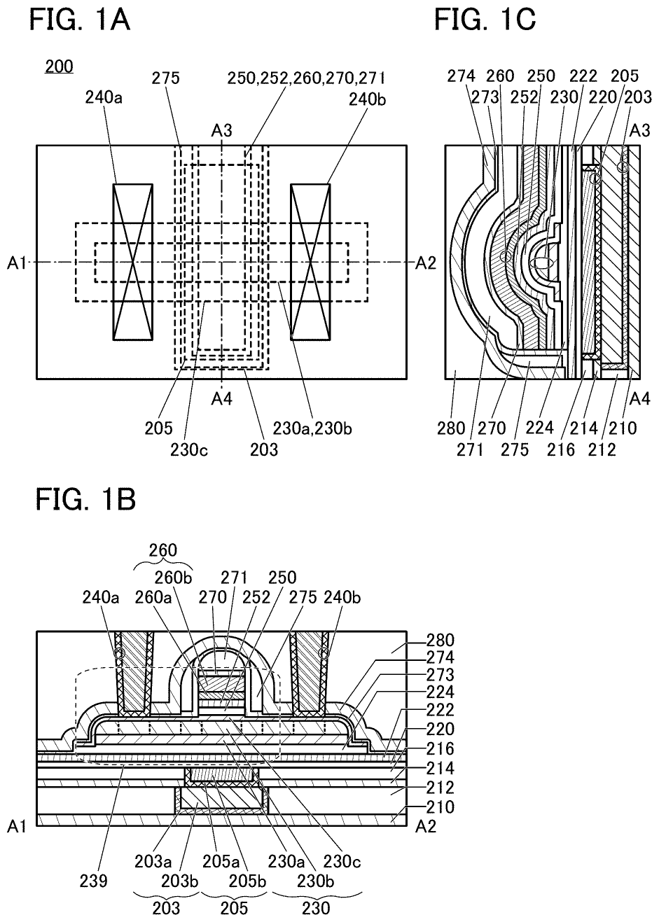

FIG. 1(A), FIG. 1(B), and FIG. 1(C) are a top view and cross-sectional views of the transistor 200 of one embodiment of the present invention and the periphery of the transistor 200.

FIG. 1(A) is a top view of the semiconductor device including the transistor 200. FIG. 1(B) and FIG. 1(C) are cross-sectional views of the semiconductor device. Here, FIG. 1(B) is a cross-sectional view of a portion indicated by a dashed-dotted line A1-A2 in FIG. 1(A), and is a cross-sectional view in the channel length direction of the transistor 200. FIG. 1(C) is a cross-sectional view of a portion indicated by a dashed-dotted line A3-A4 in FIG. 1(A), and is a cross-sectional view in the channel width direction of the transistor 200. For clarity of the drawing, some components are not illustrated in the top view of FIG. 1(A).

The semiconductor device of one embodiment of the present invention includes the transistor 200, and an insulator 210, an insulator 212, and an insulator 280 that function as interlayer films. The semiconductor device further includes a conductor 203 (a conductor 203a and a conductor 203b) functioning as a wiring and a conductor 240 (a conductor 240a and a conductor 240b) functioning as a plug, which are electrically connected to the transistor 200.

Note that in the conductor 203, the conductor 203a is formed in contact with an inner wall of an opening in the insulator 212, and the conductor 203b is formed on the inner side. Here, the level of the top surface of the conductor 203 and the level of the top surface of the insulator 212 can be substantially the same. Although the transistor 200 having a structure in which the conductor 203a and the conductor 203b are stacked is illustrated, the present invention is not limited thereto. For example, a structure in which only the conductor 203b is provided may be employed.

The conductor 240 is formed in contact with an inner wall of an opening of the insulator 280. Here, the level of the top surface of the conductor 240 and the level of the top surface of the insulator 280 can be substantially the same. Although a structure in which the conductor 240 of the transistor 200 is a single layer is illustrated, the present invention is not limited thereto. For example, the conductor 240 may have a stacked-layer structure of two or more layers.

### [Transistor 200]

As illustrated in FIG. 1, the transistor 200 includes an insulator 214 and an insulator 216 positioned over a substrate (not illustrated); a conductor 205 positioned to be embedded in the insulator 214 and the insulator 216; an insulator 220 positioned over the insulator 216 and the conductor 205; an insulator 222 positioned over the insulator 220; an insulator 224 positioned over the insulator 222; an oxide 230 (an oxide 230a, an oxide 230b, and an oxide 230c) positioned over the insulator 224; an insulator 250 positioned over the oxide 230; an insulator 252 positioned over the insulator 250; a conductor 260 (a conductor 260a and a conductor 260b) positioned over the insulator 252, an insulator 270 positioned over the conductor 260; an insulator 271 positioned over the insulator 270; an insulator 273 positioned in contact with at least the side surfaces of the insulator 250 and the conductor 260, and in contact with the oxide 230; an insulator 275 positioned to overlap with the side surface of the conductor 260 with the insulator 273 therebetween; and an insulator 274 positioned over the oxide 230 with the insulator 273 therebetween.

Although the transistor 200 has a structure in which the oxide 230a, the oxide 230b, and the oxide 230c are stacked, the present invention is not limited thereto. A structure may be employed in which a single-layer structure of the oxide 230b, a two-layer structure of the oxide 230b and the oxide 230a, a two-layer structure of the oxide 230b and the oxide 230c, or a stacked-layer structure of three or more layers is provided. Similarly, although the transistor 200 having a structure in which the conductor 260a and the conductor 260b are stacked is illustrated, the present invention is not limited thereto.

As the oxide 230, a metal oxide functioning as an oxide semiconductor (hereinafter also referred to as an oxide semiconductor) is preferably used.

For example, as the oxide 230, a metal oxide such as an In-M-Zn oxide (M is one or more selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used. Furthermore, as the oxide 230, an In—Ga oxide or an In—Zn oxide may be used.

When hydrogen or nitrogen is added to an oxide semiconductor, the carrier density is increased. Furthermore, hydrogen added to an oxide semiconductor reacts with oxygen bonded to a metal atom to be water, and thus forms an oxygen vacancy in some cases. Entry of hydrogen into the oxygen vacancy increases carrier density. Furthermore, in some cases, bonding of part of hydrogen to oxygen bonded to a metal atom causes generation of an electron serving as a carrier. That is, the oxide semiconductor to which nitrogen or hydrogen is added becomes n-type and has a reduced resistance.

Thus, when the resistance of the oxide 230 is selectively reduced, a region functioning as a semiconductor having a low carrier density and low-resistance regions functioning as a source region and a drain region can be provided in the oxide 230 which is processed into an island shape.

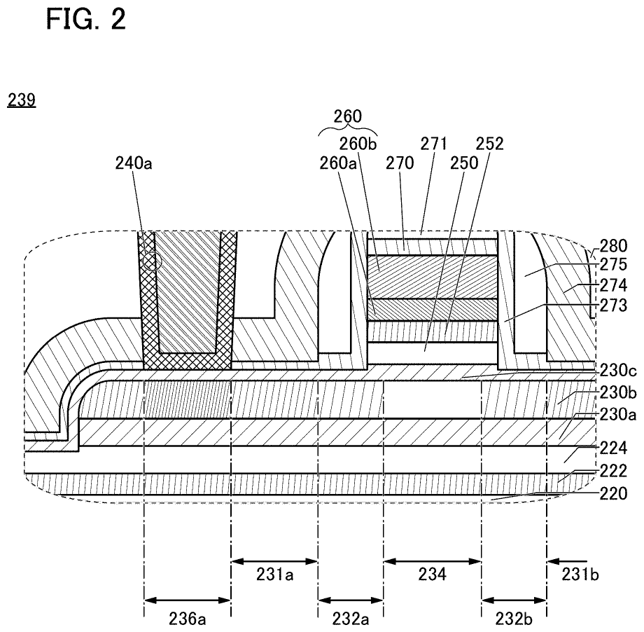

Here, FIG. 2 illustrates an enlarged view of a region 239 surrounded by a dashed line in FIG. 1(B).

As illustrated in FIG. 2, the oxide 230b includes a region 232 (a region 232a and a region 232b) between a region 234 functioning as a channel formation region of the transistor 200 and a region 231 (a region 231a and a region 231b) functioning as a source region and a drain region. In addition, a region 236 (a region 236a and a region 236b (the region 236b is a region overlapping with the conductor 240b and is not illustrated) overlapping with the conductor 240 may be included.

The region 231 functioning as the source region and the drain region is a region having a high carrier density and reduced resistance. The region 234 functioning as the channel formation region is a region having a lower carrier density than the region 231 functioning as the source region and the drain region. In addition, the region 232 is a region having a lower carrier density than the region 231 functioning as the source region and the drain region and a higher carrier density than the region 234 functioning as the channel formation region. That is, the region 232 has a function of a junction region between the channel formation region and the source region or the drain region. Note that the region 232 functions as an overlap region (also referred to as an Lov region) which overlaps with the conductor 260 functioning as a gate electrode.

When the junction region is provided, a high-resistance region is not formed between the region 231 functioning as the source region and the drain region and the region 234 functioning as the channel formation region, whereby on-state current of the transistor is increased.

The region 236 is a region having a higher carrier density and a lower resistance than 231. With the miniaturization of the transistor, the contact area between the oxide 230 and the conductor 240 is also reduced. When the resistance of the region 236 is reduced, a sufficient ohmic contact between the oxide 230 and the conductor 240 can be made.

Note that the region 236, the region 234, the region 231, and the region 232 are formed in the oxide 230b in FIG. 1 and FIG. 2; however, without being limited thereto, these regions may be formed in the oxide 230a and the oxide 230c, for example. Although boundaries between the regions are illustrated as being perpendicular to the top surface of the oxide 230 in FIG. 1 and FIG. 2, this embodiment is not limited thereto. For example, the region 232 may project to the conductor 260 side in the vicinity of the surface of the oxide 230b, and may recede to the conductor 240a side or the conductor 240b side in the vicinity of the bottom surface of the oxide 230a.

In order to selectively reduce the resistance of the oxide 230, at least one of an impurity and a metal element that increases conductivity such as indium is added to a desired region. Note that as the impurity, an element that forms an oxygen vacancy, an element trapped by an oxygen vacancy, or the like is used. Examples of the element include hydrogen, boron, carbon, nitrogen, fluorine, phosphorus, sulfur, chlorine, titanium, and a rare gas. In addition, typical examples of the rare gas element include helium, neon, argon, krypton, and xenon.

Thus, when the content percentage of the element that forms an oxygen vacancy or the element trapped by an oxygen vacancy in the region 231 is increased, the carrier density can be increased and the resistance can be reduced.

In order to reduce the resistance of the region 231, for example, a film containing hydrogen, nitrogen, or the like is preferably provided to be close to the region 231 functioning as the source region and the drain region of the oxide 230. The film containing hydrogen, nitrogen, or the like is preferably provided over the oxide 230 with at least the insulator 250, the insulator 252, the conductor 260, the insulator 273, the insulator 270, the insulator 271, and the insulator 275 therebetween.

When hydrogen or nitrogen is diffused into the region 231 of the oxide 230 from the film containing hydrogen, nitrogen, or the like, the resistance of the region 231 can be reduced. On the other hand, since the conductor 260 functioning as the gate electrode and the insulator 275 are provided between the film and the oxide 230, addition of hydrogen and nitrogen to the regions (the region 234 and the region 232) of the oxide 230 overlapping with the conductor 260 and the insulator 275 is inhibited.

Here, when excess hydrogen or nitrogen is added to the oxide 230 from the film containing hydrogen, nitrogen, or the like, the hydrogen or nitrogen is diffused into the region 234 functioning as the channel in some cases. That is, the resistance of the region originally designed as the channel formation region is also reduced, which causes a problem of electrical connection between the source region and the drain region. Moreover, by the treatment for adding impurities, thermal budget through the following process, and the like, impurities such as hydrogen and nitrogen contained in the region 231 are diffused into the region 234 in some cases.

When the region 232 is designed as appropriate, the impurities such as hydrogen and nitrogen can be inhibited from being diffused into the region 234.

For example, as illustrated in FIG. 1 and FIG. 2, the insulator 275 is preferably provided on the side surface of the conductor 260 functioning as the gate electrode. When the insulator 274 is provided as the film containing hydrogen, nitrogen, or the like with the insulator 275 therebetween, hydrogen and nitrogen are inhibited from being added to the region (the region 232) overlapping with the insulator 275. The region 232 is determined by the shape, thickness, width and the like of the insulator 275. Therefore, when the insulator 275 is designed as appropriate, the region 232 to which hydrogen and nitrogen are diffused can be adjusted, whereby the characteristics required for the transistor 200 can be obtained.

In order to inhibit the excess addition or diffusion of impurities, a structure may be employed in which the oxide 230 is not directly in contact with the film containing hydrogen, nitrogen or the like. For example, a film that inhibits diffusion of hydrogen or nitrogen is preferably provided between the oxide 230 and the film containing hydrogen, nitrogen, or the like. That is, the film that inhibits diffusion of hydrogen or nitrogen has a function of a buffer layer that inhibits excess diffusion of hydrogen or nitrogen.

In the case of the above structure, diffusion of impurities can be controlled by adjusting, as appropriate, the thickness of the film that inhibits diffusion of hydrogen or nitrogen and the thickness of the film containing hydrogen, nitrogen, or the like in accordance with the material.

Note that the film that inhibits diffusion of hydrogen or nitrogen and the film containing hydrogen, nitrogen, or the like are not necessarily removed. For example, when the film that inhibits diffusion of hydrogen or nitrogen and the film containing hydrogen, nitrogen, or the like remain, the films can function as interlayer films. Alternatively, only the film containing hydrogen, nitrogen, or the like may be removed.

For example, as illustrated in FIG. 1 and FIG. 2, the film that inhibits diffusion of hydrogen or nitrogen is preferably provided as the insulator 273 between the oxide 230 and the insulator 274, which is the film containing hydrogen, nitrogen, or the like. When the insulator 274 is provided over the region 231 of the oxide 230 with the insulator 273 therebetween, excess addition of hydrogen or nitrogen to the region 234 of the oxide 230 can be prevented.

Moreover, the insulator 273 may also function as a side barrier for protecting the side surfaces of the gate electrode and the gate insulator. Note that in the case of having a function of a side barrier, the insulator 273 is provided to cover at least the side surface of the conductor 260, the side surface of the insulator 250, and a side surface of the insulator 252 as illustrated in FIG. 1 and FIG. 2. Thus, impurities such as water or hydrogen can be prevented from entering the oxide 230 through the conductor 260, the insulator 250, and the insulator 252.

In addition, it is also preferable that the side barrier inhibit diffusion of oxygen. When diffusion of oxygen is inhibited, oxidation of the conductor 260 can be inhibited.

Here, the film thickness for preventing diffusion of impurities as the side barrier and the film thickness for diffusing impurities enough for reducing the resistance of at least the region 231 are different in some cases. That is, the film thickness required for the insulator 273 is different between the region functioning as the side barrier and the region functioning as the buffer layer in some cases. Therefore, in the insulator 273, the film thickness in the region in contact with the insulator 274 is preferably larger than the film thickness in the region in contact with the side surface of the conductor 260, the side surface of the insulator 250, and the side surface of the insulator 252.

For example, it is preferable that the film thickness of the insulator 273 in the region in contact with the insulator 274 is smaller than the film thickness thereof in the region in contact with the side surface of the conductor 260, the side surface of the insulator 250, and the side surface of the insulator 252 as illustrated in FIG. 1 and FIG. 2 by removing part of the insulator 273 when the insulator 275 is formed.

Moreover, in the case where the insulator 222 is a film that inhibits diffusion of hydrogen or nitrogen, the insulator 273 is preferably in contact with the insulator 222 on the outer side than the oxide 230. When the insulator 222 and the insulator 273 are in contact with each other, the oxide 230 is sealed with the films that inhibit diffusion of hydrogen or nitrogen. Thus, excess entrance of impurities from structure bodies other than the insulator 274 can be prevented.

In addition, the region 232 is provided so that a high-resistance region is not formed between the region 231 functioning as the source region and the drain region and the region 234 functioning as the channel formation region. That is, it is preferable that the region 232 be provided from a region overlapping with the insulator 275 to a region that is on the same surface with the surface where the side surface of the conductor 260 and the insulator 273 is in contact with each other. Alternatively, the region 232 is preferably provided from the region overlapping with the insulator 275 to inner side of the region overlapping with the conductor 260.

A metal element or an impurity may be added to the oxide 230 using, for example, the insulator 250, the insulator 252, the conductor 260, the insulator 270, and the insulator 271 as masks. In other words, since the conductor 260 functioning as the gate electrode is used as a mask, addition of hydrogen and nitrogen only to the region (the region 234) of the oxide 230 that overlaps with the conductor 260 can be inhibited, whereby the boundary between the region 234 and the region 232 can be provided in a self-aligned manner.

After that, the insulator 273 and the insulator 275 are provided, and then the insulator 274 that is the film containing hydrogen, nitrogen, or the like is provided. Here, the resistance of the region overlapping with the insulator 275 is lower than that of the region 234 due to the treatment for adding an impurity for the formation of the region 234 using the conductor 260 functioning as the gate electrode as a mask. Therefore, the junction region (the region 232) having a higher carrier density than the region 234 and a lower carrier density than the region 231 is formed between the region 231 and the region 234.

By the treatment for adding an impurity using the conductor 260 as a mask, for example, the region 232 is formed in a step after the insulator 274 is provided, so that the region 232 can be surely provided even in the case where the thermal budget is not enough for diffusing the impurity. Note that due to the diffusion of the impurity, the region 232 may overlap with the conductor 260 functioning as the gate electrode. In that case, the region 232 functions as what is called an overlap region (also referred to as an Lov region).

Alternatively, after a film to be the insulator 273 is deposited, the impurity may be added through the film to be the insulator 273 by an ion doping method, for example. The film to be the insulator 273 is provided to cover the oxide 230, the insulator 250, the conductor 260, the insulator 270, and the insulator 271. Therefore, the impurity can be added while the insulator 250 and the insulator 252 functioning as gate insulators are protected by the insulator 273.

Note that as the method for adding an impurity and a metal element, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that the impurity and the metal element to be added may be referred to as an element, a dopant, an ion, a donor, an acceptor, or the like.

Alternatively, the impurity and the metal element may be added by plasma treatment. In that case, the plasma treatment is performed with a plasma CVD apparatus, a dry etching apparatus, or an ashing apparatus, so that the impurity and the metal element can be added. Note that a plurality of the above-described treatments may be combined.

When the impurity is added with the combination of the above structures or the above steps, the region 232 can be provided in a self-aligned manner even in a miniaturized transistor whose channel length is approximately 10 nm to 30 nm.

When the region 232 is provided in the transistor 200, a high-resistance region is not formed between the region 231 functioning as the source region and the drain region and the region 234 where a channel is formed, so that the on-state current and the mobility of the transistor can be increased. Moreover, since the gate does not overlap with the source region and the drain region in the channel length direction owing to the region 232, formation of unnecessary capacitance can be inhibited. Furthermore, leakage current in a non-conduction state can be reduced owing to the region 232.

In addition, the region 236 preferably has a lower resistance than the region 231. When the resistance of the region 236 is reduced, a sufficient ohmic contact between the oxide 230 and the conductor 240 can be made.

When the content percentage of the element that forms an oxygen vacancy or the element trapped by an oxygen vacancy in the region 236 is increased, the carrier density can be increased and the resistance can be reduced. Furthermore, when a metal element such as indium is added to the region 236 to increase the content percentage of the metal element such as indium therein, the electron mobility can be increased and the resistance can be reduced. Note that in the case of adding indium, atomic ratio of indium to the element M at least in the region 236 is higher than the atomic ratio of indium to the element M in the region 234.

In order to reduce the resistance of the region 236, it is preferable that an opening in which the oxide 230 is exposed be provided in the insulator 280, the insulator 274, and the insulator 273, and an impurity or a metal element be added using the insulator 280, the insulator 274, and the insulator 273 as masks.

With the above-described structures and the above-described steps, the region 236 can be provided in a self-aligned manner even in a miniaturized transistor whose channel length is approximately 10 nm to 30 nm.

In the transistor 200 provided with the region 236, a sufficient ohmic contact between the oxide 230 and the conductor 240 can be made, whereby the on-state current and the mobility of the transistor can be increased.

When the above-described structures or the above-described steps are combined, the resistance of the oxide 230 can be selectively reduced.

That is, when an impurity is added using the conductor 260 functioning as the gate electrode or the insulator 275 as a mask, the resistance of the oxide 230 is reduced in a self-aligned manner. Therefore, when the plurality of transistors 200 are formed simultaneously, variations in electrical characteristics between the transistors can be reduced. The channel length of the transistor 200 is determined by the width of the conductor 260 and the insulator 275, and the transistor 200 can be miniaturized when the width of the conductor 260 is the minimum feature size.

Thus, by appropriately selecting the areas of the regions, a transistor having electrical characteristics that meet the demand for the circuit design can be easily provided.

In addition, when the resistance of the oxide 230 is selectively reduced to form the channel formation region, the source region, the drain region, and the like in a self-aligned manner, a separate step of forming a source electrode and a drain electrode using a metal material and the like is unnecessary. Thus, the cost can be reduced or the process can be shortened.

Moreover, an oxide semiconductor can be deposited by a sputtering method or the like, and thus can be used for a transistor included in a highly integrated semiconductor device. Furthermore, a transistor using an oxide semiconductor has an extremely low leakage current (off-state current) in a non-conduction state; thus, a semiconductor device with low power consumption can be provided.

Accordingly, a semiconductor device including a transistor including an oxide semiconductor and having a high on-state current can be provided. Alternatively, a semiconductor device including a transistor including an oxide semiconductor and having a low off-state current can be provided. Alternatively, a semiconductor device that has small variation in electrical characteristics, i.e., stable electrical characteristics, and has high reliability can be provided.

The structure of the semiconductor device including the transistor 200 of one embodiment of the present invention will be described in detail below.

The conductor 203 extends in the channel width direction as illustrated in FIG. 1(A) and FIG. 1(C) and functions as a wiring that applies a potential to the conductor 205. Note that the conductor 203 is preferably provided to be embedded in the insulator 214 and the insulator 216.

The conductor 205 is positioned to overlap with the oxide 230 and the conductor 260. Moreover, the conductor 205 is preferably provided over and in contact with the conductor 203.

Here, the conductor 260 functions as a first gate (also referred to as a top gate) electrode in some cases. The conductor 205 functions as a second gate (also referred to as a bottom gate) electrode in some cases. In that case, by changing a potential applied to the conductor 205 independently of a potential applied to the conductor 260, the threshold voltage of the transistor 200 can be controlled. In particular, by applying a negative potential to the conductor 205, the threshold voltage of the transistor 200 can be higher than 0 V, and the off-state current can be reduced. Accordingly, a drain current when a voltage applied to the conductor 260 is 0 V can be reduced.

Thus, when the conductor 205 is provided over the conductor 203, the distance between the conductor 203 and the conductor 260 functioning as the first gate electrode and the wiring can be designed as appropriate. That is, the insulator 214, the insulator 216, and the like are provided between the conductor 203 and the conductor 260, whereby a parasitic capacitance between the conductor 203 and the conductor 260 can be reduced, and the withstand voltage can be increased.

Moreover, the reduction in the parasitic capacitance between the conductor 203 and the conductor 260 can improve the switching speed of the transistor, so that the transistor can have high frequency characteristics. The increase in the withstand voltage between the conductor 203 and the conductor 260 can improve the reliability of the transistor 200. Therefore, the film thicknesses of the insulator 214 and the insulator 216 are preferably large. Note that the extending direction of the conductor 203 is not limited to this; for example, the conductor 203 may extend in the channel length direction of the transistor 200.

Note that as illustrated in FIG. 1(A), the conductor 205 is positioned to overlap with the oxide 230 and the conductor 260. In addition, the conductor 205 is preferably provided to be larger than the region 234 of the oxide 230. As illustrated in FIG. 1(C), it is particularly preferable that the conductor 205 extend to an outer region than an end portion of the region 234 of the oxide 230b in the channel width direction. That is, the conductor 205 and the conductor 260 preferably overlap with each other with the insulators therebetween on an outer side of the side surface of the oxide 230b in the channel width direction.

With the above structure, in the case where potentials are applied to the conductor 260 and the conductor 205, an electric field generated from the conductor 260 and an electric field generated from the conductor 205 are connected, so that a closed circuit in which the channel formation region formed in the oxide 230 is covered can be formed.

That is, the channel formation region in the region 234 can be electrically surrounded by the electric field of the conductor 260 functioning as the first gate electrode and the electric field of the conductor 205 functioning as the second gate electrode. In this specification, a transistor structure in which a channel formation region is electrically surrounded by electric fields of a first gate electrode and a second gate electrode is referred to as a surrounded channel (S-channel) structure.

In the conductor 205, the conductor 205a is formed in contact with an inner wall of the opening in the insulator 214 and the insulator 216, and the conductor 205b is formed on the inner side. Here, the levels of the top surfaces of the conductor 205a and the conductor 205b and the level of the top surface of the insulator 216 can be substantially the same. Although the transistor 200 has a structure in which the conductor 205a and the conductor 205b are stacked, the present invention is not limited thereto. For example, a structure in which only the conductor 205b is provided may be employed.

Here, for the conductor 205a and the conductor 203a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (or a conductive material through which the impurities are less likely to pass). Alternatively, it is preferable to use a conductive material having a function of inhibiting diffusion of oxygen (e.g., an oxygen atom or an oxygen molecule) (or a conductive material through which the oxygen is less likely to pass). Note that in this specification, a function of inhibiting diffusion of impurities or oxygen means a function of inhibiting diffusion of any one or all of the above impurities and the above oxygen.

When the conductor 205a and the conductor 203a have a function of inhibiting diffusion of oxygen, the conductivities of the conductor 205b and the conductor 203b can be prevented from being lowered because of oxidation. As a conductive material having a function of inhibiting diffusion of oxygen, for example, tantalum, tantalum nitride, ruthenium, ruthenium oxide, or the like is preferably used. Thus, a single layer or a stacked layer of the above conductive material is used for the conductor 205a and the conductor 203a. Thus, impurities such as water and hydrogen can be inhibited from being diffused to the transistor 200 side through the conductor 203 and the conductor 205.

Moreover, a conductive material containing tungsten, copper, or aluminum as its main component is preferably used for the conductor 205b. Note that the conductor 205b is illustrated as a single layer but may have a stacked-layer structure, for example, a stacked layer of any of the above conductive materials and titanium or titanium nitride.

As the conductor 203b functioning as a wiring, a conductor having a higher conductivity than the conductor 205b is preferably used. For example, a conductive material containing copper or aluminum as its main component can be used. In addition, the conductor 203b may have a stacked-layer structure, for example, a stacked layer of any of the above conductive materials and titanium or titanium nitride.

It is particularly preferable to use copper for the conductor 203b. Copper is preferably used for a wiring and the like because of its small resistance. However, copper is easily diffused, and thus may deteriorate the characteristics of the transistor 200 when diffused into the oxide 230. In view of the above, for example, a material through which copper is less likely to pass, such as aluminum oxide or hafnium oxide, is used for the insulator 214, whereby diffusion of copper can be inhibited.

Note that the conductor 205 is not necessarily provided. In that case, part of the conductor 203 can function as the second gate electrode.

Each of the insulator 210 and the insulator 214 preferably functions as a barrier insulating film that prevents an impurity such as water or hydrogen from entering the transistor from the substrate side. Accordingly, for the insulator 210 and the insulator 214, it is preferable to use an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (or an insulating material through which the above impurities are less likely to pass). Alternatively, it is preferable to use an insulating material having a function of inhibiting diffusion of oxygen (e.g., an oxygen atom or an oxygen molecule) (or an insulating material through which the oxygen is less likely to pass).

For example, it is preferable that aluminum oxide or the like be used for the insulator 210 and that silicon nitride or the like be used for the insulator 214. Accordingly, impurities such as water and hydrogen can be inhibited from being diffused to the transistor side from the substrate side through the insulator 210 and the insulator 214. Alternatively, oxygen contained in the insulator 224 or the like can be inhibited from being diffused to the substrate side through the insulator 210 and the insulator 214.

Furthermore, with the structure in which the conductor 205 is stacked over the conductor 203, the insulator 214 can be provided over the conductor 203. Here, even when a metal that is easily diffused, such as copper, is used for the conductor 203b, silicon nitride or the like provided as the insulator 214 can prevent diffusion of the metal to a layer above the insulator 214.

The permittivity of each of the insulator 212, the insulator 216, and the insulator 280 functioning as an interlayer film is preferably lower than that of the insulator 210 or the insulator 214. When a material with a low permittivity is used for an interlayer film, the parasitic capacitance generated between wirings can be reduced.

For example, a single layer or a stacked layer of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used as the insulator 212, the insulator 216, and the insulator 280. Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator of these may be subjected to nitriding treatment. Silicon oxide, silicon oxynitride, or silicon nitride may be stacked over the insulator.

The insulator 220, the insulator 222, and the insulator 224 each have a function of a gate insulator.

Here, as the insulator 224 in contact with the oxide 230, an oxide insulator that contains more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced and reliability can be improved.

As the insulator including an excess-oxygen region, specifically, an oxide material from which part of oxygen is released by heating is preferably used. An oxide that releases oxygen by heating is an oxide film in which the amount of released oxygen converted into oxygen molecules is greater than or equal to 1.0×10¹⁸ molecules/cm³, preferably greater than or equal to 1.0×10¹⁹ molecules/cm³, further preferably 2.0×10¹⁹ molecules/cm³ or greater than or equal to 3.0×10²⁰ molecules/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

In the case where the insulator 224 includes an excess-oxygen region, the insulator 222 preferably has a function of inhibiting diffusion of oxygen (e.g., an oxygen atom or an oxygen molecule) (or the insulator 222 is less likely to transmit oxygen).

When the insulator 222 has a function of inhibiting diffusion of oxygen, oxygen in the excess-oxygen region is not diffused to the insulator 220 side and thus can be supplied to the oxide 230 efficiently. Furthermore, the conductor 205 can be inhibited from reacting with oxygen from the excess-oxygen region included in the insulator 224.

For example, a single layer or a stacked layer of an insulator containing a what is called high-k material such as aluminum oxide, hafnium oxide, tantalum oxide, zirconium oxide, lead zirconate titanate (PZT), strontium titanate (SrTiO₃), or (Ba,Sr)TiO₃ (BST) is preferably used for the insulator 222. As miniaturization and high integration of a transistor progresses, a problem such as leakage current may arise because of a thinner gate insulator. When a high-k material is used for an insulator functioning as the gate insulator, a gate potential during operation of the transistor can be reduced while the physical thickness of the gate insulator is kept.

It is particularly preferable to use an insulator containing an oxide of one or both of aluminum and hafnium, which is an insulating material having a function of inhibiting diffusion of impurities, oxygen, and the like (or an insulating material through which the impurities and oxygen are less likely to pass). As the insulator containing an oxide of one or both of aluminum and hafnium, aluminum oxide, hafnium oxide, an oxide containing aluminum and hafnium (hafnium aluminate), or the like is preferably used. When formed using such a material, the insulator 222 functions as a layer that prevents release of oxygen from the oxide 230 and entry of impurities such as hydrogen from the periphery of the transistor 200 into the oxide 230.

Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator of these may be subjected to nitriding treatment. Silicon oxide, silicon oxynitride, or silicon nitride may be stacked over the insulator.

It is preferable that the insulator 220 be thermally stable. For example, when silicon oxide or silicon oxynitride, which is thermally stable, is combined with 222 an insulator of a high-k material, the stacked-layer structure can have thermal stability and a high dielectric material.

Note that the insulator 220, the insulator 222, and the insulator 224 may each have a stacked-layer structure of two or more layers. In that case, without limitation to a stacked-layer structure formed of the same material, a stacked-layer structure formed of different materials may be employed.

The oxide 230 includes the oxide 230a, the oxide 230b over the oxide 230a, and the oxide 230c over the oxide 230b. When the oxide 230b is included over the oxide 230a, impurities can be inhibited from being diffused into the oxide 230b from the structure bodies formed below the oxide 230a. Moreover, when the oxide 230b is included under the oxide 230c, impurities can be inhibited from being diffused into the oxide 230b from the structure bodies formed above the oxide 230c.

In addition, the oxide 230 preferably has a stacked-layer structure of oxides which differ in the atomic ratio of metal elements. Specifically, the atomic proportion of the element M in constituent elements in the metal oxide used as the oxide 230a is preferably greater than the atomic proportion of the element M in constituent elements in the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element M in the metal oxide used as the oxide 230a. A metal oxide that can be used as the oxide 230a or the oxide 230b can be used as the oxide 230c.

The energy of the conduction band minimum of each of the oxide 230a and the oxide 230c is preferably higher than the energy of the conduction band minimum of the oxide 230b. In other words, the electron affinity of each of the oxide 230a and the oxide 230c is preferably smaller than the electron affinity of the oxide 230b.

Here, the energy level of the conduction band minimum is gradually changes in the oxide 230a, the oxide 230b, and the oxide 230c. In other words, it can be said that the energy level of the conduction band minimum is continuously changes or continuously connected. To change the energy level gradually, the densities of defect states in mixed layers formed at an interface between the oxide 230a and the oxide 230b and an interface between the oxide 230b and the oxide 230c are preferably made low.

Specifically, when the oxide 230a and the oxide 230b or the oxide 230b and the oxide 230c contain the same element (as a main component) in addition to oxygen, a mixed layer with a low density of defect states can be formed. For example, in the case where the oxide 230b is an In—Ga—Zn oxide, an In—Ga—Zn oxide, a Ga—Zn oxide, gallium oxide, or the like is preferably used as the oxide 230a and the oxide 230c.

At this time, the oxide 230b serves as a main carrier path. Since the density of defect states at the interface between the oxide 230a and the oxide 230b and the interface between the oxide 230b and the oxide 230c can be made low, the influence of interface scattering on carrier conduction is small, and a high on-state current can be obtained.

The oxide 230 includes the region 231, the region 232, and the region 234. In addition, the region 236 may be included. Note that it is preferable that the region 231 at least partly overlap with the insulator 274 with the insulator 273 therebetween and have a higher concentration of at least one of impurities such as hydrogen and nitrogen than the region 234. It is also preferable that the concentration of at least one of impurities such as hydrogen and nitrogen in the region 232 be higher than that of region 234 and smaller than that of the region 231. It is also preferable that the region 236 be at least partly in contact with the conductor 240 and have a higher concentration of at least one of impurities such as hydrogen and nitrogen than the region 231.

That is, the region 231, the region 232, and the region 236 are each a region of the metal oxide provided as the oxide 230 to which impurities are added. Note that the region 231 has a higher conductivity than the region 234. In addition, the region 232 has a lower conductivity than the region 231 and a higher conductivity than the region 234. In addition, the region 236 has a higher conductivity than the region 231.

An oxide semiconductor to which an element that forms an oxygen vacancy or an element trapped by an oxygen vacancy is added has reduced resistance. Typical examples of such an element include hydrogen, boron, carbon, nitrogen, fluorine, phosphorus, sulfur, chlorine, titanium, and a rare gas. Typical examples of the rare gas element include helium, neon, argon, krypton, and xenon. Accordingly, the region 231, the region 232, and the region 236 may have a structure containing one or more of the above elements.

When the resistance of the region 232 of the transistor 200 is reduced, a high-resistance region is not formed between the region 231 functioning as the source region and the drain region and the region 234 where a channel is formed, so that the on-state current and the mobility of the transistor can be increased. Moreover, since the gate does not overlap with the source region and the drain region in the channel length direction owing to the region 232, formation of unnecessary capacitance can be inhibited. Furthermore, leakage current in a non-conduction state can be reduced owing to the region 232.

In addition, when the region 236 is provided in the transistor 200, a sufficient ohmic contact between the oxide 230 and the conductor 240 can be made, whereby the on-state current and the mobility of the transistor can be increased.

Thus, by appropriately selecting the areas of the regions, a transistor having electrical characteristics that meet the demand for the circuit design can be easily provided.

Thus, when the transistor 200 is turned on, the region 231a or the region 231b functions as the source region or the drain region. At least part of the region 234 functions as the region where a channel is formed. When the region 232 is provided between the region 231 and the region 234, the transistor 200 can have a high on-state current and a low leakage current (off-state current) in a non-conduction state.

There is a curved surface between the side surface of the oxide 230 and the top surface of the oxide 230. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm.

As the oxide 230, a metal oxide functioning as an oxide semiconductor (hereinafter also referred to as an oxide semiconductor) is preferably used. For example, as the metal oxide to be the region 234, it is preferable to use one having a band gap of 2 eV or more, preferably 2.5 eV or more. With the use of a metal oxide having such a wide band gap, the off-state current of the transistor can be reduced.

Note that in this specification and the like, a metal oxide containing nitrogen is also referred to as a metal oxide in some cases. Alternatively, a metal oxide containing nitrogen may be referred to as a metal oxynitride.

A transistor using an oxide semiconductor has an extremely low leakage current in a non-conduction state; thus, a semiconductor device with low power consumption can be provided. Moreover, an oxide semiconductor can be deposited by a sputtering method or the like, and thus can be used for a transistor included in a highly integrated semiconductor device.

As the oxide 230, a metal oxide such as an In-M-Zn oxide (the element M is one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) is preferably used. Alternatively, as the oxide 230, an In—Ga oxide or an In—Zn oxide may be used.

The insulator 250 functions as a gate insulator. The insulator 250 is preferably positioned in contact with the top surface of the oxide 230c. The insulator 250 is preferably formed using an insulator from which oxygen is released by heating. The insulator 250 is an oxide film of which the amount of released oxygen converted into oxygen molecules is greater than or equal to 1.0×10¹⁸ atoms/cm³, preferably greater than or equal to 1.0×10¹⁹ atoms/cm³, further preferably 2.0×10¹⁹ atoms/cm³ or 3.0×10²⁰ atoms/cm³ in thermal desorption spectroscopy (TDS analysis), for example. Note that the temperature of the film surface in the TDS analysis is preferably in a range of higher than or equal to 100° C. and lower than or equal to 700° C.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which have thermal stability, are preferable.

When an insulator from which oxygen is released by heating is provided as the insulator 250 in contact with the top surface of the oxide 230c, oxygen can be efficiently supplied to the region 234 of the oxide 230b. Furthermore, as in the insulator 224, the concentration of an impurity such as water or hydrogen in the insulator 250 is preferably reduced. The film thickness of the insulator 250 is preferably greater than or equal to 1 nm and less than or equal to 20 nm.

Furthermore, the insulator 252 preferably inhibits diffusion of oxygen in order to efficiently supply excess oxygen contained in the insulator 250 to the oxide 230. Provision of the insulator 252 that inhibits diffusion of oxygen inhibits diffusion of excess oxygen into the conductor 260. That is, reduction in the amount of excess oxygen that is supplied to the oxide 230 can be inhibited. Moreover, oxidization of the conductor 260 due to excess oxygen can be inhibited.

The insulator 250 and the insulator 252 have a function of part of the gate insulator in some cases. Therefore, when silicon oxide, silicon oxynitride, or the like is used for the insulator 250, a metal oxide that is a high-k material with a high dielectric constant is preferably used as the insulator 252. With such a stacked-layer structure, the stacked-layer structure can be thermally stable and have a high dielectric constant. Accordingly, a gate potential that is applied during operation of the transistor can be reduced while the physical thickness of the gate insulator is kept. In addition, the equivalent oxide thickness (EOT) of an insulator functioning as the gate insulator can be reduced.

With the above stacked-layer structure, on-state current can be increased without a reduction in the influence of the electric field from the conductor 260. Since the distance between the conductor 260 and the oxide 230 is kept by the physical thicknesses of the insulator 250 and the insulator 252, leakage current therebetween can be inhibited. Moreover, when the stacked-layer structure of the insulator 250 and the insulator 252 is provided, the physical distance between the conductor 260 and the oxide 230 and the electric field intensity applied from the conductor 260 to the oxide 230 can be easily adjusted as appropriate.

Specifically, a metal oxide containing one or more kinds selected from hafnium, aluminum, gallium, yttrium, zirconium, tungsten, titanium, tantalum, nickel, germanium, magnesium, and the like can be used as the insulator 252.

It is particularly preferable to use an insulator containing an oxide of one or both of aluminum and hafnium, for example, aluminum oxide, hafnium oxide, or an oxide containing aluminum and hafnium (hafnium aluminate). In particular, hafnium aluminate has higher heat resistance than a hafnium oxide film. Therefore, hafnium aluminate is preferable since it is less likely to be crystallized by a thermal budget through the following process.

The conductor 260 functioning as the first gate electrode includes the conductor 260a and the conductor 260b over the conductor 260a. It is preferable to use, for the conductor 260a, like the conductor 205a, a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom is preferably used. Alternatively, it is preferable to use a conductive material having a function of inhibiting diffusion of oxygen (e.g., an oxygen atom and an oxygen molecule).

When the conductor 260a has a function of inhibiting diffusion of oxygen, the conductivity of the conductor 260b can be prevented from being lowered because of oxidization due to excess oxygen contained in the insulator 250 and the insulator 252. As a conductive material having a function of inhibiting diffusion of oxygen, for example, tantalum, tantalum nitride, ruthenium, ruthenium oxide, or the like is preferably used.

As the conductor 260 functioning as a wiring, a conductor having high conductivity is preferably used. For example, a conductive material containing tungsten, copper, or aluminum as its main component is preferably used for the conductor 260b. The conductor 260b may have a stacked-layer structure, for example, a stacked layer of any of the above conductive materials and titanium or titanium nitride.

For example, a conductive oxide can be used for the conductor 260a. For example, the metal oxide that can be used as the oxide 230 is preferably used. In particular, an In—Ga—Zn-based oxide with an atomic ratio of [In]:[Ga]:[Zn]=4:2:3 to 4:2:4.1 or the vicinity thereof, which has high conductivity, is preferably used. When such a conductor 260a is provided, passage of oxygen to the conductor 260b can be inhibited, and an increase in electric resistance value of the conductor 260b due to oxidation can be prevented.

When such a conductive oxide is deposited by a sputtering method, oxygen can be added to the insulator 250 and the insulator 252, so that the oxygen can be supplied to the region 234 of the oxide 230. Thus, oxygen vacancies in the region 234 of the oxide 230 can be reduced.

In the case where the above conductive oxide is used as the conductor 260a, it is preferable to use, as the conductor 260b, a conductor that can add an impurity such as nitrogen to the conductor 260a to increase the conductivity of the conductor 260a. For example, titanium nitride or the like is preferably used for the conductor 260b. Alternatively, the conductor 260b may have a structure in which a metal such as tungsten is stacked over a metal nitride such as titanium nitride.

In the case where the conductor 205 extends to an outer region than the end portion of the oxide 230b in the channel width direction as illustrated in FIG. 1(C), the conductor 260 preferably overlaps with the conductor 205 with the insulator 250 therebetween in the region. That is, a stacked-layer structure of the conductor 205, the insulator 250, and the conductor 260 is preferably formed outside the side surface of the oxide 230b.

With the above structure, in the case where potentials are applied to the conductor 260 and the conductor 205, an electric field generated from the conductor 260 and an electric field generated from the conductor 205 are connected, so that a closed circuit which covers the channel formation region formed in the oxide 230 can be formed

That is, the channel formation region in the region 234 can be electrically surrounded by the electric field of the conductor 260 functioning as the first gate electrode and the electric field of the conductor 205 functioning as the second gate electrode.

Furthermore, the insulator 270 functioning as a barrier film may be positioned over the conductor 260b. For the insulator 270, an insulating material having a function of inhibiting the passage of oxygen and an impurity such as water or hydrogen is preferably used. For example, aluminum oxide or hafnium oxide is preferably used. Thus, oxidation of the conductor 260 can be prevented. Moreover, this can prevent entry of an impurity such as water or hydrogen into the oxide 230 through the conductor 260 and the insulator 250.

Furthermore, the insulator 271 functioning as a hard mask is preferably positioned over the insulator 270. When the insulator 271 is provided, the conductor 260 can be processed to have the side surface that is substantially perpendicular to the surface of the substrate; specifically, an angle formed by the side surface of the conductor 260 and the surface of the substrate can be greater than or equal to 75° and less than or equal to 100°, preferably greater than or equal to 80° and less than or equal to 95°. When the conductor is processed into such a shape, the insulator 273 that is subsequently formed can be formed into a desired shape.

Note that an insulating material having a function of inhibiting the passage of oxygen and an impurity such as water or hydrogen may be used for the insulator 271, so that the insulator 271 also functions as a barrier film. In that case, the insulator 270 is not necessarily provided.

The insulator 273 functioning as a barrier film and a buffer layer is provided in contact with the top surface and the side surface of the oxide 230, the side surface of the insulator 250, the side surface of the insulator 252, the side surface of the conductor 260, and the side surface of the insulator 270. In addition, it is preferable that the film thickness of the insulator 273 in a region in contact with the top surface and the side surface of the oxide 230 be smaller than the film thickness in a region in contact with the side surface of the insulator 250, the side surface of the insulator 252, the side surface of the conductor 260, and the side surface of the insulator 270.

Here, for the insulator 273, an insulating material having a function of inhibiting the passage of oxygen and an impurity such as water or hydrogen is preferably used. For example, aluminum oxide or hafnium oxide is preferably used. Accordingly, oxygen in the insulator 250 and the insulator 252 can be prevented from being diffused outward. In addition, impurities such as hydrogen and water can be prevented from entering the oxide 230 through the end portions and the like of the insulator 250 and the insulator 252. Thus, the formation of oxygen vacancies at the interface between the oxide 230 and the insulator 250 can be inhibited, leading to an improvement in the reliability of the transistor 200.

When the insulator 273 is provided, the side surface of the conductor 260, the side surface of the insulator 250, and the side surface of the insulator 252 can be covered with an insulator having a function of inhibiting the passage of oxygen and an impurity such as water or hydrogen. This can prevent entry of an impurity such as water or hydrogen into the oxide 230 through the conductor 260, the insulator 250, and the insulator 252. Thus, the insulator 273 has a function of a side barrier for protecting the side surfaces of the gate electrode and the gate insulator.

The insulator 275 is provided to overlap with the side surfaces of the conductor 260, the insulator 252, and the insulator 250 with the insulator 273 therebetween. In the case where the transistor is formed to have a designed channel length of 10 nm or more and 30 nm or less with the miniaturization of the transistor, for example, it is highly probable that impurity elements contained in the region 231 are diffused into the region 234, and accordingly the region 231a and the region 231b are electrically connected to each other. When the insulator 275 is provided, the distance between the region 231a and the region 231b can be maintained, which can prevent the source region and the drain region from being electrically connected to each other when a first gate potential is 0 V. In other words, when the region 232 is provided in a region of the oxide 230 overlapping with the insulator 275, diffusion of excess hydrogen or nitrogen in the region 231 into the region 234 can be prevented.

In the case where the insulator 224 is processed into an island shape, a structure may be employed in which the insulator 222 and the insulator 273 are in contact with each other on the outer side than the insulator 224. With the structure, the oxide 230 is sealed with the film that inhibits diffusion of hydrogen or nitrogen. Thus, unintended entrance of excess impurities from a structure body other than the insulator 274 can be prevented.

The insulator 274 is provided at least over the region 231 of the oxide 230 with the insulator 273 therebetween. When the insulator 274 is provided over the region 231 of the oxide 230 with the insulator 273 therebetween, addition of excess hydrogen or nitrogen to the region 234 of the oxide 230 can be prevented.

Therefore, the film thickness of the insulator 274 and the film thickness of the insulator 273 in the region in contact with the top surface and the side surface of the oxide 230 are preferably adjusted as appropriate depending on the material used. For example, as the insulator 273, a metal oxide containing one or more kinds selected from hafnium, aluminum, gallium, yttrium, zirconium, tungsten, titanium, tantalum, nickel, germanium, magnesium, and the like can be used.

In particular, aluminum oxide has a high barrier property, so that even a thin aluminum oxide film having a thickness of greater than or equal to 0.5 nm and less than or equal to 3.0 nm can inhibit diffusion of hydrogen and nitrogen. Although hafnium oxide has a lower barrier property than aluminum oxide, the barrier property can be increased with an increase in the film thickness. Therefore, the appropriate addition amount of hydrogen and nitrogen can be adjusted by adjustment of the film thickness of hafnium oxide.

Thus, it is preferable that, in the case where aluminum oxide is used for the insulator 273, the film thickness in the region in contact with the side surface of the insulator 250, the side surface of the insulator 252, the side surface of the conductor 260, and the side surface of the insulator 270 be greater than or equal to 0.5 nm, preferably greater than or equal to 3.0 nm. Meanwhile, the film thickness of the insulator 273 in the region in contact with the top surface and the side surface of the oxide 230 is preferably less than or equal to 3.0 nm.

For example, an insulator containing nitrogen can be used as the insulator 274. For example, silicon nitride, silicon nitride oxide, silicon oxynitride, aluminum nitride, aluminum nitride oxide, or the like is preferably used. In particular, a silicon nitride film can release hydrogen in the silicon nitride film during the deposition of the silicon nitride film or by a thermal budget through the following process.

The insulator 280 functioning as an interlayer film is preferably provided over the insulator 274. As in the insulator 224 or the like, the concentration of an impurity such as water or hydrogen in the film of the insulator 280 is preferably reduced. Note that an insulator similar to the insulator 210 may be provided over the insulator 280.

The conductor 240a and the conductor 240b are positioned in the openings formed in the insulator 280 and the insulator 274. The conductor 240a and the conductor 240b are positioned to face each other with the conductor 260 sandwiched therebetween. Note that the level of the top surfaces of the conductor 240a and the conductor 240b and the level of the top surface of the insulator 280 may be substantially the same.

The conductor 240a is in contact with the region 236a functioning as one of the source region and the drain region of the transistor 200, and the conductor 240b is in contact with the region 236b functioning as the other of the source region and the drain region of the transistor 200. Thus, the conductor 240a can function as one of a source electrode and a drain electrode, and the conductor 240b can function as the other of the source electrode and the drain electrode.

Since the region 236a and the region 236b are reduced in resistance, the contact resistance between the conductor 240a and the region 231a and the contact resistance between the conductor 240b and the region 231b are reduced, whereby on-state current of the transistor 200 can be increased.

The conductor 240a is formed in contact with the inner wall of the opening in the insulator 280 and the insulator 274. The region 236a of the oxide 230 is positioned on at least part of the bottom of the opening, and thus the conductor 240a is in contact with the region 236a. Similarly, the conductor 240b is formed in contact with the inner wall of the opening in the insulator 280 and the insulator 274. At least part of the region 236b of the oxide 230 is positioned at the bottom of the opening, and thus the conductor 240b is in contact with the region 236b.

Here, the conductor 240a and the conductor 240b are in contact with at least the top surface of the oxide 230, preferably further in contact with the side surface of the oxide 230. It is particularly preferable that the conductor 240a and the conductor 240b be in contact with one or both of the side surface of the oxide 230 on the A3 side and the side surface thereof on the A4 side, which intersect with the channel width direction of the oxide 230. Alternatively, a structure may be employed in which the conductor 240a and the conductor 240b are in contact with the side surface on the A1 side (the A2 side), which intersects with the channel length direction of the oxide 230. When a structure is employed in which the conductor 240a and the conductor 240b are in contact with not only the top surface of the oxide 230 but also the side surface of the oxide 230, the areas of the contact portions between the oxide 230 and each of the conductor 240a and the conductor 240b can be increased without an increase in the area of the top surface of the contact portion, so that the contact resistances between the oxide 230 and each of the conductor 240a and the conductor 240b can be reduced. Accordingly, miniaturization of the source electrode and the drain electrode of the transistor can be achieved and the on-state current can be increased.

For the conductor 240a and the conductor 240b, a conductive material containing tungsten, copper, or aluminum as its main component is preferably used. Although not illustrated, the conductor 240a and the conductor 240b may have a stacked-layer structure, for example, a stacked-layer of any of the above conductive materials and titanium or titanium nitride.

In the case where the conductor 240 has a stacked-layer structure, a conductive material having a function of inhibiting the passage of an impurity such as water or hydrogen is preferably used for a conductor in contact with the insulator 274 and the insulator 280, as in the conductor 205a or the like. For example, tantalum, tantalum nitride, titanium, titanium nitride, ruthenium, ruthenium oxide, or the like is preferably used. A single layer or a stacked layer of the conductive material having a function of inhibiting the passage of an impurity such as water or hydrogen may be used. With the use of the conductive material, an impurity such as water or hydrogen can be inhibited from entering the oxide 230 through the conductor 240a and the conductor 240b from a layer above the insulator 280.

Although not illustrated, a conductor functioning as a wiring may be positioned in contact with the top surface of the conductor 240a and the top surface of the conductor 240b.

For the conductor functioning as a wiring, a conductive material containing tungsten, copper, or aluminum as its main component is preferably used. The conductor may have a stacked-layer structure, for example, a stacked layer of any of the above conductive materials and titanium or titanium nitride. Note that like the conductor 203 or the like, the conductor may be formed to be embedded in an opening provided in an insulator.

### <Material for Semiconductor Device>

Materials that can be used for a semiconductor device will be described below.

### <<Substrate>>

As a substrate over which the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate containing silicon carbide, silicon germanium, gallium arsenide, indium phosphide, zinc oxide, or gallium oxide. Moreover, a semiconductor substrate in which an insulator region is included in the above semiconductor substrate, e.g., an SOI (Silicon On Insulator) substrate or the like is used. Examples of the conductor substrate include a graphite substrate, a metal substrate, an alloy substrate, and a conductive resin substrate. A substrate including a metal nitride, a substrate including a metal oxide, or the like is used. Moreover, an insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. Examples of the element provided over the substrate include a capacitor, a resistor, a switching element, a light-emitting element, and a memory element.

Alternatively, a flexible substrate may be used as the substrate. Note that as a method for providing a transistor over a flexible substrate, there is a method in which a transistor is fabricated over a non-flexible substrate and then is separated from the non-flexible substrate and transferred to the substrate that is a flexible substrate. In that case, a separation layer is preferably provided between the non-flexible substrate and the transistor. In addition, the substrate may have elasticity. Furthermore, the substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact applied to a semiconductor device over the substrate, which is caused by dropping or the like, can be reduced. That is, a durable semiconductor device can be provided.

For the substrate that is a flexible substrate, for example, a metal, an alloy, a resin, glass, or fiber thereof can be used. Note that as the substrate, a sheet, a film, a foil or the like that contains a fiber may be used. The substrate that is a flexible substrate preferably has a lower coefficient of linear expansion because deformation due to an environment is inhibited. For the substrate that is a flexible substrate, for example, a material whose coefficient of linear expansion is lower than or equal to 1×10⁻³/K, lower than or equal to 5×10⁻⁵/K, or lower than or equal to 1×10⁻⁵/K may be used. Examples of the resin include polyester, polyolefin, polyamide (nylon, aramid, or the like), polyimide, polycarbonate, and acrylic. In particular, aramid is suitable for the flexible substrate because of its low coefficient of linear expansion.

### <<Insulator>>

Examples of an insulator include an oxide, a nitride, an oxynitride, a nitride oxide, a metal oxide, a metal oxynitride, and a metal nitride oxide, each of which has an insulating property.

With miniaturization and high integration of a transistor, for example, a problem such as generation of leakage current may arise because of a thin gate insulator. When a high-k material is used for an insulator functioning as the gate insulator, voltage of the transistor can be reduced while the physical thickness of the gate insulator is kept. In contrast, when an interlayer film formed using a material with a low dielectric constant is used for the insulator functioning as an interlayer film, the parasitic capacitance generated between wirings can be reduced. Accordingly, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

In particular, silicon oxide and silicon oxynitride are thermally stable. Accordingly, a stacked-layer structure which is thermally stable and has a low dielectric constant can be obtained by combination with a resin, for example. Examples of the resin include polyester, polyolefin, polyamide (e.g., nylon or aramid), polyimide, polycarbonate, and acrylic. Furthermore, combining silicon oxide and silicon oxynitride with an insulator having a high dielectric constant enables a stacked-layer structure to have thermal stability and a high dielectric constant.

In addition, when a transistor using an oxide semiconductor is surrounded by an insulator having a function of inhibiting the passage of oxygen and impurities such as hydrogen, the transistor can have stable electrical characteristics.

As the insulator having a function of inhibiting the passage of oxygen and impurities such as hydrogen, a single layer or a stacked layer of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For example, a metal oxide containing one or more kinds selected from hafnium, aluminum, gallium, yttrium, zirconium, tungsten, titanium, tantalum, nickel, germanium, magnesium, and the like can be used as the insulator 273.

In particular, aluminum oxide has a high barrier property, so that even a thin aluminum oxide film having a thickness of greater than or equal to 0.5 nm and less than or equal to 3.0 nm can inhibit diffusion of hydrogen and nitrogen. Although hafnium oxide has a lower barrier property than aluminum oxide, the barrier property can be increased with an increase in the film thickness. Therefore, the appropriate addition amount of hydrogen and nitrogen can be adjusted by adjustment of the film thickness of hafnium oxide.

For example, an insulator containing nitrogen can be used as the insulator 274. For example, silicon nitride, silicon nitride oxide, silicon oxynitride, aluminum nitride, or aluminum nitride oxide is preferably used. In particular, the silicon nitride film can release hydrogen in the silicon nitride film during the deposition of the silicon nitride film or by the thermal budget through the following process.

For example, the insulator 224 and the insulator 250 functioning as part of the gate insulator are each preferably an insulator including an excess-oxygen region. When a structure is employed in which silicon oxide or silicon oxynitride including an excess-oxygen region is in contact with the oxide 230, oxygen vacancies included in the oxide 230 can be compensated.

For example, an insulator containing an oxide of one or more kinds of aluminum, hafnium, and gallium can be used for the insulator 224 and the insulator 252, which function as part of the gate insulator. In particular, it is preferable to use aluminum oxide, hafnium oxide, an oxide containing aluminum and hafnium (hafnium aluminate), or the like as an insulator containing an oxide of one or both of aluminum and hafnium.

For example, silicon oxide or silicon oxynitride, which is thermally stable, is preferably used for the insulator 222. When the gate insulator has a stacked-layer structure of a thermally stable film and a film with a high dielectric constant, the equivalent oxide thickness (EOT) of the gate insulator can be reduced while the physical thickness thereof is kept.

With the above stacked-layer structure, on-state current can be increased without a reduction in the influence of the electric field from the gate electrode. Since the distance between the gate electrode and the region where a channel is formed is kept by the physical thickness of the gate insulator, leakage current therebetween can be inhibited.

The insulator 212, the insulator 216, the insulator 271, the insulator 275, and the insulator 280 each preferably include an insulator with a low dielectric constant. For example, the insulator 212, the insulator 216, the insulator 271, the insulator 275, and the insulator 280 each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator 212, the insulator 216, the insulator 271, the insulator 275, and the insulator 280 each preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and low dielectric constant. Examples of the resin include polyester, polyolefin, polyamide (e.g., nylon or aramid), polyimide, polycarbonate, and acrylic.

As the insulator 210, the insulator 214, the insulator 270, and the insulator 273, an insulator having a function of inhibiting the passage of oxygen and impurities such as hydrogen may be used. For the insulator 270 and the insulator 273, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example.

### <<Conductor>>

For the conductors, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

Furthermore, a stack including a plurality of conductive layers formed with the above materials may be used. For example, a stacked-layer structure combining a material containing the above metal element and a conductive material containing oxygen may be employed. Furthermore, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

Note that when an oxide is used for the channel formation region of the transistor, a stacked-layer structure combining a material containing any of the above-described metal elements and a conductive material containing oxygen is preferably used for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where a channel is formed. Furthermore, a conductive material containing the above metal element and nitrogen may be used. For example, a conductive material containing nitrogen, such as titanium nitride or tantalum nitride, may be used. Furthermore, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where a channel is formed can be trapped in some cases. Alternatively, hydrogen entering from an external insulator or the like can be trapped in some cases.

For the conductor 260, the conductor 203, the conductor 205, and the conductor 240, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, and the like can be used. Furthermore, a semiconductor having high electrical conductivity, typified by polycrystalline silicon including an impurity element such as phosphorus, or silicide such as nickel silicide may be used.

### <<Metal Oxide>>

As the oxide 230, a metal oxide functioning as an oxide semiconductor (hereinafter also referred to as an oxide semiconductor) is preferably used. A metal oxide that can be used as the oxide 230 of one embodiment of the present invention will be described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide containing indium, an element M, and zinc is considered. Note that the element M is aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, and magnesium. Note that a plurality of the above-described elements may be combined as the element M.

### [Composition of Metal Oxide]

The composition of a CAC (Cloud-Aligned Composite)-OS that can be used for a transistor disclosed in one embodiment of the present invention will be described below.

Note that in this specification and the like, CAAC (c-axis aligned crystal) and CAC (Cloud-Aligned Composite) is sometimes stated. Note that CAAC refers to an example of a crystal structure, and CAC refers to an example of a function or a material composition.

A CAC-OS or a CAC-metal oxide has a conducting function in a part of the material and an insulating function in another part of the material, and has a function of a semiconductor as the whole material. Note that in the case where the CAC-OS or the CAC-metal oxide is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

In addition, the CAC-OS or the CAC-metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. Moreover, the conductive regions are sometimes observed to be coupled in a cloud-like manner with their boundaries blurred.

Furthermore, in the CAC-OS or the CAC-metal oxide, the conductive regions and the insulating regions each having a size greater than or equal to 0.5 nm and less than or equal to 10 nm, preferably greater than or equal to 0.5 nm and less than or equal to 3 nm are dispersed in the material in some cases.

The CAC-OS or the CAC-metal oxide is composed of components having different band gaps. For example, the CAC-OS or the CAC-metal oxide is composed of a component having a wide gap due to the insulating region and a component having a narrow gap due to the conductive region. In the case of the structure, when carriers flow, the carriers mainly flow in the component having a narrow gap. Moreover, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, the transistor in the on state can achieve high current driving capability, that is, high on-state current and high field-effect mobility.

In other words, the CAC-OS or the CAC-metal oxide can also be referred to as a matrix composite or a metal matrix composite.

### [Structure of Metal Oxide]

Oxide semiconductors (metal oxides) are classified into a single-crystal oxide semiconductor and a non-single-crystal oxide semiconductor. Examples of the non-single-crystal oxide semiconductors include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and the crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) is difficult to observe even in the vicinity of distortion in the CAAC-OS. That is, formation of a grain boundary is inhibited due to the distortion of lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (InN,Zn) layer. Furthermore, when indium of the In layer is replaced with the element M, the layer can also be referred to as an (In,M) layer.

The CAAC-OS is a metal oxide with high crystallinity. On the other hand, a clear crystal grain boundary is difficult to observe in the CAAC-OS; thus, a reduction in electron mobility due to the crystal grain boundary is less likely to occur. Furthermore, entry of impurities, formation of defects, or the like might decrease the crystallinity of a metal oxide, which means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

The a-like OS is a metal oxide having a structure between those of the nc-OS and the amorphous oxide semiconductor. The a-like OS contains a void or a low-density region. That is, the a-like OS has low crystallinity as compared with the nc-OS and the CAAC-OS.

An oxide semiconductor (a metal oxide) has various structures with different properties. Two or more kinds of the amorphous oxide semiconductor, the polycrystalline oxide semiconductor, the a-like OS, the nc-OS, and the CAAC-OS may be included in an oxide semiconductor of one embodiment of the present invention.

### [Transistor Including Metal Oxide]

Next, the case where the above metal oxide is used for a channel formation region of a transistor will be described.

Note that when the above metal oxide is used for a channel formation region of a transistor, the transistor having high field-effect mobility can be achieved. In addition, the transistor having high reliability can be achieved.

Furthermore, a metal oxide with a low carrier density is preferably used for the transistor. In the case where the carrier density of a metal oxide film is reduced, the impurity concentration in the metal oxide film is reduced to reduce the density of defect states. In this specification and the like, a state with a low impurity concentration and a low density of defect states is referred to as a highly purified intrinsic or substantially highly purified intrinsic state. For example, a metal oxide has a carrier density lower than 8×10¹¹/cm³, preferably lower than 1×10¹¹/cm³, and further preferably lower than 1×10¹⁰/cm³, and higher than or equal to 1×10⁻⁹/cm³.

Moreover, a highly purified intrinsic or substantially highly purified intrinsic metal oxide film has a low density of defect states and accordingly may have a low density of trap states.

Charges trapped by the trap states in the metal oxide take a long time to be released and may behave like fixed charges. Thus, a transistor whose channel formation region includes a metal oxide having a high density of trap states has unstable electrical characteristics in some cases.

Accordingly, in order to obtain stable electrical characteristics of the transistor, it is effective to reduce the concentration of impurities in the metal oxide. In addition, in order to reduce the concentration of impurities in the metal oxide, the impurity concentration in an adjacent film is also preferably reduced. Examples of impurities include hydrogen, nitrogen, an alkali metal, an alkaline earth metal, iron, nickel, and silicon.

Note that as a metal oxide used for a semiconductor of a transistor, a thin film having high crystallinity is preferably used. With the use of the thin film, the stability or the reliability of the transistor can be improved. Examples of the thin film include a thin film of a single-crystal metal oxide and a thin film of a polycrystalline metal oxide. However, to form the thin film of a single-crystal metal oxide or the thin film of a polycrystalline metal oxide over a substrate, a high-temperature process or a laser heating process is needed. Thus, the manufacturing cost is increased, and moreover, the throughput is decreased.

Non-Patent Document 1 and Non-Patent Document 2 have reported that an In—Ga—Zn oxide having a CAAC structure (referred to as CAAC-IGZO) was found in 2009. It has been reported that CAAC-IGZO has c-axis alignment, a grain boundary is not clearly observed in CAAC-IGZO, and CAAC-IGZO can be formed over a substrate at low temperatures. It has also been reported that a transistor using CAAC-IGZO has excellent electrical characteristics and high reliability.

In addition, in 2013, an In—Ga—Zn oxide having an nc structure (referred to as nc-IGZO) was found (see Non-Patent Document 3). It has been reported that nc-IGZO has periodic atomic arrangement in a microscopic region (for example, a region with a size greater than or equal to 1 nm and less than or equal to 3 nm) and there is no regularity of crystal orientation between different regions.

Non-Patent Document 4 and Non-Patent Document 5 have shown a change in average crystal size due to electron beam irradiation to thin films of the above CAAC-IGZO, the above nc-IGZO, and IGZO having low crystallinity. In the thin film of IGZO having low crystallinity, crystalline IGZO with a crystal size of approximately 1 nm was observed even before the electron beam irradiation. Thus, it has been reported that the existence of a completely amorphous structure was not observed in IGZO. In addition, it has been shown that the thin film of CAAC-IGZO and the thin film of nc-IGZO each have higher stability to electron beam irradiation than the thin film of IGZO having low crystallinity. Thus, the thin film of CAAC-IGZO or the thin film of nc-IGZO is preferably used for a semiconductor of a transistor.

Non-Patent Document 6 shows that a transistor using a metal oxide has an extremely low leakage current in a non-conduction state; specifically, the off-state current per micrometer in the channel width of the transistor is of the order of yA/μm (10⁻²⁴ A/μm). For example, a low-power-consumption CPU utilizing a characteristic of low leakage current of the transistor using a metal oxide is disclosed (see Non-Patent Document 7).

Furthermore, application of a transistor using a metal oxide to a display device that utilizes the characteristic of a low leakage current of the transistor has been reported (see Non-Patent Document 8). In the display device, a displayed image is changed several tens of times per second. The number of times an image is changed per second is called a refresh rate. The refresh rate is also referred to as driving frequency. Such high-speed screen change that is hard to be recognized by human eyes is considered as a cause of eyestrain. Thus, Non-Patent Document 8 has proposed that the refresh rate of the display device be lowered to reduce the number of image rewriting operations. Moreover, driving with a lowered refresh rate enables the power consumption of the display device to be reduced. Such a driving method is referred to as idling stop (IDS) driving.

The discovery of the CAAC structure and the nc structure has contributed to an improvement in electrical characteristics and reliability of a transistor using a metal oxide having the CAAC structure or the nc structure, a reduction in manufacturing cost, and an improvement in throughput. Furthermore, applications of the transistor to a display device and an LSI utilizing the characteristics of low leakage current of the transistor have been studied.

### [Impurities]

Here, the influence of each impurity in the metal oxide will be described.

When silicon or carbon that is a Group 14 element is contained in the metal oxide, defect states are formed in the metal oxide. Thus, the concentration of silicon or carbon in the metal oxide and the concentration of silicon or carbon in the vicinity of an interface with the metal oxide (the concentration measured by secondary ion mass spectrometry (SIMS) is set to lower than or equal to 2×10¹⁸ atoms/cm³, preferably lower than or equal to 2×10¹⁷ atoms/cm³.

When the metal oxide contains an alkali metal or an alkaline earth metal, defect states are formed and carriers are generated, in some cases. Thus, a transistor using a metal oxide that contains an alkali metal or an alkaline earth metal for its channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide obtained by SIMS is set lower than or equal to 1×10¹⁸ atoms/cm³, preferably lower than or equal to 2×10¹⁶ atoms/cm³.

Furthermore, when containing nitrogen, the metal oxide easily becomes n-type by generation of electrons serving as carriers and an increase in carrier density. As a result, a transistor using a metal oxide containing nitrogen for its channel formation region is likely to have normally-on characteristics. Thus, nitrogen in the metal oxide is preferably reduced as much as possible; for example, the nitrogen concentration in the metal oxide is set lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³ in SIMS.

Furthermore, hydrogen contained in a metal oxide reacts with oxygen bonded to a metal atom to be water, and thus forms an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using the metal oxide that contains hydrogen for its channel formation region is likely to have normally-on characteristics. Accordingly, hydrogen in the metal oxide is preferably reduced as much as possible. Specifically, the hydrogen concentration of the metal oxide, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When a metal oxide in which impurities are sufficiently reduced is used for a channel formation region in a transistor, stable electrical characteristics can be given.

### <Method for Fabricating Semiconductor Device>

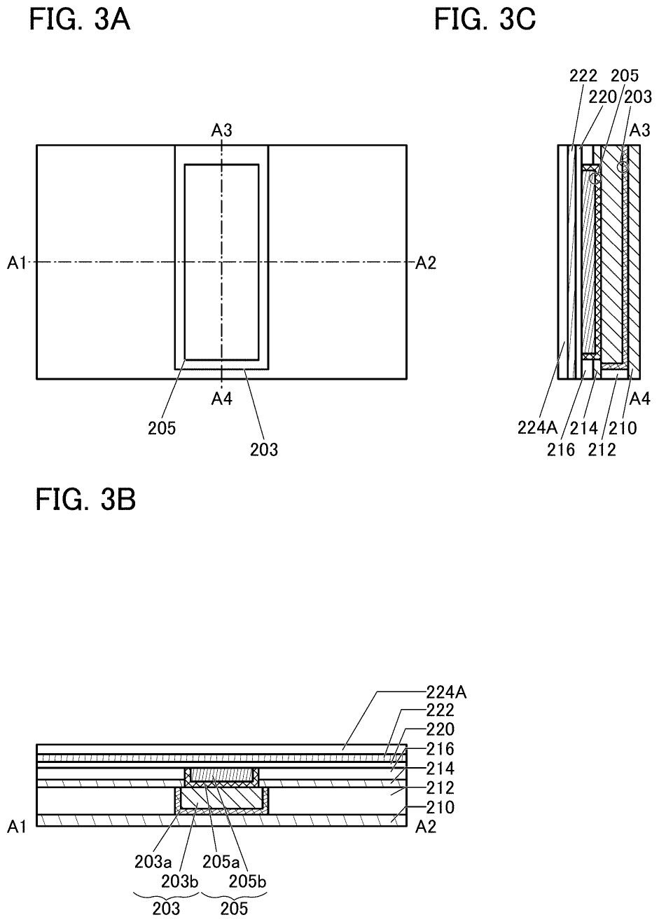

Next, a method for fabricating a semiconductor device including the transistor 200 of the present invention will be described with reference to FIG. 3 to FIG. 13. In each of FIG. 3 to FIG. 13, figure (A) is a top view. Figure (B) is a cross-sectional view of a portion indicated by a dashed-dotted line A1-A2 in figure (A). Similarly, figure (C) is a cross-sectional view of a portion indicated by a dashed-dotted line A3-A4 in figure (A).

First, a substrate (not illustrated) is prepared, and the insulator 210 is deposited over the substrate. The insulator 210 can be deposited by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. An ALD method also does not cause plasma damage during deposition, so that a film with few defects can be obtained. Note that a precursor used in an ALD method sometimes contains impurities such as carbon. Thus, a film provided by an ALD method contains impurities such as carbon in a larger amount than a film provided by another deposition method, in some cases. Note that impurities can be quantified by X-ray photoelectron spectroscopy (XPS).

Unlike in a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and thus is suitable for the case of covering a surface of an opening with a high aspect ratio, for example. On the other hand, an ALD method has a relatively low deposition rate, and thus is preferably used in combination with another deposition method with a high deposition rate such as a CVD method, in some cases.

A CVD method or an ALD method enables control of composition of a film to be obtained with a flow rate ratio of the source gases. For example, by a CVD method or an ALD method, a film with a desired composition can be deposited by adjusting the flow rate ratio of the source gases. Moreover, for example, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

In this embodiment, for the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Then, the insulator 212 is deposited over the insulator 210. The insulator 212 can be deposited by a sputtering method, a CVD method, an MBE method, a PLD method, an ALD method, or the like. In this embodiment, for the insulator 212, silicon oxide is deposited by a CVD method.

Then, an opening reaching the insulator 210 is formed in the insulator 212. Examples of the opening include a groove and a slit. In addition, a region where the opening is formed may be referred to as an opening portion. Wet etching may be used for the formation of the opening; however, dry etching is preferable for microfabrication. In addition, as the insulator 210, an insulator functioning as an etching stopper film when forming a groove by etching the insulator 212 is preferably selected. For example, in the case where a silicon oxide film is used as the insulator 212 in which the groove is to be formed, it is preferable to use a silicon nitride film, an aluminum oxide film, or a hafnium oxide film as the insulator 210, which is an insulating film functioning as an etching stopper film.

After the formation of the opening, a conductive film to be the conductor 203a is deposited. The conductive film desirably include a conductor that has a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductor to be the conductor 203a can be deposited by a sputtering method, a CVD method, an MBE method, a PLD method, an ALD method, or the like.

In this embodiment, as the conductive film to be the conductor 203a, tantalum nitride or a film of tantalum nitride and titanium nitride stacked thereover is deposited by a sputtering method. With the use of such a metal nitride as the conductor 203a, even when a metal that is easy to diffuse, such as copper, is used for the conductor 203b described later, the metal can be prevented from being diffused outward through the conductor 203a.

Next, a conductive film to be the conductor 203b is deposited over the conductive film to be the conductor 203a. The conductive film can be deposited by a sputtering method, a CVD method, an MBE method, a PLD method, an ALD method, or the like. In this embodiment, for the conductive film to be the conductor 203b, a low-resistance conductive material such as copper is deposited.

Next, chemical mechanical polishing (CMP) treatment is performed to remove parts of the conductive film to be the conductor 203a and the conductive film to be the conductor 203b, so that the insulator 212 is exposed. As a result, the conductive film to be the conductor 203a and the conductive film to be the conductor 203b remain only in the opening portion. Thus, the conductor 203 including the conductor 203a and the conductor 203b, which has a planar top surface, can be formed (see FIG. 3). Note that the insulator 212 is partly removed by the CMP treatment in some cases.

Next, the insulator 214 is deposited over the insulator 212 and the conductor 203. The insulator 214 can be deposited by a sputtering method, a CVD method, an MBE method, a PLD method, an ALD method, or the like. In this embodiment, for the insulator 214, silicon nitride is deposited by a CVD method. As described here, an insulator through which copper is less likely to pass, such as silicon nitride, is used as the insulator 214; accordingly, even when a metal that is easy to diffuse, such as copper, is used for the conductor 203b and the like, the metal can be prevented from being diffused into layers above the insulator 214.

Next, the insulator 216 is deposited over the insulator 214. The insulator 216 can be deposited by a sputtering method, a CVD method, an MBE method, a PLD method, an ALD method, or the like. In this embodiment, for the insulator 216, silicon oxide is deposited by a CVD method.

Next, an opening reaching the conductor 203 is formed in the insulator 214 and the insulator 216. The opening may be formed by wet etching; however, dry etching is preferably used for microfabrication.

After the formation of the opening, a conductive film to be the conductor 205a is deposited. The conductive film to be the conductor 205a desirably includes a conductive material that has a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductive film to be the conductor 205a can be deposited by a sputtering method, a CVD method, an MBE method, a PLD method, an ALD method, or the like.

In this embodiment, for the conductive film to be the conductor 205a, tantalum nitride is deposited by a sputtering method.

Next, a conductive film to be the conductor 205b is deposited over the conductive film to be the conductor 205a. The conductive film can be deposited by a sputtering method, a CVD method, an MBE method, a PLD method, an ALD method, or the like.

In this embodiment, for the conductive film to be the conductor 205b, titanium nitride is deposited by a CVD method and tungsten is deposited by a CVD method over the titanium nitride.

Next, CMP treatment is performed to remove parts of the conductive film to be the conductor 205a and the conductive film to be the conductor 205b, so that the insulator 216 is exposed. As a result, the conductive films to be the conductor 205a and the conductor 205b remain only in the opening portion. Thus, the conductor 205 including the conductor 205a and the conductor 205b, which has a planar top surface, can be formed (see FIG. 3). Note that the insulator 212 is partly removed by the CMP treatment in some cases.

Next, the insulator 220 is deposited over the insulator 216 and the conductor 205. The insulator 220 can be deposited by a sputtering method, a CVD method, an MBE method, a PLD method, an ALD method, or the like. In this embodiment, for the insulator 212, silicon oxide is deposited by a CVD method.

Next, the insulator 222 is deposited over the insulator 220. An insulator containing an oxide of one or both of aluminum and hafnium is preferably deposited as the insulator 222. Note that as the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in structure bodies provided around the transistor 200 are not diffused into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like.

Then, an insulating film 224A is deposited over the insulator 222. The insulating film 224A can be deposited by a sputtering method, a CVD method, an MBE method, a PLD method, an ALD method, or the like (see FIG. 3). In this embodiment, for the insulator 224A, silicon oxide is deposited by a CVD method.

Sequentially, heat treatment is preferably performed. The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen atmosphere, an inert gas atmosphere, or an atmosphere containing an oxidizing gas at 10 ppm or more, 1% or more, or 10% or more. Alternatively, the heat treatment may be performed under a reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

In this embodiment, heat treatment is performed at 400° C. in a nitrogen atmosphere for one hour after the deposition of the insulating film 224A.

Through the above heat treatment, excess oxygen is added from the insulator 222 to the insulating film 224A, whereby an excess-oxygen region can be easily formed in the insulating film 224A. Moreover, impurities such as water and hydrogen contained in the insulating film 224A can be removed, for example.

This heat treatment can also be performed after the deposition of the insulator 220 and after the deposition of the insulator 222. Although the conditions for the above-described heat treatment can be used for the heat treatment, the heat treatment after the deposition of the insulator 220 is preferably performed in an atmosphere containing nitrogen.

Here, in order to form an excess-oxygen region in the insulating film 224A, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and RF application to the substrate side allows the oxygen radicals generated by the high-density plasma to be efficiently introduced into the insulating film 224A. Alternatively, after plasma treatment containing an inert gas is performed with this apparatus, plasma treatment containing oxygen may be performed to compensate for released oxygen. Note that impurities such as water and hydrogen contained in the insulating film 224A can be removed by selecting the conditions for the plasma treatment appropriately. In that case, the heat treatment is not necessarily performed.

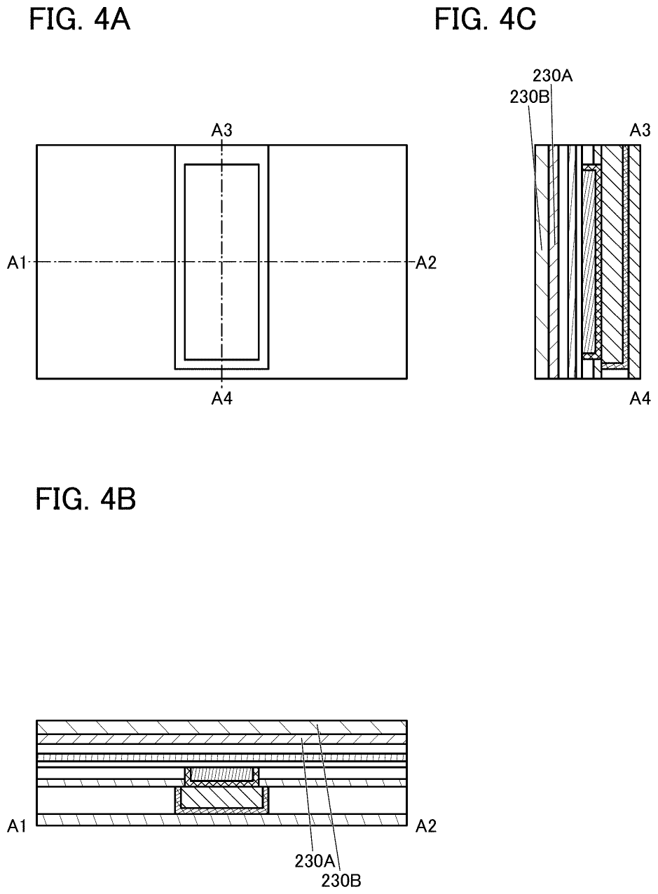

Next, an oxide film 230A to be the oxide 230a and an oxide film 230B to be the oxide 230b are deposited in this order over the insulating film 224A (see FIG. 4). Note that the oxide films are preferably deposited successively without exposure to an air atmosphere. By the deposition without exposure to the air, impurities or moisture from the air atmosphere can be prevented from being attached to the oxide film 230A and the oxide film 230B, so that the vicinity of an interface between the oxide film 230A and the oxide film 230B can be kept clean.

The oxide film 230A and the oxide film 230B can be deposited by a sputtering method, a CVD method, an MBE method, a PLD method, an ALD method, or the like.

In the case where the oxide film 230A and the oxide film 230B are deposited by a sputtering method, for example, oxygen or a mixed gas of oxygen and a rare gas is used as a sputtering gas. By increasing the proportion of oxygen contained in the sputtering gas, the amount of excess oxygen in the oxide film to be deposited can be increased. In the case where the above oxide films are deposited by a sputtering method, the above In-M-Zn oxide target can be used.

In particular, when the oxide film 230A is deposited, part of oxygen contained in the sputtering gas is supplied to the insulating film 224A in some cases. Therefore, the proportion of oxygen contained in the sputtering gas for the oxide film 230A is preferably 70% or higher, further preferably 80% or higher, and still further preferably 100%.

In the case where the oxide film 230B is formed by a sputtering method, when the proportion of oxygen contained in the sputtering gas is 1% or higher and 30% or lower, and preferably 5% or higher and 20% or lower during the deposition, an oxygen-deficient oxide semiconductor is formed. In a transistor using an oxygen-deficient oxide semiconductor, relatively high field-effect mobility can be obtained.

In this embodiment, the oxide film 230A is deposited by a sputtering method using a target with In:Ga:Zn=1:3:4 [atomic ratio]. The oxide film 230B is deposited by a sputtering method using a target with In:Ga:Zn=4:2:4.1 [atomic ratio]. Note that each of the oxide films is preferably formed to have characteristics required for the oxide 230 by appropriate selection of deposition conditions and an atomic ratio.

Next, heat treatment may be performed. For the heat treatment, the conditions for the above-described heat treatment can be used. Through the heat treatment, impurities such as water and hydrogen contained in the oxide film 230A and the oxide film 230B can be removed, for example. In this embodiment, treatment is performed at 400° C. in a nitrogen atmosphere for one hour, and successively another treatment is performed at 400° C. in an oxygen atmosphere for one hour.

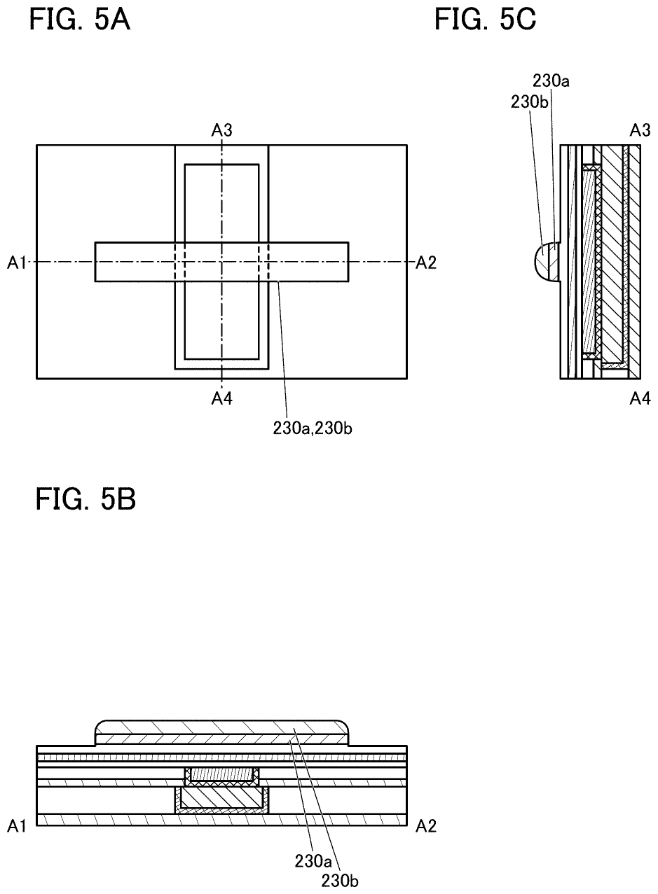

Then, the oxide film 230A and the oxide film 230B are processed into island shapes to form the oxide 230a and the oxide 230b (see FIG. 5).

The oxide 230a and the oxide 230b are formed to overlap with the conductor 205 at least partly. It is preferable that side surfaces of the oxide 230a and the oxide 230b be substantially perpendicular to a top surface of the insulator 222. When the side surfaces of the oxide 230a and the oxide 230b are substantially perpendicular to the top surface of the insulator 222, the plurality of transistors 200 can be provided in a smaller area and at a higher density. Note that a structure may be employed in which an angle formed by the side surfaces of the oxide 230a and the oxide 230b and the top surface of the insulator 222 is an acute angle. In that case, the angle formed by the side surfaces of the oxide 230a and the oxide 230b and the top surface of the insulator 222 is preferably larger.

There is a curved surface between the side surfaces of the oxide 230a and the oxide 230b and the top surface of the oxide 230a. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm, for example. When the end portions are not angular, the coverage with films deposited in a later step can be improved.

Note that for the processing of the oxide films, a lithography method can be employed. For the processing, a dry etching method or a wet etching method can be employed. The processing by a dry etching method is suitable for microfabrication.

In the lithography method, first, a resist is exposed to light through a mask. Next, a region exposed to light is removed or left using a developing solution, so that a resist mask is formed. Then, etching treatment through the resist mask is performed, so that the conductor, the semiconductor, the insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. Furthermore, an electron beam or an ion beam may be used instead of the above-described light. Note that the above mask for the exposure of the resist to light is unnecessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment, for example.

A hard mask formed of an insulator or a conductor may be used instead of the resist mask. In the case where a hard mask is used, a hard mask with a desired shape can be formed in the following manner: an insulating film or a conductive film that is the hard mask material is formed over the oxide film 230B, a resist mask is formed thereover, and then the hard mask material is etched. The etching of the oxide film 230A and the oxide film 230B may be performed after removal of the resist mask or while the resist mask remains. In the latter case, the resist mask disappears during the etching in some cases. The hard mask may be removed by etching after the etching of the above oxide films. The hard mask does not need to be removed in the case where the hard mask material does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, treatment such as dry etching performed in the above process makes impurities to attach to a surface or to diffuse into the oxide 230a, the oxide 230b, and the like due to an etching gas or the like. Examples of the impurities include fluorine and chlorine.

In order to remove the above impurities, cleaning is performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution obtained by diluting an oxalic acid, a phosphoric acid, a hydrofluoric acid, or the like with pure water or carbonated water. Alternatively, ultrasonic cleaning using pure water or carbonated water may be performed. In this embodiment, the ultrasonic cleaning using pure water or carbonated water is performed.

Sequentially, heat treatment may be performed. For the conditions of the heat treatment, the conditions for the above-described heat treatment can be used.

Next, an oxide film 230C is deposited over the insulating film 224A, the oxide 230a, and the oxide 230b.

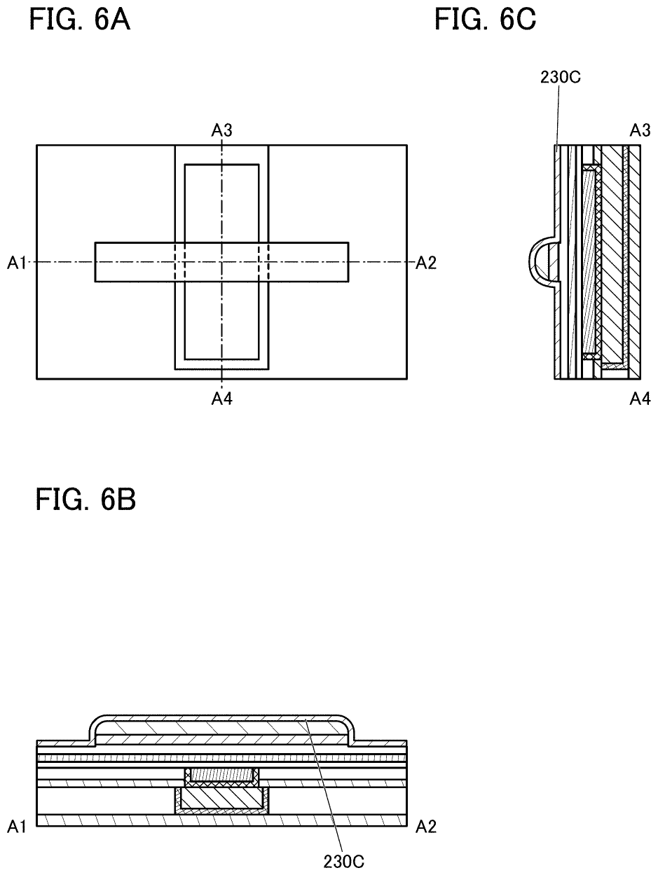

The oxide film 230C can be deposited by a sputtering method, a CVD method, an MBE method, a PLD method, an ALD method, or the like. The oxide film 230C may be deposited by a method similar to that for the oxide film 230A or the oxide film 230B in accordance with characteristics required for the oxide 230c. In this embodiment, the oxide film 230C is deposited by a sputtering method using a target with In:Ga:Zn=1:3:4 [atomic ratio] (see FIG. 6).

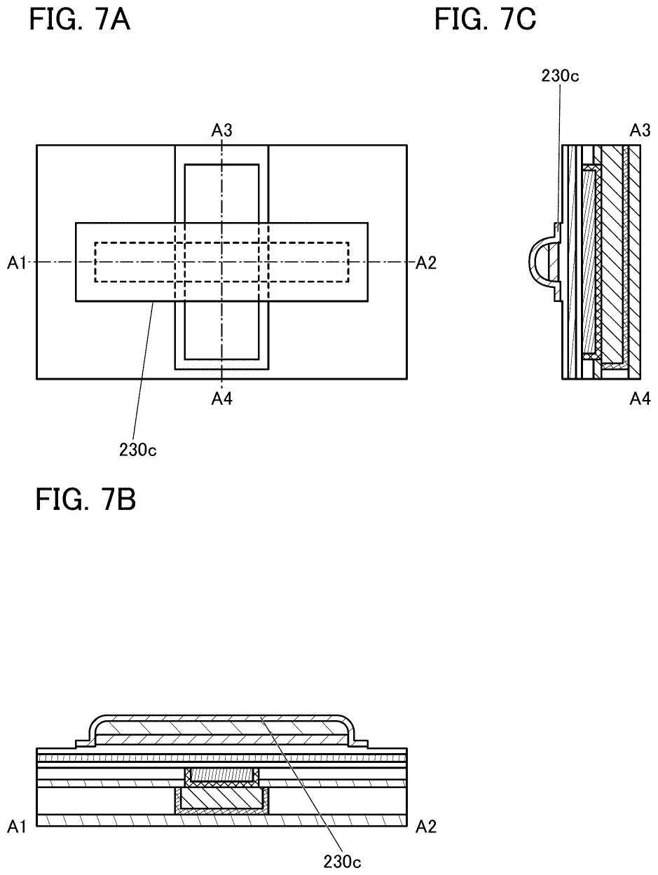

Then, the oxide film 230C is processed to form the oxide 230c (see FIG. 7). Note that in this step, the insulating film 224A may be processed into an island shape. In that case, the insulator 222 can be used as an etching stopper film.

In the case where the insulator 224A is processed into an island shape, a structure may be employed in which the insulator 222 and the insulator 273 is in contact with each other on the outer side than the insulator 224. With the structure, the oxide 230 is sealed with the film that inhibits diffusion of hydrogen or nitrogen. Thus, unintended excess entrance of impurities from a structure body other than the insulator 274 can be prevented.

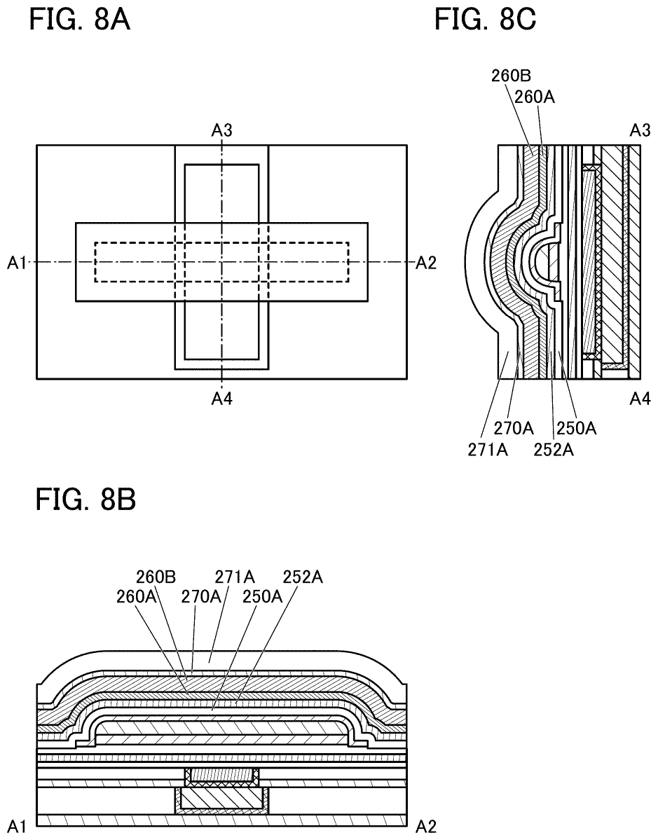

Then, an insulating film 250A, an insulating film 252A, a conductive film 260A, a conductive film 260B, an insulating film 270A, and an insulating film 271A are deposited in this order over the oxide 230 and the insulating film 224A (see FIG. 8).

First, the insulating film 250A is deposited. The insulating film 250A can be deposited by a sputtering method, a CVD method, an MBE method, a PLD method, an ALD method, or the like. In this example, silicon oxynitride is preferably deposited by a CVD method for the insulating film 250A. Note that the deposition temperature during the deposition of the insulating film 250A is preferably higher than or equal to 350° C. and lower than 450° C., particularly preferably approximately 400° C. When the insulating film 250A is deposited at 400° C., an insulator having few impurities can be deposited.

Note that oxygen is excited by microwaves to generate high-density oxygen plasma, and the insulating film 250A is exposed to the oxygen plasma, whereby oxygen can be introduced into the insulating film 250A and the oxide 230.

Furthermore, heat treatment may be performed. For the heat treatment, the conditions for the above-described heat treatment can be used. The heat treatment can reduce the moisture concentration and the hydrogen concentration in the insulating film 250A.

Then, the insulating film 252A is deposited over the insulating film 250A. An insulator containing an oxide of one or both of aluminum and hafnium is preferably deposited as the insulating film 252A. As the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in structure bodies provided around the transistor 200 are not diffused into the transistor 200 through the insulator 222, and generation of oxygen vacancies in the oxide 230 can be inhibited.

The insulating film 252A can be deposited by a sputtering method, a CVD method, an MBE method, a PLD method, an ALD method, or the like.

When a metal oxide is deposited as the insulating film 252A by a sputtering method in an atmosphere containing oxygen, oxygen can be added to the insulating film 250A and an excess-oxygen region can be formed in the insulating film 250A. The excess oxygen added to the insulating film 250A can compensate for the oxygen vacancy in the oxide 230 when supplied thereto.

Here, during the deposition of the insulating film 252A by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The relationship between the potentials is E₂>E₁>E₀.

The ions in plasma are accelerated by a potential difference (E₂−E₀) and collide with the target; accordingly, the sputtered particles are ejected from the target. These sputtered particles are attached to a deposition surface and deposited thereover; as a result, a film is deposited. Some ions recoil by the target and might, as recoil ions, pass through the formed film and be taken into the insulating film 250A and the insulating film 224A in contact with the deposition surface. The ions in the plasma are accelerated by a potential difference (E₂−E₁) and collide with the deposition surface. At that time, some ions reach the inside of the insulating film 250A and the insulating film 224A. When the ions are taken into the insulating film 250A and the insulating film 224A, a region into which the ions are taken is formed in the insulating film 250A and the insulating film 224A. That is, an excess-oxygen region is formed in the insulating film 250A and the insulating film 224A in the case where the ions contain oxygen.

When excess oxygen is introduced into the insulating film 250A and the insulating film 224A, an excess-oxygen region can be formed. The excess oxygen in the insulating film 250A and the insulating film 224A is supplied to the oxide 230 and can compensate for oxygen vacancies in the oxide 230.

Accordingly, when the deposition is performed in an oxygen gas atmosphere with a sputtering apparatus as the method for depositing the insulating film 252A, oxygen can be introduced into the insulating film 250A and the insulating film 224A while the insulating film 252A is deposited. In particular, when an oxide of one or both of aluminum and hafnium that has a barrier property is used for the insulating film 252A, excess oxygen introduced into the insulator 250 can be effectively sealed therein.

Sequentially, the conductive film 260A and the conductive film 260B are deposited. The conductive film 260A and the conductive film 260B can be deposited by a sputtering method, a CVD method, an MBE method, a PLD method, an ALD method, or the like. In this embodiment, titanium nitride is deposited by a CVD method for the conductive film 260A and tungsten is deposited by a CVD method for the conductive film 260B.

Subsequently, heat treatment can be performed. For the heat treatment, the conditions for the above-described heat treatment can be used. Note that the heat treatment is not necessarily performed in some cases. Through the heat treatment, excess oxygen is added from the insulating film 252A to the insulating film 250A and the insulator 224, whereby an excess-oxygen region can be easily formed in the insulating film 250A and the insulating film 224A.

The insulating film 270A can be deposited by a sputtering method, a CVD method, an MBE method, a PLD method, an ALD method, or the like. For the insulating film 270A functioning as a barrier film, an insulating material having a function of inhibiting the passage of oxygen and impurities such as water or hydrogen is used. For example, aluminum oxide or hafnium oxide is preferably used. Thus, oxidation of the conductor 260 can be prevented. This can prevent entry of impurities such as water or hydrogen into the oxide 230 through the conductor 260 and the insulator 250. In this embodiment, for the insulating film 270A, aluminum oxide is deposited by an ALD method.

The insulating film 271A can be deposited by a sputtering method, a CVD method, an MBE method, a PLD method, an ALD method, or the like. Here, the film thickness of the insulating film 271A is preferably larger than the film thickness of an insulating film 272A to be deposited in a later step. In that case, when an insulator 272 is formed in a later step, the insulator 271 can remain easily over the conductor 260. In this embodiment, for the insulating film 271A, silicon oxide is deposited by a CVD method.

Next, the insulating film 271A is etched to form the insulator 271. Here, the insulator 271 functions as a hard mask. When the insulator 271 is provided, the side surface of the insulator 250, the side surface of the insulator 252, the side surface of the conductor 260a, the side surface of the conductor 260b, and the side surface of the insulator 270 can be formed substantially perpendicular to the top surface of the substrate.

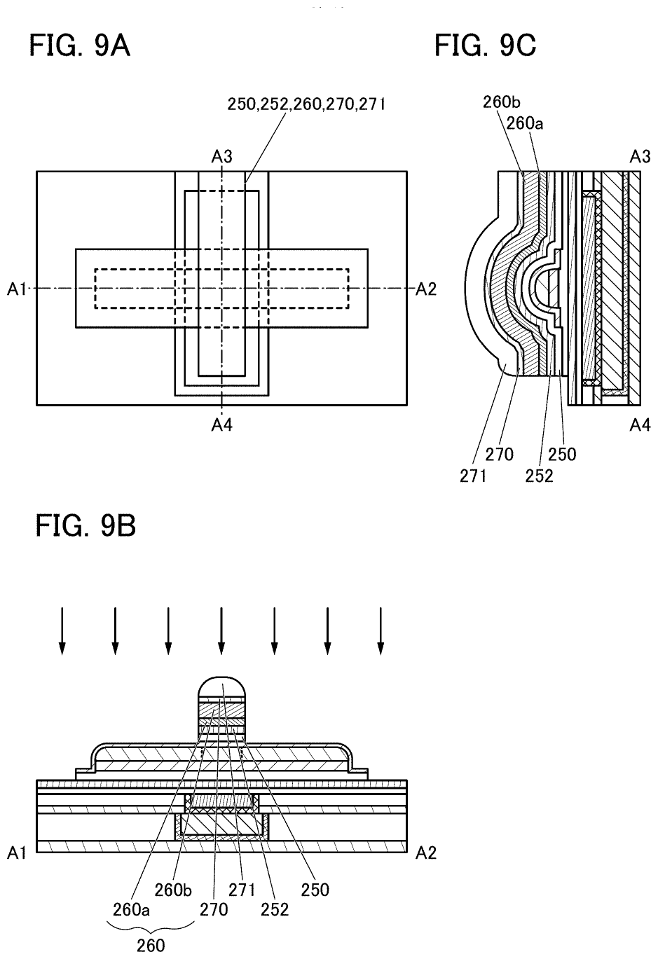

Then, with the use of the insulator 271 as a mask, the insulating film 250A, the insulating film 252A, the conductive film 260A, the conductive film 260B, and the insulating film 270A are etched to form the insulator 250, the insulator 252, the conductor 260 (the conductor 260a and the conductor 260b), and the insulator 270 (see FIG. 9). Note that in this step, the insulating film 224A may be processed into an island shape. In that case, the insulator 222 can be used as an etching stopper film.

Note that part of the oxide 230c may be removed by the etching in a region where the oxide 230c and the insulator 250 do not overlap with each other. In that case, the film thickness of the oxide 230c in a region overlapping with the insulator 250 is larger than the film thickness thereof in the region not overlapping with the insulator 250, in some cases.

The insulator 250, the insulator 252, the conductor 260, the insulator 270, and the insulator 271 are formed to at least partly overlap with the conductor 205 and the oxide 230.

In addition, the side surface of the insulator 250, the side surface of the insulator 252, the side surface of the conductor 260, and the side surface of the insulator 270 are preferably on the same surface.

It is also preferable that the surface shared by the side surface of the insulator 250, the side surface of the insulator 252, the side surface of the conductor 260, and the side surface of the insulator 270 be substantially perpendicular to the substrate. Note that in the cross-sectional shape, a structure may be employed in which the angle formed by the side surfaces of the insulator 250, the insulator 252, the conductor 260, and the insulator 270 and the top surface of the oxide 230 is an acute angle. In that case, the angle formed by the side surfaces of the insulator 250, the conductor 260, and the insulator 270 and the top surface of the oxide 230 is preferably larger.

Note that after the processing, the following process may be performed without removal of the hard mask (the insulator 271).

Here, for example, treatment for adding a metal element or an impurity to the oxide 230 using the insulator 250, the insulator 252, the conductor 260, the insulator 270, and the insulator 271 as masks may be performed (indicated by arrows in FIG. 9(B)).

Note that as the method for adding an impurity and a metal element, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that the impurity and the metal element to be added may be referred to as an element, a dopant, an ion, a donor, an acceptor, or the like.

Alternatively, the impurity and the metal element may be added by plasma treatment. In that case, the plasma treatment is performed with a plasma CVD apparatus, a dry etching apparatus, or an ashing apparatus, so that the impurity and the metal element can be added. Note that a plurality of the above-described treatments may be combined.

Since the conductor 260 functioning as a gate electrode is used as a mask, addition of hydrogen and nitrogen only to the region of the oxide 230 overlapping with the conductor 260 (the region 234) is inhibited, so that a boundary between the region 234 and the region 232 can be provided in a self-aligned manner.

By the treatment for adding an impurity using the conductor 260 as a mask, for example, the region 232 is formed in a process after the insulator 274 is provided, so that the region 232 can be surely provided even in the case where the thermal budget is not enough for diffusing the impurity. Note that due to the diffusion of an impurity, the region 232 may overlap with the conductor 260 functioning as the gate electrode. In that case, the region 232 functions as what is called an overlap region (also referred to as an Lov region).

Alternatively, the impurity may be added by an ion doping method through a film to be the insulator 273 after the film to be the insulator 273 is deposited, for example. The film to be the oxide film 273 is provided to cover the oxide 230, the insulator 250, the insulator 252, the conductor 260, the insulator 270, and the insulator 271. Therefore, the impurity can be added while the insulator 250 and the insulator 252 functioning as gate insulators are protected by the insulator 273.

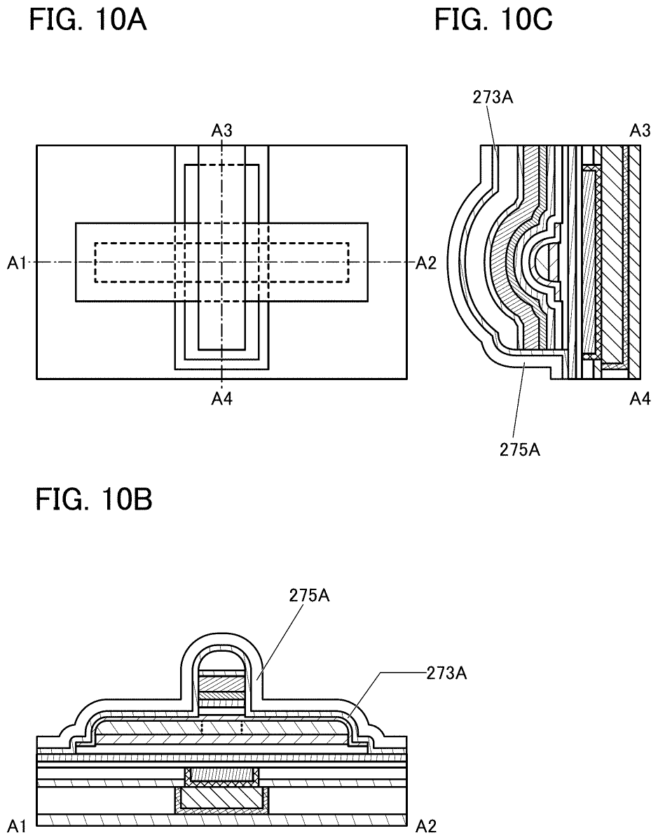

Next, an insulating film 273A and an insulating film 275A are deposited to cover the oxide 230, the insulator 250, the insulator 252, the conductor 260, the insulator 270, and the insulator 271 (see FIG. 10). The insulating film 273A and the insulating film 274A can be deposited by a sputtering method, a CVD method, an MBE method, a PLD method, an ALD method, or the like.

The insulating film 273A is preferably deposited by an ALD method, which enables good coverage. With the use of an ALD method, the insulating film 273A having a uniform thickness can be formed on the side surfaces of the insulator 250, the insulator 252, the conductor 260, and the insulator 270 even in a step portion formed by the conductor 260 and the like.

For example, a metal oxide film deposited by an ALD method can be used as the insulating film 273A. With the use of an ALD method, a dense thin film can be deposited. The metal oxide film preferably contains one or more kinds selected from hafnium, aluminum, gallium, yttrium, zirconium, tungsten, titanium, tantalum, nickel, germanium, magnesium, and the like. In this embodiment, for the insulator 273, aluminum oxide is used.

Note that aluminum oxide has a high barrier property, so that even a thin aluminum oxide film having a thickness of greater than or equal to 0.5 nm and less than or equal to 3.0 nm can inhibit diffusion of hydrogen and nitrogen. Although hafnium oxide has a lower barrier property than aluminum oxide, the barrier property can be increased with an increase in the film thickness. For example, when hafnium oxide is deposited by an ALD method, the film thickness of the hafnium oxide can be easily adjusted, and appropriate addition amount of hydrogen and nitrogen can be adjusted.

Therefore, in the case where aluminum oxide is used for the insulating film 273A, the film thickness in a region in contact with the side surface of the insulator 250, the side surface of the insulator 252, the side surface of the conductor 260, and the side surface of the insulator 270 are preferably greater than or equal to 0.5 nm, further preferably greater than or equal to 3.0 nm.

The insulator to be the insulating film 273A is preferably deposited by a sputtering method. With the use of a sputtering method, an insulator with few impurities such as water or hydrogen can be deposited. In the case of using a sputtering method, the deposition is preferably performed with the use of a facing-target sputtering apparatus, for example. With the facing-target sputtering apparatus, deposition can be performed without exposing a deposition surface to a high electric field region between facing targets; thus, the deposition surface is less likely to be damaged due to plasma during the deposition. Therefore, deposition damage to the oxide 230 during the deposition of the insulator to be the insulating film 273A can be reduced, which is preferable. A deposition method using the facing-target sputtering apparatus can be referred to as VDSP (Vapor Deposition SP) (registered trademark).

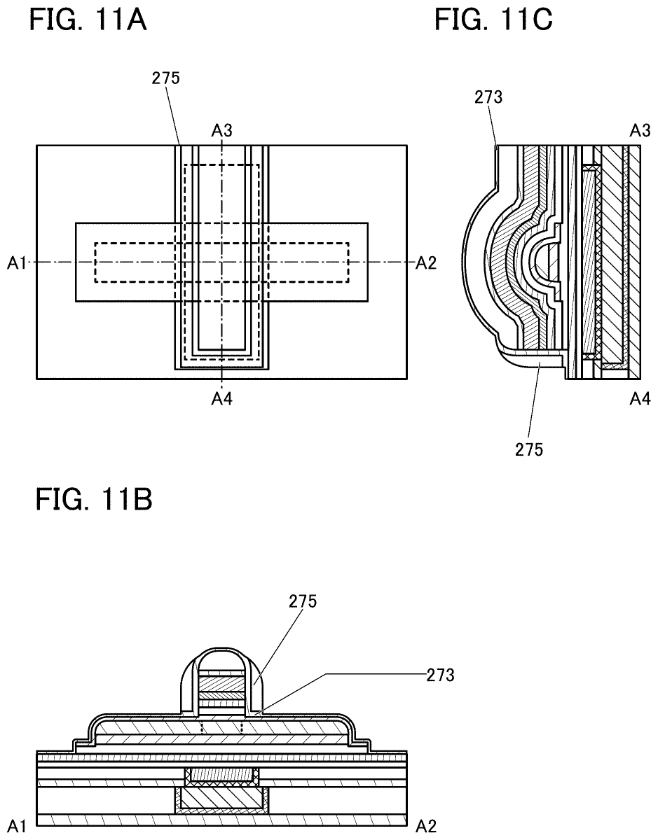

Next, the insulating film 275A is subjected to anisotropic etching treatment, whereby the insulator 275 is formed to overlap with the side surfaces of the insulator 250, the insulator 252, the conductor 260, and the insulator 270 with the insulator 273 therebetween. Moreover, the exposed surface of the insulating film 273A is removed to thin part of the insulating film 273A, so that the insulator 273 is formed (see FIG. 11). Note that in the case where the insulator 273 is aluminum oxide, the film thickness of the insulator 273 in the thinned region is preferably less than or equal to 3.0 nm.

Dry etching treatment is preferably performed as the above anisotropic etching treatment. In this manner, the insulating film in a region on a surface substantially parallel to the substrate surface can be removed, so that the insulator 272 can be formed in a self-aligned manner.

Alternatively, the above etching may etch the insulating film 273A at the same time to form the insulator 273. Note that the insulator 273 may be formed in an etching step different from the above etching.

Although not illustrated, the insulating film 275A may remain also on the side surface of the oxide 230. In that case, coverage with an interlayer film or the like to be deposited in a later step can be improved.

Since a structure body in which part of the insulating film 275A remains is formed in contact with the side surface of the oxide 230, in the case where the insulator 274 containing an element serving as an impurity is deposited to form the region 231a and the region 231b in the oxide 230 in a later step, the resistance of an interface region between the insulator 224 and the oxide 230 is not reduced, so that generation of leakage current can be inhibited.

Next, the region 231 and the region 232 are formed in the oxide 230. The region 231 and the region 232 are each a region of the metal oxide provided as the oxide 230 to which impurities are added. Note that the region 231 has higher conductivity than at least the region 234.

In order to add the impurities to the region 231 and the region 232, a dopant which is at least one of the impurities and the metal element such as indium or gallium is added, for example. Note that as the dopant, the above-described element that forms an oxygen vacancy, the element trapped by an oxygen vacancy, or the like may be used. Examples of the element include hydrogen, boron, carbon, nitrogen, fluorine, phosphorus, sulfur, chlorine, titanium, and a rare gas. In addition, typical examples of the rare gas element include helium, neon, argon, krypton, and xenon.

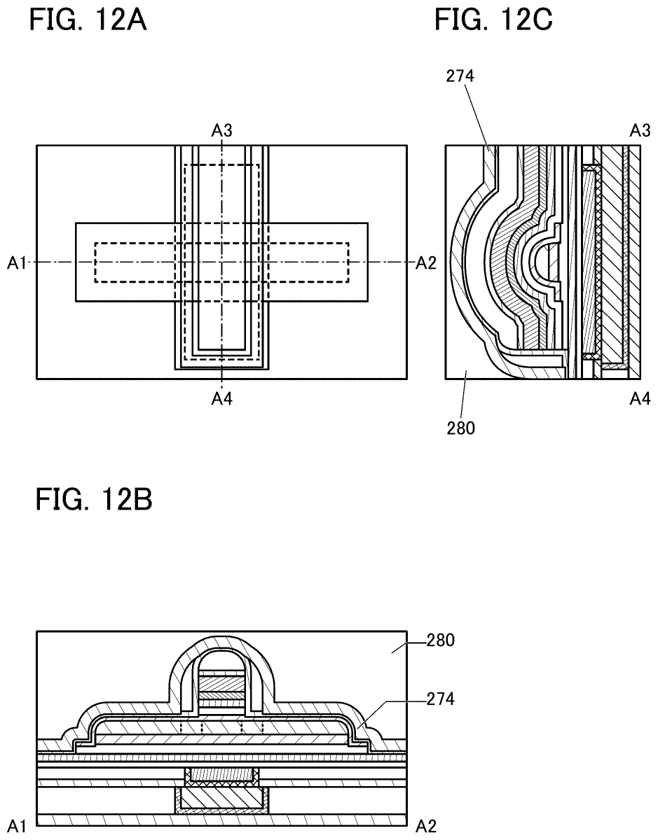

For example, in order to add impurities to the region 231 and the region 232, the insulator 274 is preferably deposited as a film containing a dopant over the region 231 with the insulator 273 therebetween. As the insulator 274, an insulating film containing one or more kinds of the above elements is preferably used (see FIG. 12).

Specifically, the insulator 274 containing an element serving as an impurity such as nitrogen is preferably deposited over the oxide 230 with the insulator 273 containing a metal element therebetween. The insulator containing an element serving as an impurity such as nitrogen may extract and absorb oxygen contained in the oxide 230. When oxygen is extracted from the oxide 230, oxygen vacancies are generated in the region 231 and the region 232. Through the deposition of the insulator 274 or heat treatment after the deposition, impurity elements such as hydrogen or nitrogen contained in the deposition atmosphere of the insulator 274 are trapped by the oxygen vacancies, so that the resistances of the region 231 and the region 232 are reduced. That is, oxygen vacancies are formed mainly in a region of the oxide 230 which is in contact with the insulator 274 because of the added impurity elements, and the impurity elements enter the oxygen vacancies, thereby increasing the carrier density and reducing the resistance. At that time, it is considered that, the impurities are diffused also into the region 232 not in contact with the insulator 274, whereby the resistance of the region 232 is reduced.

Accordingly, a source region and a drain region can be formed in a self-aligned manner owing to the deposition of the insulator 274. Thus, miniaturized or highly integrated semiconductor devices can be manufactured with high yield.

Here, when the insulator 275 is formed to overlap with the side surface of the conductor 260 with the insulator 273 therebetween, impurity elements such as nitrogen or hydrogen that are added to the region 231 can be inhibited from being diffused into the region 234 of the oxide 230.

In addition, when the insulator 273 is formed between the insulator 274 and the oxide 230, impurity elements such as nitrogen or hydrogen can be inhibited from being added excessively to the oxide 230.

Here, the top surface and the side surfaces of the conductor 260, the insulator 252, and the insulator 250 are covered with the insulator 275 and the insulator 273, whereby impurity elements such as nitrogen or hydrogen can be prevented from entering the conductor 260, the insulator 252, and the insulator 250. Thus, impurity elements such as nitrogen or hydrogen can be prevented from entering the region 234 functioning as the channel formation region of the transistor 200 through the conductor 260, the insulator 252, and the insulator 250. Accordingly, the transistor 200 having favorable electrical characteristics can be provided.

The insulator 274 can be deposited by a sputtering method, a CVD method, an MBE method, a PLD method, an ALD method, or the like.

For the insulator 274, silicon nitride, silicon nitride oxide, silicon oxynitride, or the like which is deposited by a CVD method can be used, for example. In this embodiment, silicon nitride oxide is used for the insulator 274.

In the case where silicon nitride oxide is used for the insulator 274, the region 231a and the region 231b preferably have a higher concentration of at least one of hydrogen and nitrogen than the region 234. The concentration of hydrogen or nitrogen is measured by secondary ion mass spectrometry (SIMS) or the like. Here, as the concentration of hydrogen or nitrogen in the region 234, the concentration of hydrogen or nitrogen in the middle of the region of the oxide 230b that overlaps with the insulator 250 (e.g., a portion in the oxide 230b which is located equidistant from both side surfaces of the insulator 250 in the channel length direction) is measured.

Note that the above regions may be formed in combination with other methods for adding a dopant. As other methods for adding a dopant, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that a dopant may be referred to as an ion, donor, acceptor, impurity, element, or the like.

Alternatively, impurities may be added by plasma treatment. In this case, the plasma treatment is performed with a plasma CVD apparatus, a dry etching apparatus, or an ashing apparatus, so that a dopant can be added to the region 231 and the region 232. Note that a plurality of the above-described treatments may be combined to form the regions and the like.

For example, when the content percentage of the element that forms an oxygen vacancy or the element trapped by an oxygen vacancy in the region 231 is increased, the carrier density can be increased and the resistance can be reduced. Alternatively, for example, when a metal element such as indium is added to the region 231 to increase the content percentage of the metal atom such as indium in the oxide 230, the electron mobility can be increased and the resistance can be reduced. Note that in the case of adding indium, atomic ratio of indium to the element M at least in the region 231 is higher than the atomic ratio of indium to the element M in the region 234.

When the region 232 is provided in the transistor 200, a high-resistance region not formed between the region 231 functioning as the source region and the drain region and the region 234 where a channel is formed, so that the on-state current and the mobility of the transistor can be increased. Since the gate does not overlap with the source region and the drain region in the channel length direction owing to the region 232, formation of unnecessary capacitance can be inhibited. Furthermore, leakage current in a non-conduction state can be reduced owing to the region 232.

Thus, by appropriately selecting the areas of the regions, a transistor having electrical characteristics that meet the demand for the circuit design can be easily provided.

Subsequently, heat treatment can be performed. For the heat treatment, the conditions for the above-described heat treatment can be used. Through the heat treatment, the added impurities are diffused into the region 232 of the oxide 230, whereby the on-state current can be increased.

Next, the insulator 280 is deposited over the insulator 274. The insulator 280 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used. In this embodiment, silicon oxynitride is used for the insulating film.

Next, the insulator 280 is partly removed. The insulator 280 is preferably formed to have a planar top surface. For example, the insulator 280 may have a planar top surface right after the deposition of the insulating film to be the insulator 280. Alternatively, for example, the insulator 280 may have planarity by removing the insulator and the like from the top surface after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have planarity.

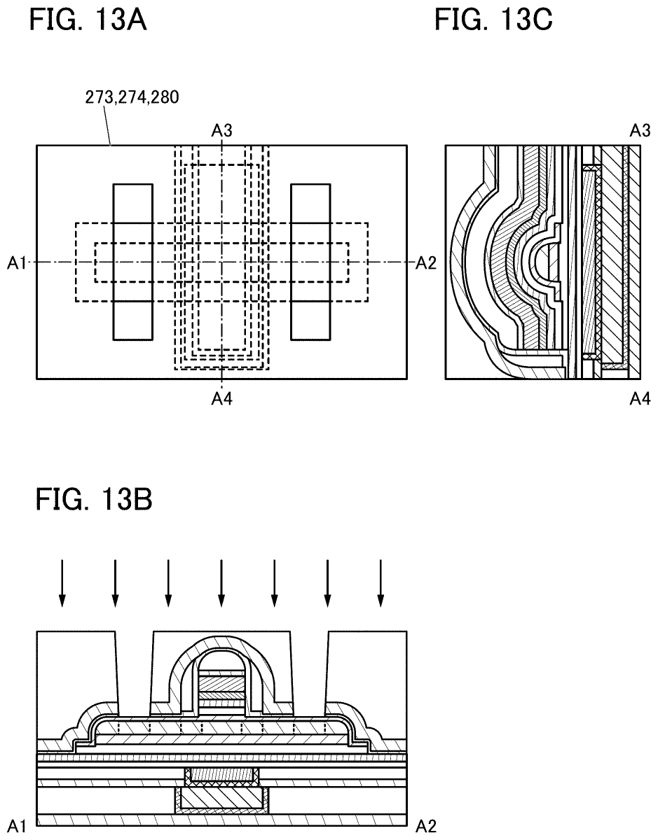

Next, openings reaching the oxide 230 are formed in the insulator 280 and the insulator 274 (see FIG. 13). The openings can be formed by a lithography method. Note that in order that the conductor 240a and the conductor 240b are provided in contact with the side surface of the oxide 230, the openings are formed to reach the oxide 230 such that the side surface of the oxide 230 is exposed in the openings.

Here, treatment for adding a metal element or an impurity to the oxide 230 using the insulator 280, the insulator 274, and the insulator 273 as masks may be performed, for example (indicated by arrows in FIG. 13(B)). When the treatment for adding a metal element or an impurity is performed, the region 236 can be formed in a self-aligned manner. Note that the region 236 preferably has a lower resistance than the region 231. When the resistance of the region 236 is reduced, a sufficient ohmic contact between the oxide 230 and the conductor 240 can be made.

Note that as the method for adding an impurity and a metal element, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that the impurity and the metal element to be added may be referred to as an element, a dopant, an ion, a donor, an acceptor, or the like.

The impurity and the metal element may be added by plasma treatment. In that case, the plasma treatment is performed with a plasma CVD apparatus, a dry etching apparatus, or an ashing apparatus, so that the impurity and the metal element can be added. Note that a plurality of the above-described treatments may be combined.

Next, a conductive film to be the conductor 240a and the conductor 240b is deposited. The conductive film can be deposited by a sputtering method, a CVD method, an MBE method, a PLD method, an ALD method, or the like.

Next, CMP treatment is performed to remove part of the conductive film to be the conductor 240a and the conductor 240b, so that the insulator 280 is exposed. As a result, the conductive film remains only in the openings, so that the conductor 240a and the conductor 240b having planar top surfaces can be formed (see FIG. 1).

Through the above process, the semiconductor device including the transistor 200 can be fabricated. As illustrated in FIG. 3 to FIG. 13, with the use of the method for fabricating the semiconductor device described in this embodiment, the transistor 200 can be formed.

According to one embodiment of the present invention, a semiconductor device having favorable electrical characteristics can be provided. Alternatively, according to one embodiment of the present invention, a semiconductor device with low off-state current can be provided. Alternatively, according to one embodiment of the present invention, a transistor with high on-state current can be provided. Alternatively, according to one embodiment of the present invention, a highly reliable semiconductor device can be provided. Alternatively, according to one embodiment of the present invention, a semiconductor device that can be miniaturized or highly integrated can be provided. Alternatively, according to one embodiment the present invention, a semiconductor device with reduced power consumption can be provided. Alternatively, according to one embodiment of the present invention, a semiconductor device with high productivity can be provided.

The structure, method, and the like described above in this embodiment can be used in combination as appropriate with the structures, methods, and the like described in the other embodiments.

### <Modification Example of Semiconductor Device>

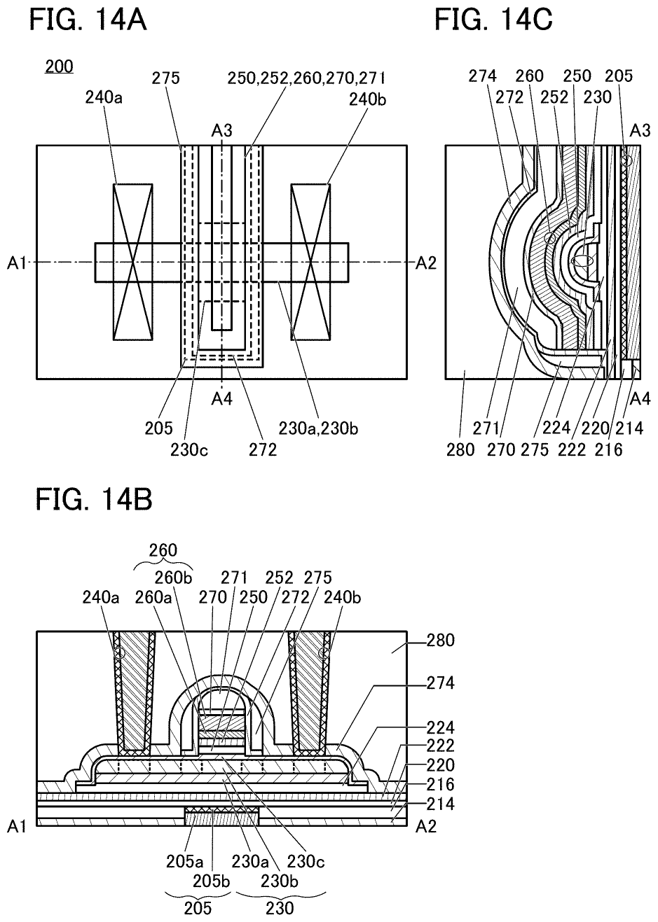

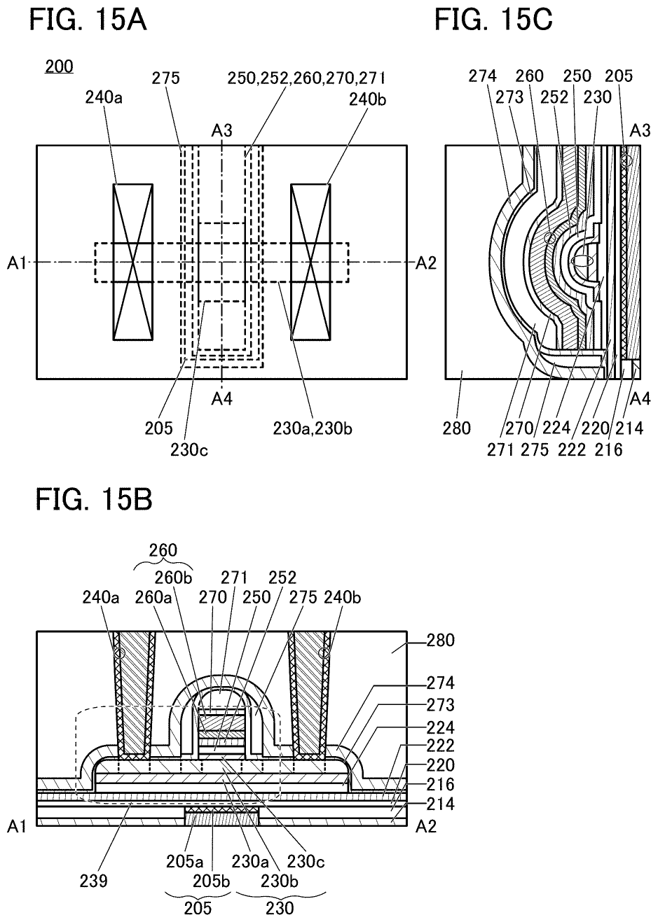

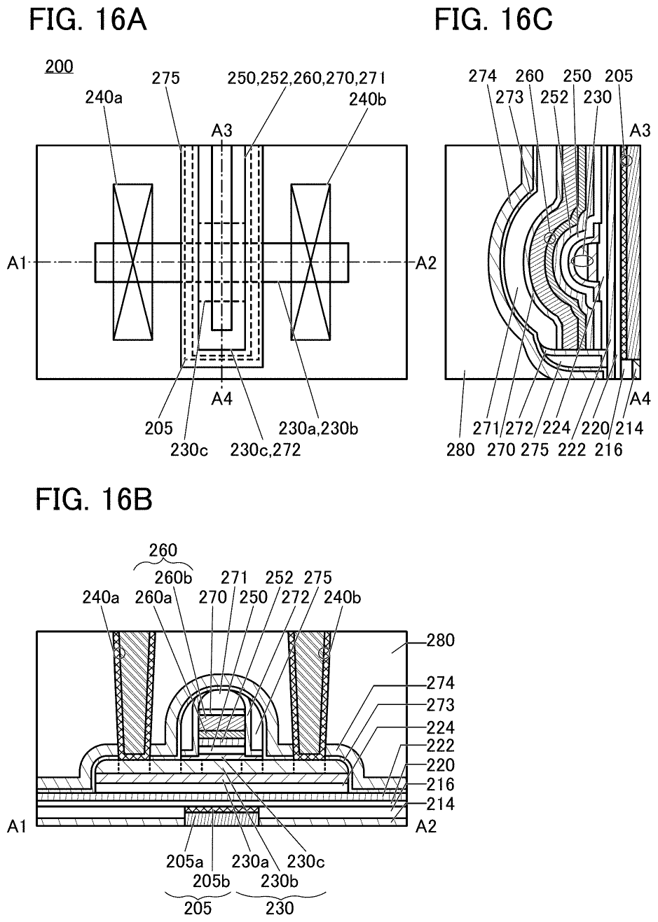

An example of a semiconductor device including the transistor 200 of one embodiment of the present invention will be described below with reference to FIG. 14, FIG. 15, and FIG. 16.

Figures (A) are top views of the semiconductor device including the transistor 200. Figures (B) and figures (C) are cross-sectional views of the semiconductor device. Here, figures (B) are cross-sectional views of a portion indicated by a dashed-dotted line A1-A2 in figures (A), and are cross-sectional views in the channel length direction of the transistor 200. Figures (C) are cross-sectional views of a portion indicated by a dashed-dotted line A3-A4 in figures (A), and are cross-sectional views in the channel width direction of the transistor 200. For clarity of the drawing, some components are not illustrated in the top views of figures (A).

Note that in the semiconductor device illustrated in FIG. 14, FIG. 15, and FIG. 16, components having the same functions as the components in the semiconductor device described in <Structure example of semiconductor device> are denoted by the same reference numerals.

The structure of the transistor 200 will be described with reference to FIG. 14, FIG. 15, and FIG. 16 below. Note that also in this section, the materials described in detail in <Structure example of semiconductor device> can be used as the materials for the transistor 200.

### Modification Example 1 of Semiconductor Device

The transistor 200 illustrated in FIG. 14 is different from the semiconductor device described in <Structure example of semiconductor device> at least in that the insulator 273 is not provided and the insulator 272 functioning as a side barrier is provided.

Specifically, as illustrated in FIG. 14, the oxide 230 includes a region directly in contact with the insulator 274. For example, in the case where the insulator 274 contains less impurities or the insulator 274 is deposited to be thin, when the insulator 274 is directly in contact with the oxide 230 without the insulator 273 therebetween, the resistances of the region 231 and the region 232 of the oxide 230 can be reduced.

Note that the insulator 272 can be formed by removing a region of the insulating film 273A which does not overlap with the insulator 275 and the conductor 260. Here, the insulator 271 is formed over the insulator 270, whereby the insulator 270 can remain even when portions of the insulating film 273A that are over the insulator 270 are removed. In addition, when the height of a structure body composed of the insulator 250, the insulator 252, the conductor 260, the insulator 270, and the insulator 271 is larger than the height of the oxide 230, the insulating film 273A on the side surface of the oxide 230 can be removed. Furthermore, when the end portions of the oxide 230a and the oxide 230b each have a rounded shape, time taken to remove the insulating film 273A deposited on the side surfaces of the oxide 230a and the oxide 230b with the oxide 230c therebetween can be shortened, leading to easier formation of the insulator 272.

Although not illustrated, the insulating film 273A may remain also on the side surface of the oxide 230. In that case, coverage with an interlayer film or the like to be deposited in a later step can be improved. When the insulator remains on the side surface of the oxide 230, entry of impurities such as water or hydrogen into the oxide 230 can be reduced and outward diffusion of oxygen from the oxide 230 can be prevented, in some cases.

### Modification Example 2 of Semiconductor Device

The transistor 200 illustrated in FIG. 15 is different from the semiconductor device described in <Structure example of semiconductor device> at least in the shape of the oxide 230c.

Specifically, as illustrated in FIG. 15, the side surface of the oxide 230c may have a surface which is on the same surface as the side surface of the conductor 260, the side surface of the insulator 250, and the side surface of the insulator 252.

Note that the oxide 230c can be processed using the insulator 250, the insulator 252, and the conductor 260 as masks. When the oxide 230c over the region 236 is removed, the oxide 230b with a high conductivity is in contact with the conductor 260, so that a sufficient ohmic contact therebetween can be made.

### Modification Example 3 of Semiconductor Device

The transistor 200 illustrated in FIG. 16 is different from the semiconductor device illustrated in FIG. 15 at least in that the insulator 272 functioning as a side barrier and the insulator 273 functioning as a buffer layer are separately formed. The shape of the oxide 230c is also different.

Specifically, as illustrated in FIG. 16, the side surface of the oxide 230c may have a surface which is on the same surface as the side surface of the insulator 272. In addition, the insulator 273 functioning as a buffer layer and covering the insulator 275 and the oxide 230 is included.

Note that the oxide 230c and the insulator 272 can be processed using the insulator 275 and the conductor 260 as masks. When the oxide 230c over the region 236 is removed, the oxide 230b with a high conductivity is in contact with the conductor 260, so that a sufficient ohmic contact therebetween can be made.

### Modification Example 4 of Semiconductor Device

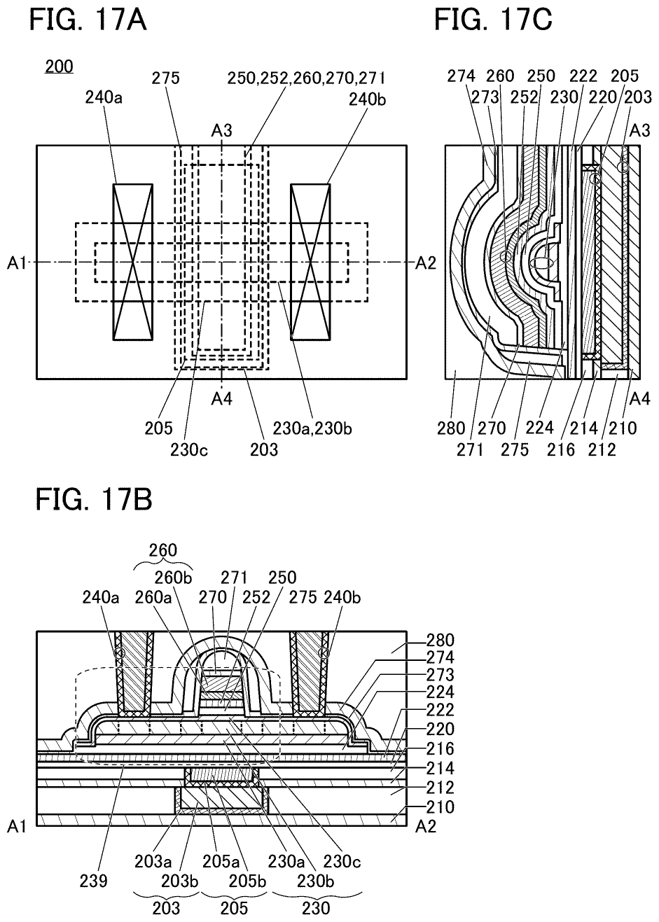

The transistor 200 illustrated in FIG. 17 is different from the semiconductor device illustrated in FIG. 1 at least in the shapes of the side surface of the insulator 250, the side surface of the insulator 252, the side surface of the conductor 260, and the side surface of the insulator 270.

Specifically, as illustrated in FIG. 17, the side surface of the insulator 250, the side surface of the insulator 252, the side surface of the conductor 260, and the side surface of the insulator 270 may have a taper angle with respect to the top surface of the oxide 230. With the shape, the coverage with the insulator 273 and the insulator 274 can be improved.

The composition, structure, method, and the like described above in this embodiment can be used in combination as appropriate with the compositions, structures, methods, and the like described in the other embodiments.

### Embodiment 2

An example of a semiconductor device including the transistor 200 of one embodiment of the present invention will be described below.

### <Structure Example of Semiconductor Device>

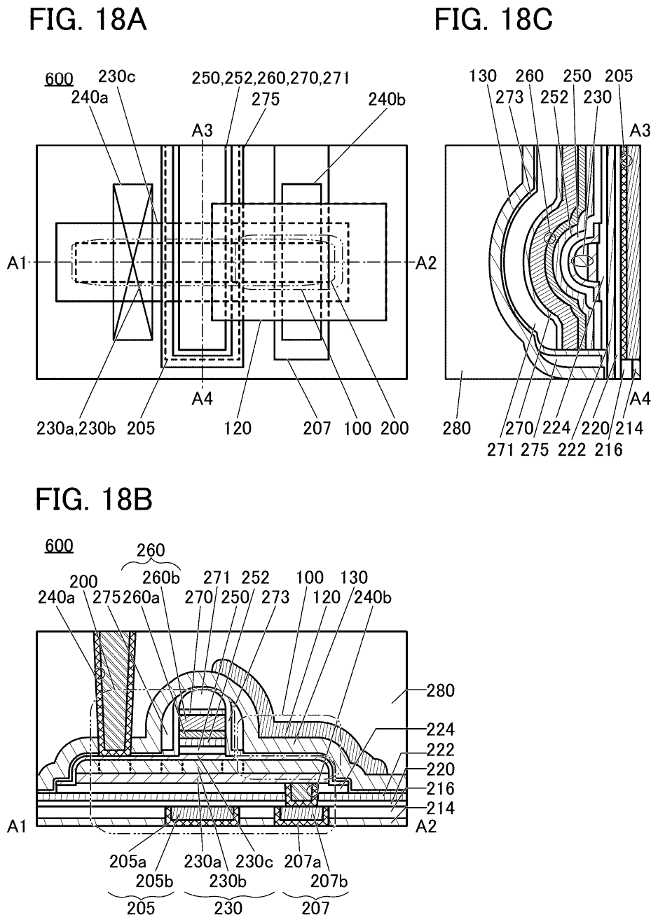

FIG. 18(A), FIG. 18(B), and FIG. 18(C) are a top view and cross-sectional views of the transistor 200, a capacitor 100, and the periphery of the transistor 200 of one embodiment of the present invention. Note that in this specification, a memory device including one capacitor and at least one transistor is referred to as a cell.

FIG. 18(A) is a top view of a cell 600 including the transistor 200 and the capacitor 100. FIG. 18(B) and FIG. 18(C) are cross-sectional views of the cell 600. Here, FIG. 18(B) is a cross-sectional view of a portion indicated by a dashed-dotted line A1-A2 in FIG. 18(A), and is a cross-sectional view in the channel length direction of the transistor 200. FIG. 18(C) is a cross-sectional view of a portion indicated by a dashed-dotted line A3-A4 in FIG. 18(A), and is a cross-sectional view in the channel width direction of the transistor 200. For clarity of the drawing, some components are not illustrated in the top view of FIG. 18(A).

### [Cell 600]

The semiconductor device of one embodiment of the present invention includes the transistor 200, the capacitor 100, and the insulator 280 functioning as an interlayer film. The conductor 240 (the conductor 240a and the conductor 240b) functioning as a plug and being electrically connected to the transistor 200 is also included.

The transistor 200 and the capacitor 100 are provided in the same layer in the cell 600 illustrated in FIG. 18, whereby some of the components included in the transistor 200 and some of the components included in the capacitor 100 can be used in common. That is, some of the components of the transistor 200 function as part of the components of the capacitor 100 in some cases.

Furthermore, part or the whole of the capacitor 100 overlaps with the transistor 200, so that the total area of the projected area of the transistor 200 and the projected area of the capacitor 100 can be reduced.

Furthermore, the conductor 240b and a conductor 207 (a conductor 207a and a conductor 207b) functioning as plugs or wirings electrically connected to the transistor 200 are provided below a region where the capacitor 100 and the transistor 200 overlap with each other, so that the cell 600 can be easily miniaturized or highly integrated. Moreover, since the conductor 207 can be formed in the same step as the conductor 205, which is part of the components of the transistor 200, the process can be shortened.

Note that the layouts of the transistor 200 and the capacitor 100 can be designed as appropriate depending on the required capacitance value of the capacitor 100.

For example, the area of the capacitor 100 is determined depending on the area where the region 231b of the oxide 230 and a conductor 120 overlap with each other with an insulator 130 therebetween. That is, in the case where the capacitance value required for the cell 600 cannot be obtained by the capacitor 100 illustrated in FIG. 18(A) and FIG. 18(B), the widths of the regions 231b of the oxide 230a and the oxide 230b in the A3-A4 direction are made larger than the widths of the regions 234 of the oxide 230a and the oxide 230b in the A3-A4 direction, which can increase the capacitance value.

For example, the length of the region 231b of the oxide 230 in the A1-A2 direction may be longer than the length of the conductor 120 in the A1-A2 direction. In that case, the conductor 240b can be embedded in the insulator 280. That is, the region 231b of the oxide 230 and the conductor 240b may be provided in contact with each other in a region where the region 231b of the oxide 230 and the conductor 120 do not overlap with each other. Thus, by forming the conductor 240a and the conductor 240b in the same step, the process can be shortened.

With the above structure, miniaturization or high integration can be achieved. Moreover, the design flexibility can be increased. Furthermore, the transistor 200 and the capacitor 100 are formed through the same process. Accordingly, the process can be shortened, leading to an improvement in productivity.

### [Transistor 200]

The structure of the transistor included in the semiconductor device described in the above embodiment can be used as the structure of the transistor 200. Note that the transistor 200 illustrated in FIG. 18 is an example and the structure is not limited thereto; an appropriate transistor is used in accordance with a circuit configuration or a driving method.

For example, the insulator 275 is preferably provided in the transistor 200. With the structure, parasitic capacitance generated between the conductor 120 functioning as the electrode of the capacitor 100 and the conductor 260 functioning as the gate electrode of the transistor 200 can be reduced. Therefore, a material having a low dielectric constant is preferably used for the insulator 275. For example, the dielectric constant of the insulator 275 is preferably lower than 4, further preferably lower than 3. For the insulator 275, silicon oxide or silicon oxynitride can be used, for example. The reduction in the parasitic capacitance leads to high-speed operation of the transistor 200.

### [Capacitor 100]

As illustrated in FIG. 18, the capacitor 100 has a structure including some components shared with the transistor 200. This embodiment describes an example of the capacitor 100 in which the region 231b provided in the oxide 230 of the transistor 200 functions as one electrode of the capacitor 100.

The capacitor 100 includes the region 231b of the oxide 230, the insulator 130 over the region 231, and the conductor 120 over the insulator 130. Moreover, the conductor 120 is preferably positioned over the insulator 130 to at least partly overlap with the region 231b of the oxide 230.

The region 231b of the oxide 230 functions as one electrode of the capacitor 100, and the conductor 120 functions as the other electrode of the capacitor 100. The insulator 130 functions as a dielectric of the capacitor 100. The region 231b of the oxide 230 has a reduced resistance and is a conductive oxide. Thus, the region 231b of the oxide 230 can function as one electrode of the capacitor 100.

Note that an insulator corresponding to the insulator 273 and the insulator 274 in the above-described transistor may be processed to provide the insulator 130. The insulator 130 (the insulator corresponding to the insulator 273 and the insulator 274) may remain in contact with the transistor 200 and the insulator 224.

Alternatively, by addition of a dopant to the region 231 of the oxide 230 by an ion doping method, plasma treatment, or the like, the insulator 130 may be separately provided as a dielectric, without provision of the insulator corresponding to the insulator 274. For the insulator 130, a single layer or a stacked layer of aluminum oxide or silicon oxynitride can be used, for example.

For the conductor 120, a conductive material containing tungsten, copper, or aluminum as its main component is preferably used. Although not illustrated, the conductor 120 may have a stacked-layer structure, for example, a stacked layer of any of the above conductive materials and titanium or titanium nitride.

### <Structure of Cell Array>

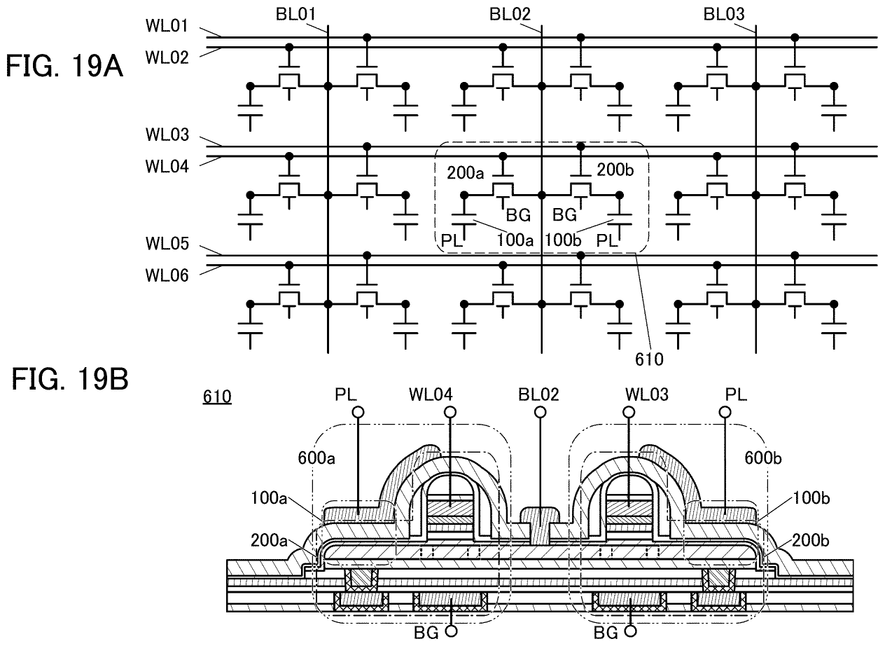

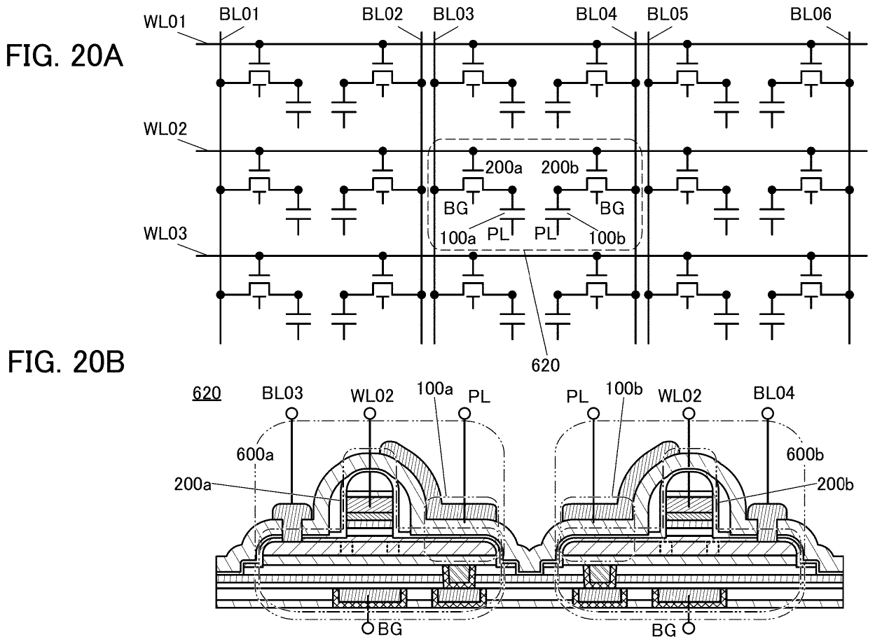

Here, FIG. 19 and FIG. 20 each illustrate an example of a cell array of this embodiment. For example, the cells 600 each including the transistor 200 and the capacitor 100 illustrated in FIG. 17 are arranged in a matrix, whereby a cell array can be formed.

FIG. 19(A) is a circuit diagram showing an embodiment in which the cells 600 illustrated in FIG. 17 are arranged in a matrix. In FIG. 19(A), one of the source and the drain of the transistors included in the cells 600 which are adjacent in the row direction are electrically connected to common BLs (BL01, BL02, and BL03). Furthermore, the BLs are also electrically connected to one of the source and the drain of each of the transistors included in the cells 600 arranged in the column direction. In contrast, the first gates of the transistors included in the cells 600 which are adjacent in the row direction are electrically connected to different WLs (WL01 to WL06). In addition, the transistors included in the cells 600 may each be provided with a second gate BG. The threshold voltage of the transistor can be controlled by a potential applied to BG. The first electrode of the capacitor included in the cell 600 is electrically connected to the other of the source and the drain of the transistor. At this time, the first electrode of the capacitor is formed of part of components included in the transistor. In addition, the second electrode of the capacitor included in the cell 600 is electrically connected to PL.

FIG. 19(B) is a cross-sectional view which extracts part of the row including a circuit 610 including a cell 600a electrically connected to WL04 and BL02 and a cell 600b electrically connected to WL03 and BL02 in FIG. 19(A). FIG. 19(B) illustrates a cross-sectional view of the cell 600a and the cell 600b.

The cell 600a includes a transistor 200a and a capacitor 100a. The cell 600b includes a transistor 200b and a capacitor 100b.

One of a source and a drain of the transistor 200a and one of a source and a drain of the transistor 200b are both electrically connected to BL02.

Sharing a wiring which is electrically connected to one of the source and the drain of each transistor as in the above structure can further reduce the area occupied by the cell array.

FIG. 20(A) is a circuit diagram showing an embodiment, which is different from that in FIG. 19(A), in which the cells 600 illustrated in FIG. 17 are arranged in a matrix. In FIG. 20(A), first gates of the transistors included in the cells 600 arranged in the row direction are electrically connected to common WLs (WL01, WL02, and WL03). Furthermore, one of a source and a drain of the transistors included in the cells arranged in the column direction are electrically connected to common BLs (BL01 to BL06). In addition, the transistors included in the cells 600 may each be provided with a second gate BG. The threshold voltage of the transistor can be controlled by a potential applied to BG. The first electrode of the capacitor included in the cell 600 is electrically connected to the other of the source and the drain of the transistor. At this time, the first electrode of the capacitor is formed of part of components included in the transistor. In addition, the second electrode of the capacitor included in the cell 600 is electrically connected to PL.

FIG. 20(B) is a cross-sectional view which extracts part of the row including a circuit 620 including the cell 600a electrically connected to WL02 and BL03 and the cell 600b electrically connected to WL02 and BL04 in FIG. 20(A). FIG. 20(B) illustrates a cross-sectional view of the cell 600a and the cell 600b.

The cell 600a includes the transistor 200a and the capacitor 100a. The cell 600b includes the transistor 200b and the capacitor 100b.

The composition, structure, method, and the like described above in this embodiment can be used in combination as appropriate with the compositions, structures, methods, and the like described in the other embodiments.

### Embodiment 3

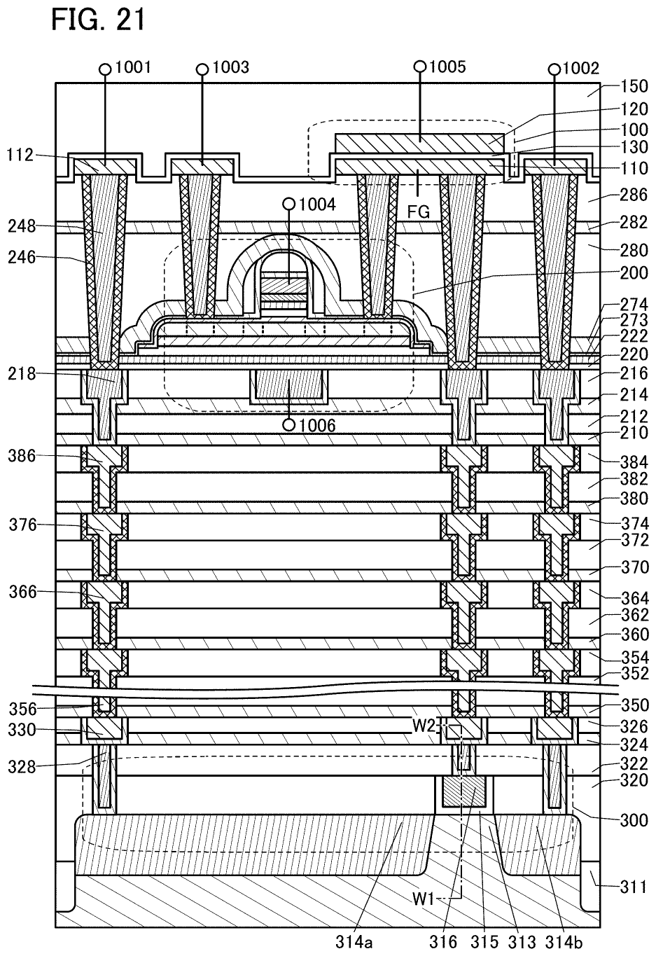

In this embodiment, embodiments of semiconductor devices will be described with reference to FIG. 21 to FIG. 24.

### <Memory Device 1>

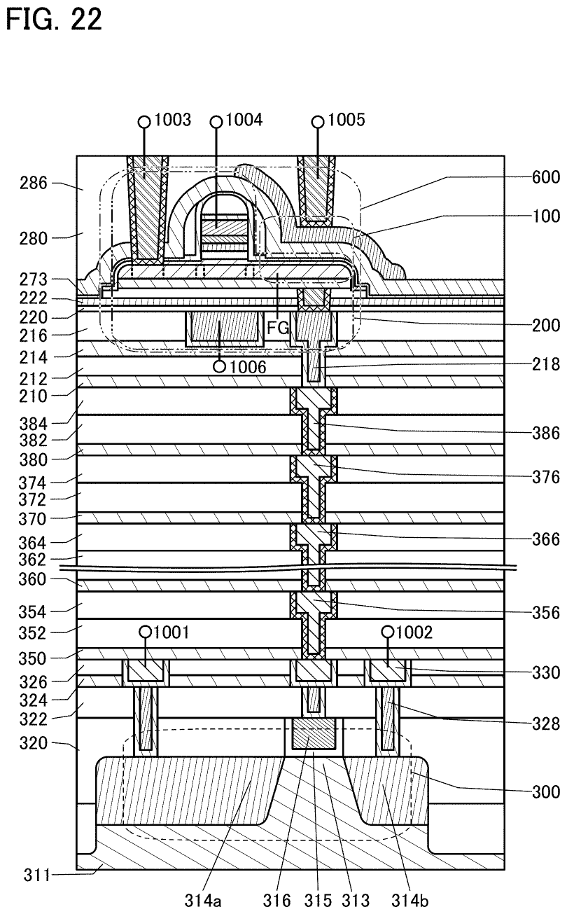

A memory device illustrated in FIG. 21 and FIG. 22 each include a transistor 300, the transistor 200, and the capacitor 100.

The transistor 200 is a transistor in which a channel is formed in a semiconductor layer including an oxide semiconductor. Since the off-state current of the transistor 200 is small, a memory device using the transistor can retain stored contents for a long time. In other words, since refresh operation is not required or frequency of refresh operation is extremely low, the power consumption of the memory device can be sufficiently reduced.

In the memory devices illustrated in FIG. 21 and FIG. 22, a wiring 1001 is electrically connected to a source of the transistor 300 and a wiring 1002 is electrically connected to a drain of the transistor 300. Furthermore, a wiring 1003 is electrically connected to one of the source and the drain of the transistor 200, a wiring 1004 is electrically connected to the first gate of the transistor 200, and a wiring 1006 is electrically connected to the second gate of the transistor 200. In addition, a gate of the transistor 300 and the other of the source and the drain of the transistor 200 are electrically connected to one electrode of the capacitor 100, and a wiring 1005 is electrically connected to the other electrode of the capacitor 100.

The memory devices illustrated in FIG. 21 and FIG. 22 have a feature that the potential of the gate of the transistor 300 can be retained, and thus enable writing, retaining, and reading of data as follows.

Writing and retaining of data are described. First, the potential of the wiring 1004 is set to a potential at which the transistor 200 is in a conduction state, so that the transistor 200 is brought into a conduction state. Accordingly, the potential of the wiring 1003 is supplied to a node FG where the gate of the transistor 300 and the one electrode of the capacitor 100 are electrically connected to each other. That is, a predetermined charge is supplied to the gate of the transistor 300 (writing). Here, one of charges providing two different potential levels (hereinafter, referred to as Low-level charge and High-level charge) is supplied. After that, the potential of the wiring 1004 is set to a potential at which the transistor 200 is in a non-conduction state, so that the transistor 200 is brought into a non-conduction state; thus, the charge is retained in the node FG (retaining).

In the case where the off-state current of the transistor 200 is small, the charge in the node FG is retained for a long time.

Next, reading of data is described. An appropriate potential (reading potential) is supplied to the wiring 1005 while a predetermined potential (constant potential) is supplied to the wiring 1001, whereby the wiring 1002 has a potential corresponding to the amount of charge retained in the node FG. This is because when the transistor 300 is of an n-channel type, an apparent threshold voltage V_{th_H} at the time when the High-level charge is supplied to the gate of the transistor 300 is lower than an apparent threshold voltage V_{th_L} at the time when the Low-level charge is supplied to the gate of the transistor 300. Here, an apparent threshold voltage refers to the potential of the wiring 1005 that is needed to bring the transistor 300 into a conduction state. Thus, the potential of the wiring 1005 is set to a potential V₀ that is between V_{th_H} and V_{th_L}, whereby the charge supplied to the node FG can be determined. For example, in the case where the High-level charge is supplied to the node FG in writing, the transistor 300 is in a conduction state when the potential of the wiring 1005 becomes V₀ (>V_{th_H}). On the other hand, in the case where the Low-level charge is supplied to the node FG, the transistor 300 remains in a non-conduction state even when the potential of the wiring 1005 becomes V₀ (<V_{th_L}). Thus, the data retained in the node FG can be read by determining the potential of the wiring 1002.

### <Structure of Memory Device 1>

The memory device of one embodiment of the present invention includes the transistor 300, the transistor 200, and the capacitor 100 as illustrated in FIG. 21. The transistor 200 is provided above the transistor 300, and the capacitor 100 is provided above the transistor 300 and the transistor 200.

The transistor 300 is provided over a substrate 311 and includes a conductor 316, an insulator 315, a semiconductor region 313 that is part of the substrate 311, and a low-resistance region 314a and a low-resistance region 314b functioning as a source region and a drain region.

The transistor 300 is of either a p-channel type or an n-channel type.

A region of the semiconductor region 313 where a channel is formed, a region in the vicinity thereof, the low-resistance region 314a and the low-resistance region 314b functioning as the source region and the drain region, and the like preferably include a semiconductor such as a silicon-based semiconductor, and preferably include single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing may be used. Alternatively, the transistor 300 may be a HEMT (High Electron Mobility Transistor) with the use of GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to a semiconductor material used for the semiconductor region 313.

For the conductor 316 functioning as a gate electrode, a semiconductor material such as silicon containing an element that imparts n-type conductivity, such as arsenic or phosphorus, or an element that imparts p-type conductivity, such as boron; or a conductive material such as a metal material, an alloy material, or a metal oxide material can be used.

Note that the work function is determined by a material for the conductor, whereby the threshold voltage can be adjusted by changing the material for the conductor. Specifically, it is preferable to use a material such as titanium nitride or tantalum nitride for the conductor. Moreover, in order to ensure both conductivity and embeddability, it is preferable to use a stacked layer of metal materials such as tungsten and aluminum as the conductor, and it is particularly preferable to use tungsten in terms of heat resistance.

Note that the transistor 300 illustrated in FIG. 21 is an example and the structure is not limited thereto; an appropriate transistor is used in accordance with a circuit configuration or a driving method.

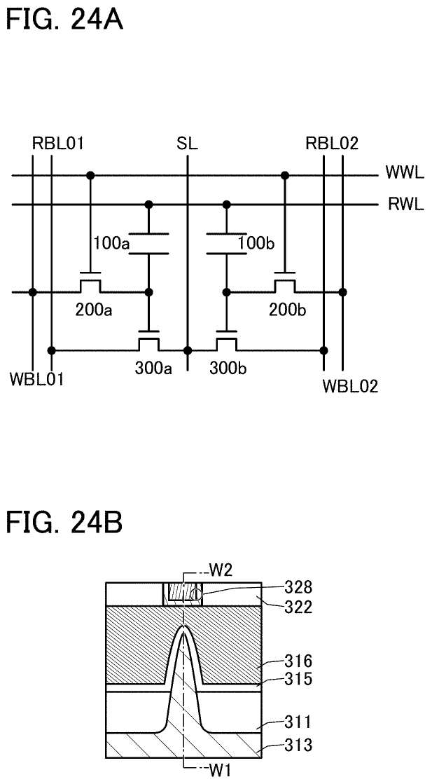

Here, FIG. 24(B) illustrates a cross-sectional view of the transistor 300 in the W width direction indicated by W1-W2 in FIG. 21. As illustrated in FIG. 24(B), the transistor 300 has a convex shape in the semiconductor region 313 (part of the substrate 311) where a channel is formed. Furthermore, the conductor 316 is provided to cover the side surfaces and the top surface of the semiconductor region 313 with the insulator 315 therebetween. Note that for the conductor 316, a material that adjusts the work function may be used. Such a transistor 300 is also referred to as a FIN-type transistor because it utilizes a convex portion of the semiconductor substrate. Note that an insulator functioning as a mask for forming the convex portion may be included in contact with an upper portion of the convex portion. Furthermore, although the case where the convex portion is formed by processing part of the semiconductor substrate is described here, a semiconductor film having a convex shape may be formed by processing an SOI substrate.

An insulator 320, an insulator 322, an insulator 324, and an insulator 326 are provided to be stacked in this order to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride is used, for example.

The insulator 322 may have a function of a planarization film for planarizing a level difference caused by the transistor 300 or the like provided thereunder. For example, the top surface of the insulator 322 may be planarized by planarization treatment using a chemical mechanical polishing (CMP) method or the like to improve planarity.

Furthermore, as the insulator 324, a film having a barrier property that inhibits diffusion of hydrogen and impurities from the substrate 311, the transistor 300, or the like into a region where the transistor 200 is provided is preferably used.

As an example of the film having a barrier property against hydrogen, silicon nitride formed by a CVD method can be used. Here, diffusion of hydrogen into a semiconductor element including an oxide semiconductor, such as the transistor 200, degrades the characteristics of the semiconductor element in some cases. Thus, a film that inhibits the diffusion of hydrogen is preferably used between the transistor 200 and the transistor 300. The film that inhibits diffusion of hydrogen is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per area of the insulator 324 is smaller than or equal to 10×10¹⁵ atoms/cm², preferably smaller than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. Furthermore, for example, the dielectric constant of the insulator 326 is preferably 0.7 times or less, further preferably 0.6 times or less the dielectric constant of the insulator 324. When a material with a low permittivity is used for an interlayer film, the parasitic capacitance generated between wirings can be reduced.

Furthermore, a conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 each have a function of a plug or a wiring. In addition, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

As a material for each of plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 21, an insulator 350, an insulator 352, and an insulator 354 are provided to be stacked in this order. Furthermore, a conductor 356 is formed in the insulator 350, the insulator 352, and the insulator 354. The conductor 356 has a function of a plug or a wiring. Note that the conductor 356 can be provided using a material similar to those for the conductor 328 and the conductor 330.

Note that for example, as the insulator 350, an insulator having a barrier property against hydrogen is preferably used, as with the insulator 324. Furthermore, the conductor 356 preferably includes a conductor having a barrier property against hydrogen. In particular, the conductor having a barrier property against hydrogen is formed in an opening portion of the insulator 350 having a barrier property against hydrogen. With this structure, the transistor 300 can be separated from the transistor 200 by a barrier layer, so that the diffusion of hydrogen from the transistor 300 into the transistor 200 can be inhibited.

Note that as the conductor having a barrier property against hydrogen, tantalum nitride is preferably used, for example. Furthermore, by stacking tantalum nitride and tungsten, which has high conductivity, the diffusion of hydrogen from the transistor 300 can be inhibited while the conductivity as a wiring is kept. In that case, a structure in which a tantalum nitride layer having a barrier property against hydrogen is in contact with the insulator 350 having a barrier property against hydrogen is preferable.

A wiring layer may be provided over the insulator 350 and the conductor 356. For example, in FIG. 21, an insulator 360, an insulator 362, and an insulator 364 are provided to be stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, an insulator having a barrier property against hydrogen is preferably used, as with the insulator 324. Furthermore, the conductor 366 preferably includes a conductor having a barrier property against hydrogen. In particular, the conductor having a barrier property against hydrogen is formed in an opening portion included in the insulator 360 having a barrier property against hydrogen. With this structure, the transistor 300 can be separated from the transistor 200 by a barrier layer, so that the diffusion of hydrogen from the transistor 300 into the transistor 200 can be inhibited.

A wiring layer may be provided over the insulator 364 and the conductor 366. For example, in FIG. 21, an insulator 370, an insulator 372, and an insulator 374 are provided to be stacked in this order. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, an insulator having a barrier property against hydrogen is preferably used, as with the insulator 324. Furthermore, the conductor 376 preferably includes a conductor having a barrier property against hydrogen. In particular, the conductor having a barrier property against hydrogen is formed in an opening portion of the insulator 370 having a barrier property against hydrogen. With this structure, the transistor 300 can be separated from the transistor 200 by a barrier layer, so that the diffusion of hydrogen from the transistor 300 into the transistor 200 can be inhibited.

A wiring layer may be provided over the insulator 374 and the conductor 376. For example, in FIG. 21, an insulator 380, an insulator 382, and an insulator 384 are provided to be stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, an insulator having a barrier property against hydrogen is preferably used, as with the insulator 324. Furthermore, the conductor 386 preferably includes a conductor having a barrier property against hydrogen. In particular, the conductor having a barrier property against hydrogen is formed in an opening portion included in the insulator 380 having a barrier property against hydrogen. With this structure, the transistor 300 can be separated from the transistor 200 by a barrier layer, so that the diffusion of hydrogen from the transistor 300 into the transistor 200 can be inhibited.

The insulator 210, the insulator 212, the insulator 214, and the insulator 216 are provided to be stacked in this order over the insulator 384. A substance having a barrier property against oxygen or hydrogen is preferably used for one of the insulator 210, the insulator 212, the insulator 214, and the insulator 216.

As the insulator 210 and the insulator 214, for example, a film having a barrier property that inhibits diffusion of hydrogen and impurities from the substrate 311, a region where the transistor 300 is provided, or the like into the region where the transistor 200 is provided is preferably used. Thus, a material similar to that for the insulator 324 can be used.

Furthermore, as an example of the film having a barrier property against hydrogen, silicon nitride formed by a CVD method can be used. Here, diffusion of hydrogen into a semiconductor element including an oxide semiconductor, such as the transistor 200, degrades the characteristics of the semiconductor element in some cases. Thus, a film that inhibits the diffusion of hydrogen is preferably used between the transistor 200 and the transistor 300. The film that inhibits the diffusion of hydrogen is specifically a film from which a small amount of hydrogen is released.

Furthermore, as the film having a barrier property against hydrogen, for example, as the insulator 210 and the insulator 214, a metal oxide such as aluminum oxide, hafnium oxide, or tantalum oxide is preferably used.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a fabrication process and after the fabrication of the transistor. Furthermore, release of oxygen from the oxide included in the transistor 200 can be inhibited. Thus, aluminum oxide is suitably used as a protective film for the transistor 200.

Furthermore, for example, a material similar to that for the insulator 320 can be used for the insulator 212 and the insulator 216. Furthermore, when a material with a relatively low permittivity is used for an interlayer film, the parasitic capacitance generated between wirings can be reduced. For example, as the insulator 212 and the insulator 216, a silicon oxide film or a silicon oxynitride film can be used.

A conductor 218, a conductor included in the transistor 200, and the like are embedded in the insulator 210, the insulator 212, the insulator 214, and the insulator 216. Note that the conductor 218 has a function of a plug or a wiring that is electrically connected to the capacitor 100 or the transistor 300. The conductor 218 can be provided using a material similar to those for the conductor 328 and the conductor 330.

In particular, the conductor 218 in a region in contact with the insulator 210 and the insulator 214 is preferably a conductor having a barrier property against oxygen, hydrogen, and water. With this structure, the transistor 300 can be separated from the transistor 200 by a layer having a barrier property against oxygen, hydrogen, and water, so that the diffusion of hydrogen from the transistor 300 into the transistor 200 can be inhibited.

The transistor 200 is provided above the insulator 216. Note that the structure of the transistor included in the semiconductor device described in the above embodiment can be used as that of the transistor 200. Note that the transistor 200 illustrated in FIG. 21 is an example and the structure is not limited thereto; an appropriate transistor is used in accordance with a circuit configuration or a driving method.

The insulator 280 is provided above the transistor 200.

An insulator 282 is provided over the insulator 280. A substance having a barrier property against oxygen or hydrogen is preferably used for the insulator 282. Thus, for the insulator 282, a material similar to that used for the insulator 214 can be used. For the insulator 282, a metal oxide such as aluminum oxide, hafnium oxide, or tantalum oxide is preferably used, for example.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a fabrication process and after the fabrication of the transistor. Furthermore, release of oxygen from the oxide included in the transistor 200 can be inhibited. Thus, aluminum oxide is suitably used as a protective film for the transistor 200.

An insulator 286 is provided over the insulator 282. A material similar to that for the insulator 320 can be used for the insulator 286. Furthermore, when a material with a relatively low permittivity is used for an interlayer film, the parasitic capacitance generated between wirings can be reduced. For example, a silicon oxide film or a silicon oxynitride film can be used as the insulator 286.

A conductor 246, a conductor 248, and the like are embedded in the insulator 220, the insulator 222, the insulator 280, the insulator 282, and the insulator 286.

The conductor 246 and the conductor 248 have a function of a plug or a wiring that is electrically connected to the capacitor 100, the transistor 200, or the transistor 300. The conductor 246 and the conductor 248 can be provided using a material similar to those for the conductor 328 and the conductor 330.

The capacitor 100 is provided above the transistor 200. The capacitor 100 includes a conductor 110, the conductor 120, and the insulator 130.

A conductor 112 may be provided over the conductor 246 and the conductor 248. The conductor 112 has a function of a plug or a wiring that is electrically connected to the capacitor 100, the transistor 200, or the transistor 300. Furthermore, the conductor 110 has a function of the one electrode of the capacitor 100. Note that the conductor 112 and the conductor 110 can be formed at the same time.

For the conductor 112 and the conductor 110, a metal film containing an element selected from molybdenum, titanium, tantalum, tungsten, aluminum, copper, chromium, neodymium, and scandium; a metal nitride film containing any of the above-described elements as its component (a tantalum nitride film, a titanium nitride film, a molybdenum nitride film, or a tungsten nitride film); or the like can be used. Alternatively, a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can also be used.

The conductor 112 and the conductor 110 each having a single-layer structure are illustrated in FIG. 21; however, the structure is not limited thereto, and a stacked-layer structure of two or more layers may be employed. For example, between a conductor having a barrier property and a conductor having a high conductivity, a conductor which is highly adhesive to the conductor having a barrier property and the conductor having high conductivity may be formed.

In addition, as a dielectric of the capacitor 100, the insulator 130 is provided over the conductor 112 and the conductor 110. The insulator 130 can be provided to have a stacked layer or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, a material having high dielectric strength, such as silicon oxynitride, is preferably used for the insulator 130. With the structure, the dielectric strength of the capacitor 100 can be increased and the electrostatic breakdown of the capacitor 100 can be inhibited owing to the insulator 130.

Over the insulator 130, the conductor 120 is provided to overlap with the conductor 110. Note that for the conductor 120, a conductive material such as a metal material, an alloy material, or a metal oxide material can be used. It is preferable to use a high-melting-point material that has both heat resistance and conductivity, such as tungsten or molybdenum, and it is particularly preferable to use tungsten. Furthermore, in the case where the conductor 120 is formed concurrently with another component such as a conductor, Cu (copper), Al (aluminum), or the like, which is a low-resistance metal material, is used.

An insulator 150 is provided over the conductor 120 and the insulator 130. The insulator 150 can be provided using a material similar to that for the insulator 320. Furthermore, the insulator 150 may function as a planarization film that covers uneven shapes thereunder.

With the use of this structure, a change in electrical characteristics can be reduced and reliability can be improved in a memory device using a transistor including an oxide semiconductor. Alternatively, a transistor including an oxide semiconductor and having a large on-state current can be provided. Alternatively, a transistor including an oxide semiconductor and having a small off-state current can be provided. Alternatively, a semiconductor device with reduced power consumption can be provided.

### Modification Example 1 of Memory Device 1

An example of the memory device of one embodiment of the present invention will be described with reference to FIG. 22.

FIG. 22(A) is a cross-sectional view of a memory device including the capacitor 100, the transistor 200, and the transistor 300. Note that in the memory device illustrated in FIG. 22, components having the same functions as the components in the semiconductor device and the memory device described in the above embodiment and <Structure of memory device 1> are denoted by the same reference numerals.

In FIG. 22, the transistor 200 is provided in the cell 600 described in the above embodiment, which is different from the semiconductor device described in <Structure of memory device 1>.

Specifically, as illustrated in FIG. 22, the cell 600 that shares part of the components of the capacitor 100 and part of the components of the transistor 200 is included instead of the capacitor 100 and the transistor 200.

In the above structure, the cell 600 and the transistor 300 partly or entirely overlap with each other, so that the total area of the projected area of the memory device can be reduced. Accordingly, the cell 600 can be easily miniaturized or highly integrated. Furthermore, the process can be shortened.

### Modification Example 2 of Memory Device 1

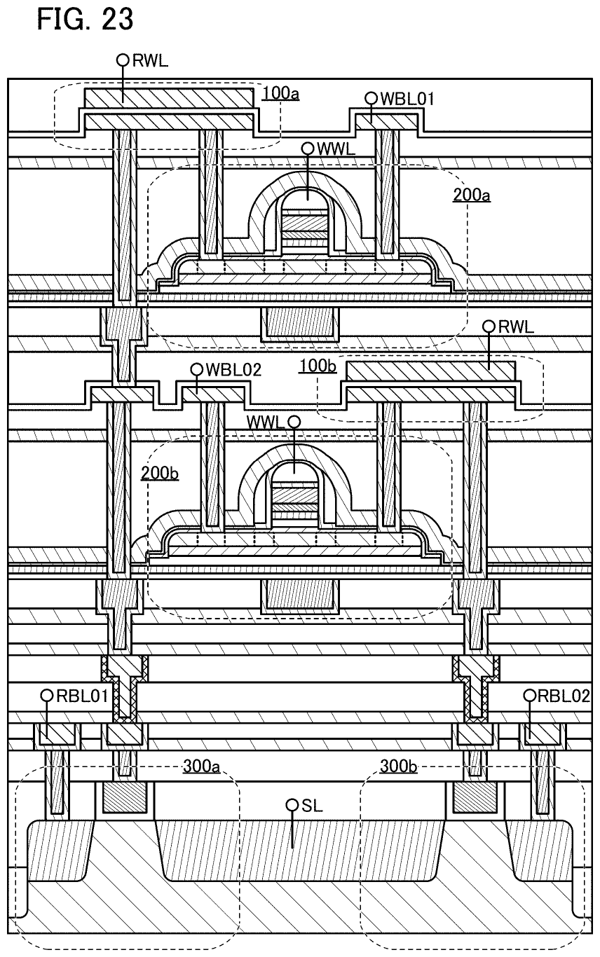

Another example of a modification example of this embodiment is shown in FIG. 23 and FIG. 24(A).

When the memory devices illustrated in FIG. 21 are integrated as memory cells, a memory cell array can be formed. For example, in the circuit diagram shown in FIG. 24(A), a plurality of memory devices are preferably provided so that memory cells are arranged in a matrix. FIG. 23 is an example of a cross-sectional view of the memory cell array in which the transistors 200 are integrated in the memory device illustrated in FIG. 21.

FIG. 23 and FIG. 24(A) each illustrate a memory cell array in which a memory device including a transistor 300a, a transistor 200a, and a capacitor 100a, and a memory device including a transistor 300b, a transistor 200b, and a capacitor 100b are integrated.

For example, as illustrated in FIG. 23, the transistor 200a and the transistor 200b can be provided to overlap with each other. In addition, an SL line shared by the transistor 300a and the transistor 300b can be provided. For example, when the region 314a is provided as the SL line shared by the transistor 300a and the transistor 300b, a wiring and a plug need not to be formed, so that the process can be shortened. Furthermore, this structure enables a reduction in area, higher integration, and miniaturization of the semiconductor device.

At least part of this embodiment can be implemented in combination with the other embodiments described in this specification as appropriate.

### Embodiment 4

An example of a semiconductor device including the capacitor 100, the transistor 200, and a transistor 400 of one embodiment of the present invention will be described below.

### <Structure Example of Semiconductor Device>

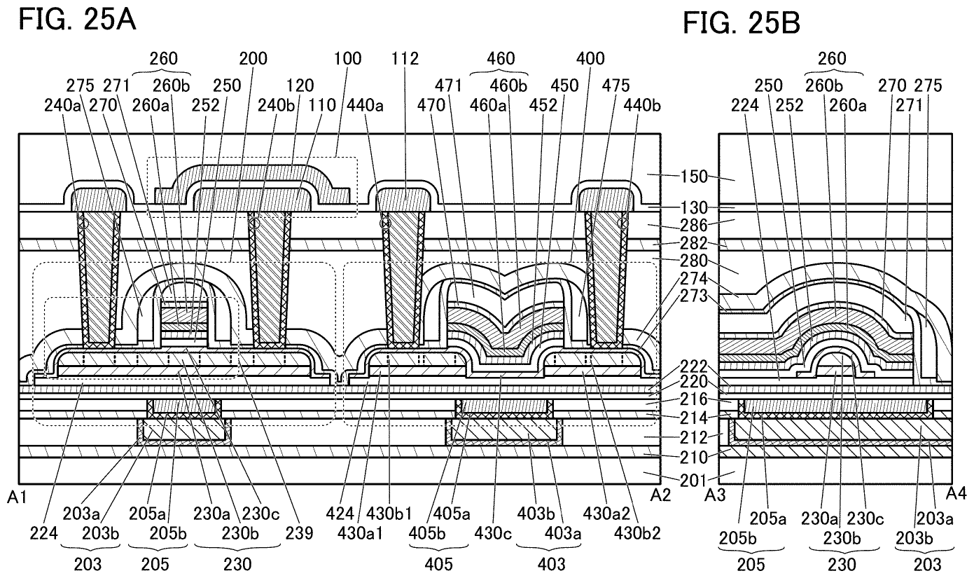

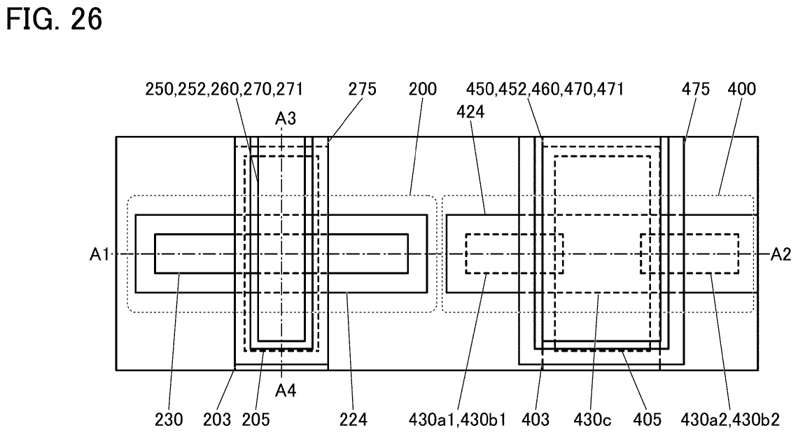

FIG. 25(A) and FIG. 25(B) are cross-sectional views illustrating the periphery of the transistor 200 and the transistor 400 of one embodiment of the present invention, and FIG. 26 is a top view of the semiconductor device. Note that for clarity of the drawing, some components are not illustrated in the top view of FIG. 26.

FIG. 25(A) is a cross-sectional view of a portion indicated by a dashed-dotted line A1-A2 in FIG. 26, and is a cross-sectional view in the channel length direction of the transistor 200 and the transistor 400. FIG. 25(B) is a cross-sectional view of a portion indicated by a dashed-dotted line A3-A4 in FIG. 26, and is a cross-sectional view in the channel width direction of the transistor 200.

The transistor 200 and the transistor 400 which are formed over a substrate 201 have different structures. For example, the transistor 400 can have a structure in which a drain current (Iₒᵤₜ) is smaller than that of the transistor 200 when a back gate potential and a top gate potential are each 0 V. Note that in this specification and the like, Iₒᵤₜ refers to a drain current when the potential of a gate that controls the switching operation of a transistor is 0 V.

For example, a structure is employed in which the transistor 400 is used as a switching element to control the potential of a back gate of the transistor 200. Thus, a charge at a node connected to the back gate of the transistor 200 can be inhibited from being lost by making the node connected to the back gate of the transistor 200 have a desired potential and then turning off the transistor 400.

The structure of each of the transistor 200 and the transistor 400 will be described below with reference to FIG. 25 and FIG. 26. Note that the materials of the transistor 200 and the transistor 400 are described in detail in <Material for semiconductor device>.

The semiconductor device of one embodiment of the present invention includes the transistor 200 and the insulator 210, the insulator 212, and the insulator 280 that function as interlayer films. The semiconductor device further includes the conductor 203 (the conductor 203a and the conductor 203b) functioning as a wiring and the conductor 240 (the conductor 240a and the conductor 240b) functioning as a plug, which are electrically connected to the transistor 200. The semiconductor device further includes a conductor 403 (a conductor 403a and a conductor 403b) functioning as a wiring and a conductor 440 (a conductor 440a and a conductor 440b) functioning as a plug, which are electrically connected to the transistor 400.

Note that in the conductor 203 and the conductor 403, the conductor 203a and the conductor 403a are formed in contact with the inner walls of the openings in the insulator 212, and the conductor 203b and the conductor 403b are formed on the corresponding inner sides. Here, the level of the top surfaces of the conductor 203 and the conductor 403 and the level of the top surface of the insulator 212 can be substantially the same.

The conductor 240 and the conductor 440 are formed in contact with the inner walls of openings in the insulator 280, the insulator 282, and the insulator 286. Here, the level of the top surfaces of the conductor 240 and the conductor 440 and the level of the top surface of the insulator 286 can be substantially the same.

Note that although the conductor functioning as a wiring or a plug is illustrated to have a stacked-layer structure of two layers, the present invention is not limited thereto. For example, a single layer or a stacked-layer structure of three or more layers may be employed.

### [Transistor 200]

As illustrated in FIG. 25, the transistor 200 is a transistor including a metal oxide in its channel formation region, and any of the transistors described in the above embodiment can be used as the transistor 200.

### [Transistor 400]

Next, the transistor 400, which has electrical characteristics different from those of the transistor 200, will be described. The transistor 400 is a transistor that can be fabricated in parallel with the above transistor 200, and is preferably formed in the same layer as the transistor 200. By being fabricated in parallel with the transistor 200, the transistor 400 can be fabricated without an extra step.

As illustrated in FIG. 25(A), the transistor 400 includes the insulator 210 and the insulator 212 positioned over the substrate 201; a conductor 405 (a conductor 405a and a conductor 405b) positioned to be embedded in the insulator 214 and the insulator 216; the insulator 220 positioned over the insulator 216 and the conductor 405; the insulator 222 positioned over the insulator 220; an insulator 424 positioned over the insulator 222; an oxide 430a1 and an oxide 430a2 positioned over the insulator 424; an oxide 430b1 positioned in contact with a top surface of the oxide 430a1; an oxide 430b2 positioned in contact with a top surface of the oxide 430a2; an oxide 430c positioned in contact with a top surface of the insulator 424, side surfaces and the top surfaces of the oxide 430a1 and the oxide 430a2, and side surfaces and top surfaces of the oxide 430b1 and the oxide 430b2; an insulator 450 positioned over the oxide 430c; an insulator 452 positioned over the insulator 450; a conductor 460a positioned over the insulator 452; a conductor 460b positioned over the conductor 460a; an insulator 470 positioned over the conductor 460b; an insulator 471 positioned over the insulator 470; the insulator 273 positioned in contact with side surfaces of the insulator 450, the insulator 452, the conductor 460a, the conductor 460b, the insulator 470, and the insulator 471, and in contact with the oxide 430; an insulator 475 positioned to overlap with the side surface of the conductor 460 with the insulator 273 therebetween; and the insulator 274 positioned over the oxide 430 with the insulator 273 therebetween.

Hereinafter, the oxide 430a1, the oxide 430a2, the oxide 430b1, the oxide 430b2, and the oxide 430c are collectively referred to as the oxide 430 in some cases. Although the transistor 400 having a structure in which the conductor 460a and the conductor 460b are stacked is illustrated, the present invention is not limited thereto. For example, a structure in which only the conductor 460b is provided may be employed.

Here, the conductors, the insulators, and the oxides included in the transistor 400 can be formed in the same process as the conductors, the insulators, and the oxides included in the transistor 200 that is in the same layer as the transistor 400. That is, the conductor 405 (the conductor 405a and the conductor 405b) corresponds to the conductor 205 (the conductor 205a and the conductor 205b); the oxide 430 (the oxide 430a1, the oxide 430a2, the oxide 430b1, the oxide 430b2, and the oxide 430c) corresponds to the oxide 230 (the oxide 230a, the oxide 230b, and the oxide 230c); the insulator 450 corresponds to the insulator 250; the insulator 452 corresponds to the insulator 252; the conductor 460 (the conductor 460a and the conductor 460b) corresponds to the conductor 260 (the conductor 260a and the conductor 260b); the insulator 470 corresponds to the insulator 270; the insulator 471 corresponds to the insulator 271; and the insulator 475 corresponds to the insulator 275. Therefore, the conductors, the insulators, and the oxides included in the transistor 400 can be formed using the same materials as those for the transistor 200, and the components of the transistor 200 can be referred to for the transistor 400.

The oxide 430c is preferably formed to cover the oxide 430a1, the oxide 430b1, the oxide 430a2, and the oxide 430b2. Moreover, a side surface of the oxide 430a1 and a side surface of the oxide 430b1 are preferably substantially aligned with each other, and a side surface of the oxide 430a2 and a side surface of the oxide 430b2 are preferably substantially aligned with each other. For example, the oxide 430c is formed in contact with the side surfaces of the oxide 430a1 and the oxide 430a2, the top surfaces and side surfaces of the oxide 430b1 and the oxide 430b2, and part of the top surface of the insulator 424. Here, when the oxide 430c is seen from above, the side surfaces of the oxide 430c are positioned on the outer side than the side surface of the oxide 430a1 and the side surface of the oxide 430b1, and than the side surface of the oxide 430a2 and the side surface of the oxide 430b2.

The oxides 430a1 and 430b1, and the oxides 430a2 and 430b2 are formed to face each other with the conductor 405, the insulator 450, the insulator 452, and the conductor 460 sandwiched therebetween.

Furthermore, there are curved surfaces between the side surface of the oxide 430b1 and the top surface of the oxide 430b1 and between the side surface of the oxide 430b2 and the top surface of the oxide 430b2. That is, an end portion of the side surface and an end portion of the top surface are preferably curved (hereinafter such a shape is also referred to as a rounded shape). The radius of curvature of the curved surface of the end portions of the oxide 430b1 or the oxide 430b2, for example, is preferably greater than or equal to 3 nm and less than or equal to 10 nm, further preferably greater than or equal to 5 nm and less than or equal to 6 nm.

The oxide 430 includes a region overlapping with the insulator 275 or the insulator 274 with the insulator 273 therebetween, and the resistance of the region and the vicinity thereof is reduced as in the region 231 and the region 232 of the transistor 200. Furthermore, the oxide 430 includes a region in contact with the conductor 440, and the resistance of the region is reduced as in the region 236 of the transistor 200. Accordingly, the oxide 430a1, the oxide 430b1, and part of the oxide 430c can function as one of a junction region, a source region, and a drain region of the transistor 400, and the oxide 430a2, the oxide 430b2, and the other part of the oxide 430c can function as one of the junction region, and the source region and the drain region of the transistor 400.

A region of the oxide 430c that is sandwiched between the oxides 430a1 and 430b1 and the oxides 430a2 and 430b2 functions as a channel formation region. Here, the distance between the oxides 430a1 and 430b1 and the oxides 430a2 and 430b2 is preferably long; for example, it is preferably longer than the length of the conductor 260 of the transistor 200 in the channel length direction. This can reduce the off-state current of the transistor 400.

The oxide 430c of the transistor 400 can be formed using the same material as that for the oxide 230c of the transistor 200. That is, as the oxide 430c, the metal oxide that can be used as the oxide 230a or the oxide 230b can be used. For example, in the case where an In—Ga—Zn oxide is used as the oxide 430c, the atomic ratio of In to Ga and Zn can be In:Ga:Zn=1:1:1, In:Ga:Zn=1:3:2, In:Ga:Zn=4:2:3, or In:Ga:Zn=1:3:4.

The transistor in which the oxide 430c is used for its channel formation region preferably has electrical characteristics different from those of the transistor in which the oxide 230b is used for its channel formation region. For this reason, for example, the oxide 430c and the oxide 230b are preferably different in any of a material for the oxide, the content ratio of elements contained in the oxide, the film thickness of the oxide, and the width and length of a channel formation region formed in the oxide.

The case where the same metal oxide as that for the oxide 230c is used as the oxide 430c is described below. For example, a metal oxide with a relatively high insulating property and a relatively low atomic proportion of In is preferably used as the oxide 430c. In the case where such a metal oxide is use as the oxide 430c, the atomic proportion of the element M in constituent elements in the oxide 430c can be larger than the atomic proportion of the element M in constituent elements in the oxide 230b. In addition, the atomic ratio of the element M to In in the oxide 430c can be larger than the atomic ratio of the element M to In in the oxide 230b. Accordingly, the threshold voltage of the transistor 400 can be higher than 0 V, the off-state current can be reduced, and the drain current when the gate voltage is 0 V can be extremely low.

In the oxide 430c functioning as a channel formation region of the transistor 400, oxygen vacancies and impurities such as water or hydrogen are preferably reduced as in the oxide 230c of the transistor 200, or the like. Accordingly, the threshold voltage of the transistor 400 can be higher than 0 V, the off-state current can be reduced, and the drain current when the gate voltage is 0 V can be extremely low.

The threshold voltage of the transistor 400 using the oxide 430c is preferably higher than the threshold voltage of the transistor 200 in which a negative potential is not applied to the second gate electrode. In order to make the threshold voltage of the transistor 400 higher than the threshold voltage of the transistor 200, for example, it is preferable that a metal oxide having a relatively higher atomic proportion of In than the metal oxide used for the oxide 230a and the oxide 430c be used as the oxide 230b in the transistor 200.

Furthermore, the distance between the oxides 430a1 and 430b1 and the oxides 430a2 and 430b2 is preferably longer than the width of the region 234 of the transistor 200. In that case, the channel length of the transistor 400 can be longer than the channel length of the transistor 200; thus, the threshold voltage of the transistor 400 can be higher than the threshold voltage of the transistor 200 in which a negative potential is not applied to the second gate electrode.

The channel formation region of the transistor 400 is formed in the oxide 430c, whereas the channel formation region of the transistor 200 is formed in the oxide 230a, the oxide 230b, and the oxide 230c. Accordingly, the film thickness of the oxide 430 in the channel formation region of the transistor 400 can be smaller than the film thickness of the oxide 230 in the channel formation region of the transistor 200. Therefore, the threshold voltage of the transistor 400 can be higher than the threshold voltage of the transistor 200 in which a negative potential is not applied to the second gate electrode.

### [Capacitor 100]

A structure may be employed in which the capacitor 100 is provided over the transistor 200 and the transistor 400. In this embodiment, an example in which the capacitor 100 is formed using the conductor 110 electrically connected to the transistor 200 is described.

The insulator 130 is preferably positioned over the conductor 110 and the plurality of conductors 112. For the insulator 130, a single layer or a stacked layer of aluminum oxide or silicon oxynitride can be used, for example.

Moreover, the conductor 120 is preferably positioned over the insulator 130 to at least partly overlap with the conductor 110. Like the conductor 110 or the like, a conductive material containing tungsten, copper, or aluminum as its main component is preferably used for the conductor 120. Although not illustrated, the conductor 120 may have a stacked-layer structure, for example, a stacked layer of any of the above conductive materials and titanium or titanium nitride. Note that, like the conductor 203 or the like, the conductor 120 may be formed to be embedded in an opening provided in an insulator.

The conductor 110 functions as one electrode of the capacitor 100, and the conductor 120 functions as the other electrode of the capacitor 100. The insulator 130 functions as a dielectric of the capacitor 100.

The insulator 150 is preferably positioned over the insulator 130 and the conductor 120. An insulator that can be used as the insulator 280 can be used as the insulator 150.

### [Circuit Diagram of Semiconductor Device]

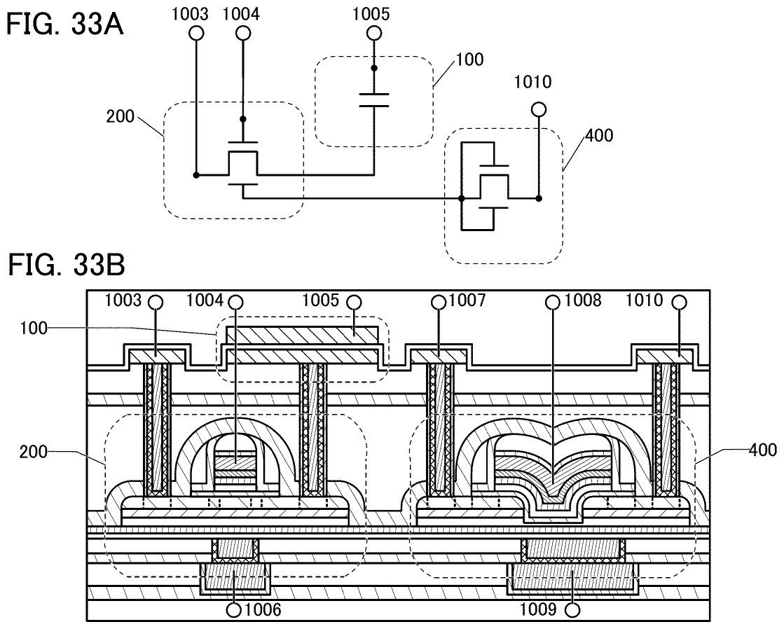

Here, FIG. 33(A) shows a circuit diagram showing an example of the connection relationship of the transistor 200, the transistor 400, and the capacitor 100 in the semiconductor device described in this embodiment. FIG. 33(B) illustrates a cross-sectional view in which a wiring 1003 to a wiring 1010 and the like illustrated in FIG. 33(A) correspond to those illustrated in FIG. 33(A).

As illustrated in FIG. 33(A) and FIG. 33(B), in the transistor 200, the gate is electrically connected to the wiring 1004, one of the source and the drain is electrically connected to the wiring 1003, and the other of the source and the drain is electrically connected to the one electrode of the capacitor 100. The other electrode of the capacitor 100 is electrically connected to the wiring 1005. A drain of the transistor 400 is electrically connected to the wiring 1010. Moreover, as illustrated in FIG. 33(A) and FIG. 33(B), the back gate of the transistor 200 and a source, a top gate, and a back gate of the transistor 400 are electrically connected through the wiring 1006, the wiring 1007, the wiring 1008, and the wiring 1009.

Here, the on state and off state of the transistor 200 can be controlled by application of a potential to the wiring 1004. When the transistor 200 is brought into an on state and a potential is applied to the wiring 1003, charges can be supplied to the capacitor 100 through the transistor 200. At this time, by bringing the transistor 200 into an off state, the charges supplied to the capacitor 100 can be retained. By application of a given potential to the wiring 1005, the potential of a connection portion between the transistor 200 and the capacitor 100 can be controlled by capacitive coupling. For example, when a ground potential is applied to the wiring 1005, the charges are retained easily. Furthermore, by application of a negative potential to the wiring 1010, the negative potential is applied to the back gate of the transistor 200 through the transistor 400, whereby the threshold voltage of the transistor 200 can be higher than 0 V, the off-state current can be reduced, and the drain current when the gate voltage is 0 V can be extremely low.

As illustrated in FIG. 33(A), in the structure in which the top gate and the back gate of the transistor 400 are connected to the source (diode connection), and the source of the transistor 400 and the back gate of the transistor 200 are connected, the back-gate potential of the transistor 200 can be controlled by the wiring 1010. When the negative potential of the back gate of the transistor 200 is retained, the top gate-source potential difference and the back gate-source potential difference of the transistor 400 each become 0 V. Since the drain current when the gate voltage of the transistor 400 is 0 V is extremely low and the threshold voltage of the transistor 400 is higher than that of the transistor 200, this structure allows the negative potential of the back gate of the transistor 200 to be retained for a long time without power supply to the transistor 400.

Moreover, the negative potential of the back gate of the transistor 200 is retained, in which case the drain current when the gate voltage of the transistor 200 is 0 V can be kept extremely small without power supply to the transistor 200. In other words, the charges can be retained in the capacitor 100 for a long time without power supply to the transistor 200 and the transistor 400. For example, with the use of such a semiconductor device as a memory element, data can be retained for a long time without power supply. Therefore, a memory device with a low refresh frequency or a memory device that does not need refresh operation can be provided.

Note that the connection relationship of the transistor 200, the transistor 400, and the capacitor 100 is not limited to that illustrated in FIG. 33(A) and FIG. 33(B). The connection relationship can be modified as appropriate in accordance with a necessary circuit configuration.

### <Method for Fabricating Semiconductor Device>

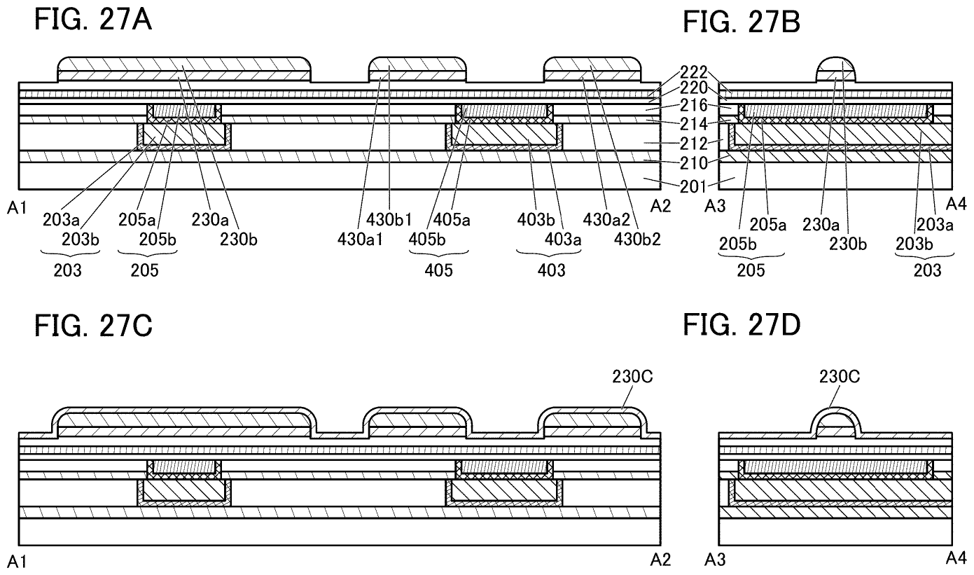

Next, a method for fabricating a semiconductor device including the transistor 200 and the transistor 400 of one embodiment of the present invention will be described with reference to FIG. 27 to FIG. 32. In each of FIG. 27 to FIG. 32, figure (A) is a cross-sectional view corresponding to a portion indicated by a dashed-dotted line A1-A2 in FIG. 26. Similarly, figure (B) is a cross-sectional view corresponding to a portion indicated by a dashed-dotted line A3-A4 in FIG. 26.

First, the substrate 201 is prepared, and the insulator 210 is deposited over the substrate 201. The insulator 210 may be deposited by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving electric charges from plasma. In that case, accumulated charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is a deposition method which enables less plasma damage to an object. An ALD method also does not cause plasma damage during deposition, so that a film with few defects can be obtained. Note that a precursor used in an ALD method sometimes contains impurities such as carbon. Thus, a film provided by an ALD method contains impurities such as carbon in a larger amount than a film provided by another deposition method, in some cases. Note that impurities can be quantified by X-ray photoelectron spectroscopy (XPS).

Unlike in a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and thus is suitable for the case of covering a surface of an opening with a high aspect ratio, for example. On the other hand, an ALD method has a relatively low deposition rate, and thus is preferably used in combination with another deposition method with a high deposition rate such as a CVD method, in some cases.

A CVD method or an ALD method enables control of composition of a film to be obtained with a flow rate ratio of the source gases. For example, a CVD method or an ALD method, a film with a desired composition can be deposited by adjusting the flow rate ratio of the source gases. Moreover, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

In this embodiment, for the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Then, the insulator 212 is deposited over the insulator 210. The insulator 212 can be deposited by a sputtering method, a CVD method, an MBE method, a PLD method, an ALD method, or the like. In this embodiment, for the insulator 212, silicon oxide is deposited by a CVD method.

Then, openings reaching the insulator 210 are formed in the insulator 212. Examples of the opening include a groove and a slit. A region where the opening is formed may be referred to as an opening portion. The openings can be formed by wet etching; however, dry etching is preferably used for microfabrication. In addition, as the insulator 210, an insulator functioning as an etching stopper film when forming a groove by etching the insulator 212 is preferably selected. For example, in the case where a silicon oxide film is used as the insulator 212 in which the groove is to be formed, it is preferable to use, as the insulator 210, a silicon nitride film, an aluminum oxide film, or a hafnium oxide film as an insulating film functioning as an etching stopper film.

After formation of the opening, a conductive film to be the conductor 203a and the conductor 403a is deposited. The conductive film preferably includes a conductor having a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductor to be the conductor 203a and the conductor 403a can be deposited by a sputtering method, a CVD method, an MBE method, a PLD method, an ALD method, or the like.

In this embodiment, as the conductive film to be the conductor 203a and the conductor 403a, tantalum nitride or a stacked film of tantalum nitride and titanium nitride over the tantalum nitride is deposited by a sputtering method. With the use of such a metal nitride as the conductor 203a and the conductor 403a, even when a metal that is easy to diffuse, such as copper, is used for the conductor 203b and the conductor 403b described later, the metal can be prevented from being diffused outward through the conductor 203a and the conductor 403a.

Next, a conductive film to be the conductor 203b and the conductor 403b is deposited over the conductive film to be the conductor 203a and the conductor 403a. The conductive film can be deposited by a sputtering method, a CVD method, an MBE method, a PLD method, an ALD method, or the like. In this embodiment, as the conductive film to be the conductor 203b and the conductor 403b, a low-resistant conductive material such as copper is deposited.

Next, CMP treatment is performed to remove parts of the conductive film to be the conductor 203a and the conductor 403a and the conductive film to be the conductor 203b and the conductor 403b, so that the insulator 212 is exposed. As a result, the conductive film to be the conductor 203a and the conductor 403a and the conductive film to be the conductor 203b and the conductor 403b remain only in the opening portion. Thus, the conductor 203 including the conductor 203a and the conductor 203b and the conductor 403 including the conductor 403a and the conductor 403b, each of which has a planar top surface, can be formed. Note that the insulator 212 is partly removed by the CMP treatment in some cases.

Next, the insulator 214 is deposited over the insulator 212, the conductor 203, and the conductor 403. The insulator 214 can be deposited by a sputtering method, a CVD method, an MBE method, a PLD method, an ALD method, or the like. In this embodiment, for the insulator 214, silicon nitride is deposited by a CVD method. As described here, an insulator through which copper is less likely to pass, such as silicon nitride, is used as the insulator 214; accordingly, even when a metal that is easy to diffuse, such as copper, is used for the conductor 203b and the like, the metal can be prevented from being diffused into layers above the insulator 214.

Next, the insulator 216 is deposited over the insulator 214. The insulator 216 can be deposited by a sputtering method, a CVD method, an MBE method, a PLD method, an ALD method, or the like. In this embodiment, for the insulator 216, silicon oxide is deposited by a CVD method.

Next, openings reaching the conductor 203 and the conductor 403 are formed in the insulator 214 and the insulator 216. The openings can be formed by wet etching; however, dry etching is preferably used for microfabrication.

After formation of the openings, a conductive film to be the conductor 205a and the conductor 405a is deposited. The conductive film to be the conductor 205a and the conductor 405a preferably contains a conductive material that has a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductive film to be the conductor 205a and the conductor 405a can be deposited by a sputtering method, a CVD method, an MBE method, a PLD method, an ALD method, or the like.

In this embodiment, tantalum nitride is deposited by a sputtering method for the conductive film to be the conductor 205a and the conductor 405a.

Next, a conductive film to be the conductor 205b and the conductor 405b is deposited over the conductive film to be the conductor 205a and the conductor 405a. The conductive film can be deposited by a sputtering method, a CVD method, an MBE method, a PLD method, an ALD method, or the like.

In this embodiment, as the conductive film to be the conductor 205b and the conductor 405b, titanium nitride is deposited by a CVD method and tungsten is deposited by a CVD method over the titanium nitride.

Next, CMP treatment is performed to remove parts of the conductive film to be the conductor 205a and the conductor 405a and the conductive film to be the conductor 205b and the conductor 405b, so that the insulator 216 is exposed. As a result, the conductive film to be the conductor 205a and the conductor 405a and the conductive film to be the conductor 205b and the conductor 405b remain only in the openings. Thus, the conductor 205 including the conductor 205a and the conductor 205b and the conductor 405 including the conductor 405a and the conductor 405b, each of which has a planar top surface, can be formed. Note that the insulator 212 is partly removed by the CMP treatment in some cases.

Next, the insulator 220 is deposited over the insulator 216, the conductor 205, and the conductor 405. The insulator 220 can be deposited by a sputtering method, a CVD method, an MBE method, a PLD method, an ALD method, or the like.

In this embodiment, for the insulator 220, silicon oxide is deposited by a CVD method.

Next, the insulator 222 is deposited over the insulator 220. An insulator containing an oxide of one or both of aluminum and hafnium is preferably deposited as the insulator 222. As the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in structure bodies provided around the transistor 200 are not diffused into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like.

In this embodiment, for the insulator 222, hafnium oxide is deposited by an ALD method.

Next, an insulating film to be the insulator 224 and the insulator 424 is deposited over the insulator 222. The insulating film to be the insulator 224 and the insulator 424 can be deposited by a sputtering method, a CVD method, a MBE method, a PLD method, an ALD method, or the like.

In this embodiment, for the insulating film to be the insulator 224 and the insulator 424, silicon oxide is deposited by a CVD method.

Sequentially, heat treatment is preferably performed. The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The first heat treatment is performed in a nitrogen atmosphere, an inert gas atmosphere, or an atmosphere containing an oxidizing gas at 10 ppm or more, 1% or more, or 10% or more. The first heat treatment may be performed under a reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

Through the above heat treatment, excess oxygen can be added to the insulating film to be the insulator 224 and the insulator 424 from the insulator 222, so that an excess-oxygen region can be easily formed in the insulating film to be the insulator 224 and the insulator 424.

This heat treatment can also be performed after the formation of the insulator 220 and after the formation of the insulator 222. Although the conditions for the above-described heat treatment can be used for the heat treatment, the heat treatment after the deposition of the insulator 220 is preferably performed in an atmosphere containing nitrogen. In addition, through the above heat treatment, impurities such as hydrogen and water contained in the insulating film to be the insulator 224 and the insulator 424 can be removed, for example.

Here, in order to form an excess-oxygen region in the insulating film to be the insulator 224 and the insulator 424, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and application of the RF to the substrate side allows oxygen radicals generated by the high-density plasma to be efficiently introduced into the insulator 224. Alternatively, after plasma treatment with an inert gas is performed with this apparatus, plasma treatment with oxygen may be performed to compensate for released oxygen. Note that impurities such as hydrogen and water contained in the insulator 224 can be removed by selecting the conditions for the plasma treatment appropriately. In this case, the heat treatment is not necessarily performed.

Next, an oxide film to be the oxide 230a, the oxide 430a1, and the oxide 430a2 and an oxide film to be oxide 230b, the oxide 430b1, and the oxide 430b2 are deposited in this order over the insulating film to be the insulator 224 and the insulator 424. Note that the oxide films are preferably deposited successively without exposure to an air atmosphere. When the oxide films are deposited without exposure to the air, impurities and moisture in the air can be prevented from being attached onto the oxide film to be the oxide 230a, the oxide 430a1, and the oxide 430a2 and the oxide film to be the oxide 230b, the oxide 430b1, and the oxide 430b2, so that the vicinity of an interface between the oxide film to be the oxide 230a, the oxide 430a1, and the oxide 430a2 and the oxide film to be the oxide 230b, the oxide 430b1, and the oxide 430b2 can be kept clean.

The oxide film to be the oxide 230a, the oxide 430a1, and the oxide 430a2 and the oxide film to be the oxide 230b, the oxide 430b1, and the oxide 430b2 can be deposited by a sputtering method, a CVD method, an MBE method, a PLD method, an ALD method, or the like.

In the case where the oxide film to be the oxide 230a, the oxide 430a1, and the oxide 430a2 and the oxide film to be the oxide 230b, the oxide 430b1, and the oxide 430b2 are deposited by a sputtering method, for example, oxygen or a mixed gas of oxygen and a rare gas is used as a sputtering gas. By increasing the proportion of oxygen contained in the sputtering gas, the amount of excess oxygen in the oxide film to be deposited can be increased. In the case where the above oxide films are deposited by a sputtering method, the above In-M-Zn oxide target can be used.

In particular, part of oxygen contained in the sputtering gas is supplied to the insulating film to be the insulator 224 and the insulator 424 in some cases during the deposition of the oxide film to be the oxide 230a, the oxide 430a1, and the oxide 430a2. Note that the proportion of oxygen contained in the sputtering gas for the oxide film to be the oxide 230a, the oxide 430a1, and the oxide 430a2 is 70% or higher, preferably 80% or higher, and further preferably 100%.

In addition, in the case where the oxide film to be the oxide 230b, the oxide 430b1, and the oxide 430b2 is formed by a sputtering method, when the proportion of oxygen contained in the sputtering gas is 1% or higher and 30% or lower, preferably 5% or higher and 20% or lower, an oxygen-deficient metal oxide is formed. In a transistor using an oxygen-deficient metal oxide for its channel formation region, relatively high field-effect mobility can be obtained.

In this embodiment, the oxide film to be the oxide 230a, the oxide 430a1, and the oxide 430a2 is deposited by a sputtering method using a target with In:Ga:Zn=1:3:4 [atomic ratio]. In addition, the oxide film to be the oxide 230b, the oxide 430b1, and the oxide 430b2 is deposited by a sputtering method using a target with In:Ga:Zn=4:2:4.1 [atomic ratio]. Note that each of the oxide films is preferably formed to have characteristics required for the oxide 230 by appropriate selection of deposition conditions and an atomic ratio.

Next, heat treatment may be performed. For the heat treatment, the conditions for the above-described heat treatment can be used. Through the heat treatment, impurities such as water and hydrogen in the oxide film to be the oxide 230a, the oxide 430a1, and the oxide 430a2 and the oxide film to be the oxide 230b, the oxide 430b1, and the oxide 430b2 can be removed, for example. In this embodiment, treatment is performed at 400° C. in a nitrogen atmosphere for one hour, and successively another treatment is performed at 400° C. in an oxygen atmosphere for one hour.

Next, the oxide film to be the oxide 230a, the oxide 430a1, and the oxide 430a2 and the oxide film to be the oxide 230b, the oxide 430b1, and the oxide 430b2 are processed into an island shape to form a stacked-layer structure of the oxide 230a and the oxide 230b, a stacked-layer structure of the oxide 430a1 and the oxide 430b1, and a stacked-layer structure of the oxide 430a2 and the oxide 430b2 (see FIG. 27(A) and FIG. 27(B)). Note that in the process, the insulating film to be the insulator 224 and the insulator 424 is partly removed in some cases.

Here, the oxide 230a and the oxide 230b are formed to overlap with the conductor 205 at least partly. It is preferable that side surfaces of the oxide 230a and the oxide 230b be substantially perpendicular to a top surface of the insulating film to be the insulator 224. When the side surfaces of the oxide 230a and the oxide 230b are substantially perpendicular to the top surface of the insulating film to be the insulator 224, the plurality of transistors 200 can be provided in a smaller area and at a higher density. Note that a structure may be employed in which an angle formed by the side surfaces of the oxide 230a and the oxide 230b and the top surface of the insulating film to be the insulator 224 is an acute angle. In that case, the angle formed by the side surfaces of the oxide 230a and the oxide 230b and the top surface of the insulating film to be the insulator 224 is preferably larger.

There is a curved surface between the side surfaces of the oxide 230a and the oxide 230b and the top surface of the oxide 230b. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm.

Similarly, there are curved surfaces between the side surfaces of the oxide 430a1 and the oxide 430b1 and the top surface of the oxide 430b1, and between the side surfaces of the oxide 430a2 and the oxide 430b2 and the top surface of the oxide 430b2. That is, an end portion of the side surface and an end portion of the top surface are preferably curved (hereinafter such a curved shape is also referred to as a rounded shape). The radius of curvature of the curved surface of each of the end portions of the oxide 430b1 and the oxide 430b2 is preferably greater than or equal to 3 nm and less than or equal to 10 nm, further preferably greater than or equal to 5 nm and less than or equal to 6 nm.

When the end portions are not angular, the coverage with films deposited in the following process can be improved.

Note that for the processing of the oxide films, a lithography method can be employed. For the processing, a dry etching method or a wet etching method can be employed. The processing by a dry etching method is suitable for microfabrication.

Note that in the lithography method, first, a resist is exposed to light through a mask. Next, a region exposed to light is removed or left using a developing solution, so that a resist mask is formed.

Then, etching treatment through the resist mask is performed, so that the conductor, the semiconductor, the insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. Furthermore, an electron beam or an ion beam may be used instead of the above-described light. Note that the above mask for the exposure of the resist to light is unnecessary in the case of using an electron beam or an ion beam. Note that for removal of the resist mask after the light exposure, dry etching treatment such as ashing can be performed, wet etching treatment can be performed, wet etching treatment can be performed after dry etching treatment, or dry etching treatment can be performed after wet etching treatment, for example.

A hard mask formed of an insulator or a conductor may be used instead of the resist mask. In the case where a hard mask is used, a hard mask with a desired shape can be formed in the following manner: an insulating film or a conductive film that is the hard mask material is formed over the oxide film to be the oxide 230b, the oxide 430b1, and the oxide 430b2, a resist mask is formed thereover, and then the hard mask material is etched. The etching of the oxide fill to be the oxide 230a, the oxide 430a1, and the oxide 430a2 and the oxide film to be the oxide 230b, the oxide 430b1, and the oxide 430b2 may be performed after removal of the resist mask or while the resist mask remain. In the latter case, the resist mask disappears during the etching in some cases. The hard mask may be removed by etching after the etching of the above oxide films. The hard mask does not need to be removed in the case where the hard mask material does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, treatment such as dry etching performed in the above process causes the attachment or diffusion of impurities due to an etching gas or the like to a surface or an inside of the oxide 230a, the oxide 230b, and the like. Examples of the impurities include fluorine and chlorine.

In order to remove the impurities, cleaning is performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution obtained by diluting an oxalic acid, a phosphoric acid, a hydrofluoric acid, or the like with pure water or carbonated water. Alternatively, ultrasonic cleaning using pure water or carbonated water may be performed. In this embodiment, the ultrasonic cleaning using pure water or carbonated water is performed.

Sequentially, heat treatment may be performed. For the heat treatment, the conditions for the above-described heat treatment can be used.

Next, the oxide film 230C is deposited over the insulating film to be the insulator 224 and the insulator 424, the stacked-layer structure of the oxide 230a and the oxide 230b, the stacked-layer structure of the oxide 430a1 and the oxide 430b1, and the stacked-layer structure of the oxide 430a2 and the oxide 430b2 (see FIG. 27(C) and FIG. 27(D)). The oxide film can be deposited by a sputtering method, a CVD method, an MBE method, a PLD method, an ALD method, or the like.

The oxide film 230C may be deposited using conditions similar to those for the oxide film to be the oxide 230a, or may be deposited using conditions similar to those for the oxide film to be the oxide 230b. Alternatively, these conditions may be combined for the deposition.

In this embodiment, the oxide film 230C is deposited by a sputtering method using a target with In:Ga:Zn=4:2:4.1 [atomic ratio]. At this time, the oxide film may be deposited at a proportion of oxygen of 70% or higher, preferably 80% or higher, further preferably 100%.

Note that for the oxide film 230C, in accordance with characteristics required for the oxide film to be the oxide 230c and the oxide 430c, a deposition method similar to that for the oxide film to be the oxide 230a, the oxide 430a1, and the oxide 430a2, or a deposition method similar to that for the oxide film to be the oxide 230b, the oxide 430b1, and the oxide 430b2 can be used. In this embodiment, the oxide film to be the oxide 230c and the oxide 430c is deposited by a sputtering method using a target with In:Ga:Zn=4:2:4.1 [atomic ratio].

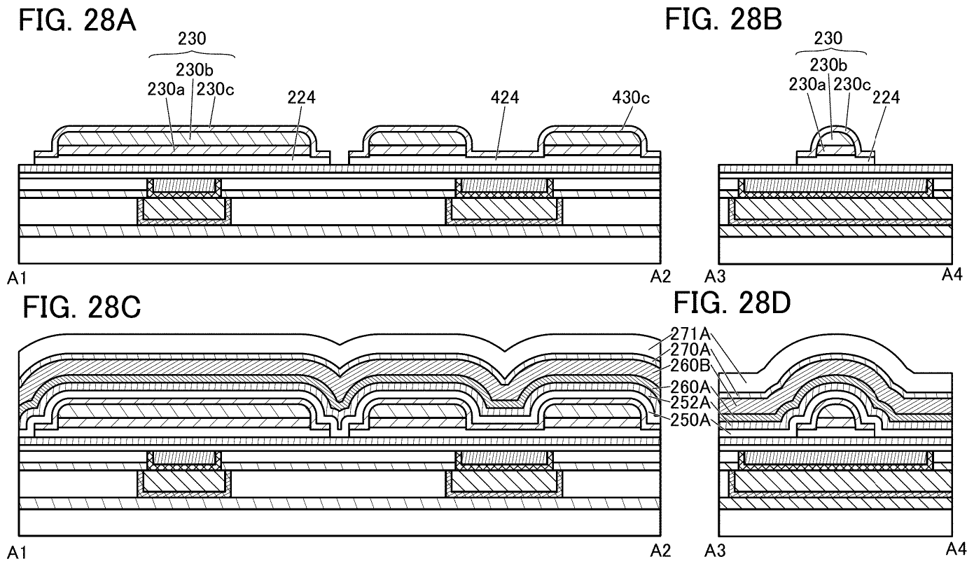

Then, the oxide film 230C is processed into an island shape to form the oxide 430c and the oxide 230 including the oxide 230c (see FIG. 28(A) and FIG. 28(B)). Here, the oxide 230c is preferably formed to cover the oxide 230a and the oxide 230b. Furthermore, the oxide 430c is preferably formed to cover the oxide 430a1, the oxide 430b1, the oxide 430a2, and the oxide 430b2. The processing is performed by a lithography method. The processing can be performed by a dry etching method or a wet etching method. The processing by a dry etching method is suitable for microfabrication. In a lithography method, a hard mask may be used instead of a resist mask.

Sequentially, the insulating film 250A, the insulating film 252A, the conductive film 260A, the conductive film 260B, the insulating film 270A, and the insulating film 271A are deposited in this order (see FIG. 28 (C) and FIG. 28(D)).

The insulating film 250A can be deposited by a sputtering method, a CVD method, an MBE method, a PLD method, an ALD method, or the like. Note that the deposition temperature at the time of the deposition of the insulating film 250A is preferably higher than or equal to 350° C. and lower than 450° C., particularly preferably approximately 400° C. When the insulating film 250A is deposited at 400° C., an insulator having few impurities can be deposited.

Note that oxygen is excited by microwaves to generate high-density oxygen plasma, and the insulating film 250A is exposed to the oxygen plasma, whereby oxygen can be introduced into the insulating film 250A, the oxide 230, and the oxide 430c.

Furthermore, heat treatment may be performed. For the heat treatment, the conditions for the above-described heat treatment can be used. The heat treatment can reduce the moisture concentration and the hydrogen concentration in the insulating film 250A.

Next, the insulating film 252A is deposited over the insulating film 250A. An insulator containing an oxide of one or both of aluminum and hafnium is preferably deposited as the insulating film 252A. As the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulating film 252A has a barrier property against hydrogen and water, hydrogen and water contained in structure bodies provided around the transistor 200 are not diffused into the transistor 200 through the insulating film 252A, and generation of oxygen vacancies in the oxide 230 can be inhibited.

The insulating film 252A can be deposited by a sputtering method, a CVD method, an MBE method, a PLD method, an ALD method, or the like.

When a metal oxide is deposited as the insulating film 252A by a sputtering method in an atmosphere containing oxygen, oxygen can be added to the insulating film 250A and an excess-oxygen region can be formed in the insulating film 250A. The excess oxygen added to the insulating film 250A can compensate for the oxygen vacancy in the oxide 230 when supplied thereto.

Here, during the deposition of the insulating film 252A by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The relationship between the potentials is E₂>E₁>E₀.

The ions in plasma are accelerated by a potential difference (E₂−E₀) and collide with the target; accordingly, the sputtered particles are ejected from the target. These sputtered particles are attached to a deposition surface and deposited thereover; as a result, a film is deposited. Some ions recoil by the target and might pass through the deposited film as recoil ions, and be taken into the insulating film 250A in contact with the deposition surface. The ions in the plasma are accelerated by a potential difference (E₂−E₁) and collide with the deposition surface.

At that time, some ions reach the inside of the insulating film 250A. When the ions are taken into the insulating film 250A, a region into which the ions are taken is formed in the insulating film 250A. That is, an excess-oxygen region is formed in the insulating film 250A in the case where the ions contain oxygen.

When excess oxygen is introduced into the insulating film 250A, an excess-oxygen region can be formed. The excess oxygen in the insulating film 250A is supplied to the oxide 230 and can compensate for oxygen vacancies in the oxide 230.

Accordingly, when the deposition is performed in an oxygen gas atmosphere with a sputtering apparatus as the method for depositing the insulating film 252A, oxygen can be introduced into the insulating film 250A while the insulating film 252A is deposited. In particular, when an oxide of one or both of aluminum and hafnium that has a barrier property is used for the insulating film 252A, excess oxygen introduced into the insulator 250 can be effectively sealed therein.

Sequentially, the conductive film 260A and the conductive film 260B are deposited. The conductive film 260A and the conductive film 260B can be deposited by a sputtering method, a CVD method, an MBE method, a PLD method, an ALD method, or the like. In this embodiment, titanium nitride is deposited by a CVD method for the conductive film 260A and tungsten is deposited by a CVD method for the conductive film 260B

Subsequently, heat treatment can be performed. For the heat treatment, the conditions for the above-described heat treatment can be used. Note that the heat treatment is not necessarily performed in some cases. Through the heat treatment, excess oxygen is added from the insulating film 252A to the insulating film 250A, whereby an excess-oxygen region can be easily formed in the insulating film 250A.

Sequentially, the insulating film 270A and the insulating film 271A are deposited. The insulating film 270A can be deposited by a sputtering method, a CVD method, an MBE method, a PLD method, an ALD method, or the like. For the insulating film 270A functioning as a barrier film, an insulating material having a function of inhibiting the passage of oxygen and impurities such as water or hydrogen is used. For example, aluminum oxide or hafnium oxide is preferably used. Thus, oxidation of the conductor 260 can be prevented. Moreover, this can prevent entry of impurities such as water or hydrogen into the oxide 230 through the conductor 260 and the insulator 250. In this embodiment, for the insulating film 270A, aluminum oxide is deposited by an ALD method.

The insulating film 271A can be deposited by a sputtering method, a CVD method, an MBE method, a PLD method, an ALD method, or the like. Here, the film thickness of the insulating film 271A is preferably larger than the film thickness of an insulating film 272A to be deposited in a later step. In that case, when an insulator 272 is formed in a later step, the insulator 271 can remain easily over the conductor 260. In this embodiment, for the insulating film 271A, silicon oxide is deposited by a CVD method.

Next, the insulating film 271A is etched to form the insulator 271 and the insulator 471. The insulator 271 and the insulator 471 each function as a hard mask. When the insulator 271 and the insulator 471 are provided, the side surface of the insulator 250, the side surface of the insulator 252, the side surface of the conductor 260a, the side surface of the conductor 260b, the side surface of the insulator 270, the side surface of the insulator 450, the side surface of the insulator 452, the side surface of the conductor 460a, the side surface of the conductor 460b, and the side surface of the insulator 470 can be formed to be substantially perpendicular to the top surface of the substrate.

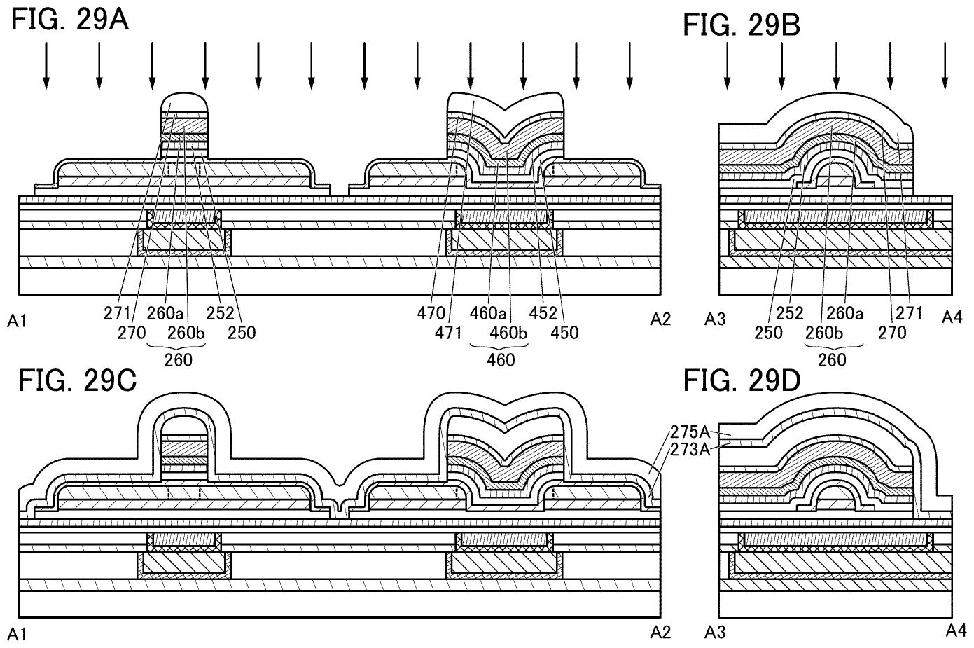

The insulating film 250A, the insulating film 252A, the conductive film 260A, the conductive film 260B, and the insulating film 270A are etched using the insulator 271 and the insulator 471 as masks, so that the insulator 250, the insulator 252, the conductor 260 (the conductor 260a and the conductor 260b), the insulator 270, the insulator 450, the insulator 452, the conductor 460 (the conductor 460a and the conductor 460b), and the insulator 470 are formed (see FIG. 29(A) and FIG. 29(B)). Note that parts of the oxide 230c and the oxide 430c may be removed by the etching in a region where the oxide film 230C and the insulator 250 do not overlap with each other. In that case, the film thickness of the oxide 230c in a region overlapping with the insulator 250 is larger than the film thickness thereof in the region not overlapping with the insulator 250 in some cases. In addition, the film thickness of the oxide 430c in a region overlapping with the insulator 450 is larger than the film thickness thereof in the region not overlapping with the insulator 450 in some cases.

The insulator 250, the insulator 252, the conductor 260a, the conductor 260b, the insulator 270, and the insulator 271 are formed to at least partly overlap with the conductor 205, the oxide 230a, and the oxide 230b.

The side surface of the insulator 250, the side surface of the insulator 252, the side surface of the conductor 260a, the side surface of the conductor 260b, and the side surface of the insulator 270 are preferably on the same surface. In addition, the side surface of the insulator 450, the side surface of the insulator 452, the side surface of the conductor 460a, the side surface of the conductor 460b, and the side surface of the insulator 470 are preferably on the same surface.

Note that after the processing, the following process may be performed without removal of the hard masks (the insulator 271 and the insulator 471).

Here, treatment for adding a metal element or an impurity to the oxide 230 and a stack of the oxide 430a, the oxide 430b, and the oxide 430c (hereinafter also referred to as the oxide 430) may be performed using the insulator 250, the insulator 252, the conductor 260, the insulator 270, the insulator 271, the insulator 450, the insulator 452, the conductor 460, the insulator 470, and the insulator 471 as masks (indicated by allows in FIG. 29(A) and FIG. 29(B)).

As the method for adding a metal element or an impurity, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that the impurity and the metal element to be added may be referred to as an element, a dopant, an ion, a donor, an acceptor, or the like.

The impurity and the metal element may be added by plasma treatment. In that case, the plasma treatment is performed with a plasma CVD apparatus, a dry etching apparatus, or an ashing apparatus, so that the impurity and the metal element can be added. Note that a plurality of the above-described treatments may be combined.

Since the conductor 260 functioning as a gate electrode is used as a mask, addition of hydrogen and nitrogen only to the region of the oxide 230 that overlaps with the conductor 260 (the region 234) is inhibited, so that a boundary between the region 234 and the region 232 can be provided in a self-aligned manner.

By the treatment for adding an impurity using the conductor 260 as a mask, for example, the region 232 is formed in a step after the insulator 274 is provided, so that the region 232 can be surely provided even in the case where the thermal budget is not enough for diffusing the impurity. Note that due to the diffusion of the impurity, the region 232 may overlap with the conductor 260 functioning as the gate electrode. In that case, the region 232 functions as what is called an overlap region (also referred to as an Lov region).

Alternatively, after the insulating film 273A is deposited, the impurity may be added through the insulating film 273A by an ion doping method, for example. The insulating film 273A is provided to cover the oxide 230, the insulator 250, the insulator 252, the conductor 260, the insulator 270, the insulator 271, the oxide 430, the insulator 450, the insulator 452, the conductor 460, the insulator 470, and the insulator 471. Therefore, the impurity can be added while the insulator 250 and the insulator 252 functioning as gate insulators are protected by the insulator 273.

Next, the insulating film 273A and the insulating film 275A are deposited to cover the oxide 230, the insulator 250, the insulator 252, the conductor 260, the insulator 270, and the insulator 271 (see FIG. 29(C), and FIG. 29(D)). The insulating film 273A and the insulating film 274A can be deposited by a sputtering method, a CVD method, an MBE method, a PLD method, an ALD method, or the like.

The insulating film 273A is preferably deposited by an ALD method, which enables good coverage. With the use of an ALD method, the insulating film 273A having a uniform thickness can be formed on the side surfaces of the insulator 250, the insulator 252, the conductor 260, and the insulator 270 even in a step portion formed by the conductor 260, the conductor 460, and the like.

A metal oxide film deposited by an ALD method can be used as the insulating film 273A, for example. With the use of an ALD method, a dense thin film can be deposited. The metal oxide film preferably contain one or more kinds selected from hafnium, aluminum, gallium, yttrium, zirconium, tungsten, titanium, tantalum, nickel, germanium, magnesium, and the like. In this embodiment, aluminum oxide is used for the insulator 273.

Note that aluminum oxide has a high barrier property, so that even a thin aluminum oxide film having a thickness of greater than or equal to 0.5 nm and less than or equal to 3.0 nm can inhibit diffusion of hydrogen and nitrogen. Although hafnium oxide has a lower barrier property than aluminum oxide, the barrier property can be increased with an increase in the film thickness. For example, when hafnium oxide is deposited by an ALD method, the film thickness of the hafnium oxide can be easily adjusted, and appropriate addition amount of hydrogen and nitrogen can be adjusted.

Therefore, in the case where aluminum oxide is used for the insulating film 273A, the film thickness in a region in contact with the side surface of the insulator 250, the side surface of the insulator 252, the side surface of the conductor 260, and the side surface of the insulator 270 and the film thickness in a region in contact with the side surface of the insulator 450, the side surface of the insulator 452, the side surface of the conductor 460, and the side surface of the insulator 470 are preferably greater than or equal to 0.5 nm, preferably greater than or equal to 3.0 nm.

The insulator to be the insulating film 273A is preferably deposited by a sputtering method. With the use of a sputtering method, an insulator containing few impurities such as water or hydrogen can be deposited. In the case of using a sputtering method, the deposition is preferably performed with the use of a facing-target sputtering apparatus, for example. With the facing-target sputtering apparatus, deposition can be performed without exposing a deposition surface to a high electric field region between facing targets; thus, the deposition surface is less likely to be damaged due to plasma during the deposition. Therefore, deposition damage to the oxide 230 during the deposition of the insulator to be the insulating film 273A can be reduced, which is preferable. A deposition method using a facing-target sputtering apparatus can be referred to as VDSP (Vapor Deposition SP) (registered trademark).

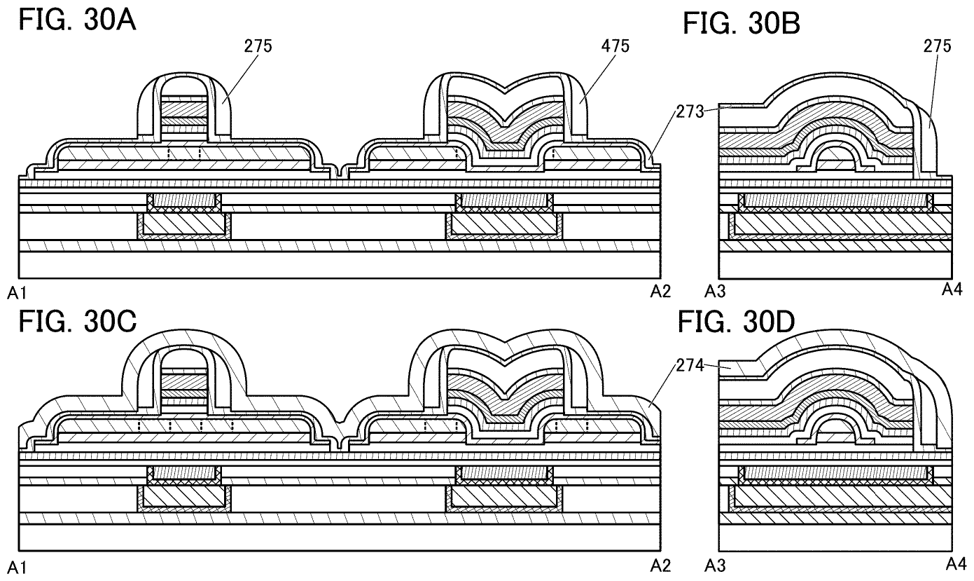

Next, the insulating film 275A is subjected to anisotropic etching treatment, whereby the insulator 275 is formed to overlap with the side surfaces of the insulator 250, the insulator 252, the conductor 260, and the insulator 270 with the insulator 273 therebetween. At the same time, the insulator 475 is formed to overlap with the side surfaces of the insulator 450, the insulator 452, the conductor 460, and the insulator 470 with the insulator 273 therebetween. Moreover, the exposed surface of the insulating film 273A is removed to thin part of the insulating film 273A, so that the insulator 273 is formed (see FIG. 30(A) and FIG. 30(B)). Note that in the case where the insulator 273 is aluminum oxide, the film thickness of the insulator 273 in the thinned region is preferably less than or equal to 3.0 nm.

Dry etching treatment is preferably performed as the above anisotropic etching treatment. In this manner, the insulating film in a region on a surface substantially parallel to the substrate surface can be removed, so that the insulator 272 can be formed in a self-aligned manner.

Alternatively, the above etching may etch the insulating film 273A at the same time to form the insulator 273. Note that the insulator 273 may be formed in an etching step different from the above etching.

Although not illustrated, the insulating film 275A may remain also on the side surface of the oxide 230 and the side surface of the oxide 430. In that case, coverage with an interlayer film or the like to be formed in a later step can be improved.

Since a structure body in which part of the insulating film 275A remains is formed in contact with the side surface of the oxide 230 and the side surface of the oxide 430, in the case of depositing the insulator 274 containing an element serving as an impurity in a later step to form a low-resistance region in the oxide 230 and the oxide 430, the resistances of an interface region between the insulator 224 and the oxide 230 and an interface region between the insulator 424 and the oxide 430 are not reduced, so that generation of leakage current can be inhibited.

Sequentially, low-resistance regions are formed in the oxide 230 and the oxide 430. The region 231 and the region 232 are each a region of the metal oxide provided as the oxide 230 to which impurities are added. Note that the region 231 has higher conductivity than at least the region 234.

In order to selectively add the impurities to the oxide 230 and the oxide 430, a dopant which is at least one of the impurities and metal element such as indium or gallium is added, for example. Note that as the dopant, the above-described element that forms an oxygen vacancy, the element trapped by an oxygen vacancy, or the like may be used. Examples of the element include hydrogen, boron, carbon, nitrogen, fluorine, phosphorus, sulfur, chlorine, titanium, and a rare gas.

For example, in order to add impurities to the region 231 and the region 232, the insulator 274 is preferably deposited, as a film containing the dopant, to overlap with the region whose resistance is to be reduced with the insulator 273 therebetween. As the insulator 274, an insulating film containing one or more kinds of the above elements is preferably used (see FIG. 30(C) and FIG. 30(D)).

Specifically, the insulator 274 containing an element serving as an impurity such as nitrogen is preferably deposited over the oxide 230 and the oxide 430 with the insulator 273 containing a metal element therebetween. The insulator containing an element serving as an impurity such as nitrogen may extracts and absorbs oxygen contained in the oxide 230 and the oxide 430. Oxygen vacancies are generated in regions of the oxide 230 and the oxide 430 from which oxygen is extracted. Due to the deposition of the insulator 274 or heat treatment after the deposition, impurity elements such as hydrogen or nitrogen contained in the deposition atmosphere for depositing the insulator 274 are trapped in the oxygen vacancies, so that the resistances of the oxide 230 and the oxide 430 are selectively reduced. That is, oxygen vacancies are formed mainly in regions of the oxide 230 and the oxide 430 which are in contact with the insulator 274 because of the added impurity elements, and the impurity elements enter the oxygen vacancies, thereby increasing the carrier density and reducing the resistance. It is considered that, at this time, the impurities are diffused also into the regions that are not in contact with the insulator 274, thereby reducing the resistance thereof.

Accordingly, a source region and a drain region can be formed in a self-aligned manner owing to the deposition of the insulator 274. Thus, miniaturized or highly integrated semiconductor devices can be manufactured with high yield.

Here, the insulator 275 and the insulator 475 are formed to overlap with the side surfaces of the conductor 260 and the conductor 460 with the insulator 273 therebetween, whereby the impurity element such as nitrogen or hydrogen added to the regions of the oxide 230 and the oxide 430 whose resistances are selectively reduced can be inhibited from being diffused into the channel formation region of each transistor.

Furthermore, the insulator 273 is formed between the insulator 274 and the oxide 230 and between the insulator 274 and the oxide 430, whereby the impurity elements such as nitrogen or hydrogen can be inhibited from being added excessively to the oxide 230 and the oxide 430.

Here, the top surface and the side surface of the conductor 260, the insulator 252, and the insulator 250 are covered with the insulator 275 and the insulator 273, whereby the impurity elements such as nitrogen or hydrogen can be prevented from entering the conductor 260, the insulator 252, and the insulator 250. Thus, the impurity elements such as nitrogen or hydrogen can be prevented from entering the region 234 functioning as the channel formation region of the transistor 200 through the conductor 260, the insulator 252, and the insulator 250. Accordingly, the transistor 200 having favorable electrical characteristics can be provided.

Here, the top surface and the side surfaces of the conductor 460, the insulator 452, and the insulator 450 are covered with the insulator 475 and the insulator 273, whereby impurity elements such as nitrogen and hydrogen can be prevented from entering the conductor 460, the insulator 452, and the insulator 450. Thus, impurity elements such as nitrogen or hydrogen can be prevented from entering the region functioning as the channel formation region of the transistor 400 through the conductor 460, the insulator 452, and the insulator 450. Accordingly, the transistor 400 having favorable electrical characteristics can be provided.

The insulator 274 can be deposited by a sputtering method, a CVD method, an MBE method, a PLD method, an ALD method, or the like.

For the insulator 274, silicon nitride, silicon nitride oxide, silicon oxynitride, or the like which is deposited by a CVD method can be used, for example. In this embodiment, silicon nitride oxide is used for the insulator 274.

In the case where silicon nitride oxide is used for the insulator 274, the low-resistance region preferably has a higher concentration of at least one of hydrogen and nitrogen than the region where the channel is formed. The concentration of hydrogen or nitride is measured by secondary ion mass spectrometry (SIMS) or the like. Here, as the concentration of hydrogen or nitride in the region 234, the concentration of hydrogen or nitrogen in the middle of the region of the oxide 230b that overlaps with the insulator 250 (e.g., a portion in the oxide 230b which is located equidistant from both side surfaces of the insulator 250 in the channel length direction) is measured.

Note that the above regions may be formed in combination with other methods for adding a dopant. As other methods for adding a dopant, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that a dopant may be referred to as an ion, donor, acceptor, impurity, element, or the like.

Alternatively, impurities may be added by plasma treatment. In this case, the plasma treatment is performed with a plasma CVD apparatus, a dry etching apparatus, or an ashing apparatus, so that a dopant can be selectively added to the oxide 230 and the oxide 430. Note that a plurality of the above-described treatments may be combined to form each region.

For example, when the content percentage of the element that forms an oxygen vacancy or the element trapped by an oxygen vacancy in oxide 230 and the oxide 430 is increased, the carrier density is increased and the resistance can be reduced. For example, when a metal element such as indium is added to the oxide 230 and the oxide 430 to increase the content percentage of the metal atom such as indium in the oxide 230 and the oxide 430, the electron mobility can be increased and the resistance can be reduced. Note that in the case of adding indium, atomic ratio of indium to the element M at least in the low-resistance region is higher than the atomic ratio of indium to the element M in the region where the channel is formed.

When the region 232 is provided in the transistor 200, a high-resistance region not formed between the region 231 functioning as the source region and the drain region and the region 234 where a channel is formed, so that the on-state current and the mobility of the transistor can be increased. Since the gate does not overlap with the source region and the drain region in the channel length direction owing to the region 232, formation of unnecessary capacitance can be inhibited. Furthermore, leakage current in a non-conduction state can be reduced owing to the region 232.

Thus, by appropriately selecting the areas of the regions, a transistor having electrical characteristics that meet the demand for the circuit design can be easily provided.

Subsequently, heat treatment can be performed. For the heat treatment, the conditions for the above-described heat treatment can be used. Through the heat treatment, the added impurities are diffused into the region 232 of the oxide 230, whereby the on-state current can be increased.

Next, the insulating film to be the insulator 280 is deposited over the insulator 274. The insulator 280 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used. In this embodiment, silicon oxynitride is used for the insulating film.

Next, the insulator 280 is partly removed. The insulator 280 is preferably formed to have a planar top surface. For example, the insulator 280 may have a planar top surface right after the deposition of the insulating film to be the insulator 280. Alternatively, for example, the insulator 280 may have planarity by removing the insulator and the like from the top surface after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have planarity.

Then, the insulator 282 is formed over the insulator 280. The insulator 282 is preferably deposited with a sputtering apparatus. When aluminum oxide having a barrier property is used for the insulator 282, for example, impurity diffusion from structure bodies formed above the insulator 282 into the transistor 200 and the transistor 400 can be inhibited.

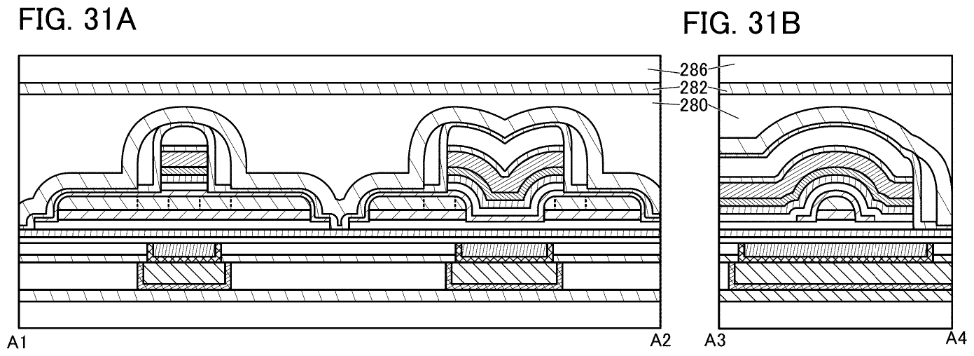

Then, the insulator 286 is deposited over the insulator 282. As the insulator 286, for example, an insulator containing oxygen, such as a silicon oxide film or a silicon oxynitride film, is formed by a CVD method. The permittivity of the insulator 286 is preferably lower than that of the insulator 282. When a material with a low permittivity is used for an interlayer film, the parasitic capacitance generated between wirings can be reduced (see FIG. 31).

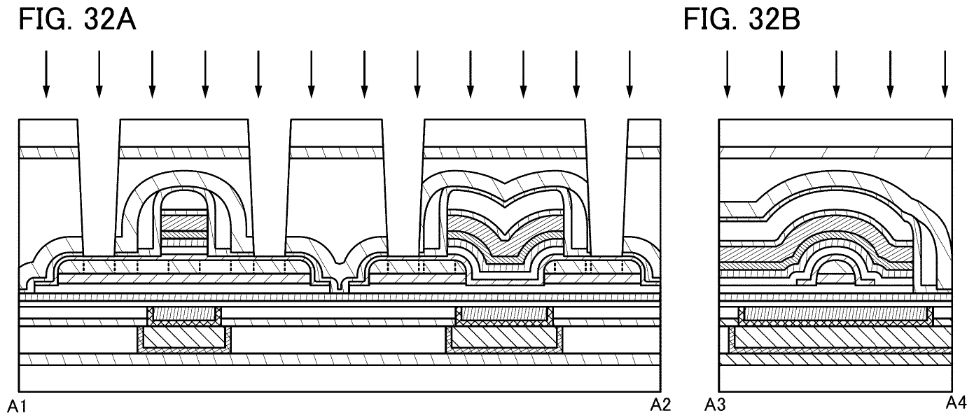

Then, openings reaching the transistor 200, the transistor 400, the wirings, and the like are formed in the insulator 286, the insulator 282, and the insulator 280 (see FIG. 32).

Here, treatment for adding a metal element or an impurity to the oxide 230 and the oxide 430 using the insulator 280, the insulator 274, and the insulator 273 as masks may be performed, for example (indicated by arrows in FIG. 32). When the treatment for adding a metal element or an impurity is performed, the resistance of the region such as the region 236 can be reduced in a self-aligned manner. Note that the region 236 preferably has a lower resistance than the region 231. When the resistance of the region 236 is reduced, a sufficient ohmic contact between the oxide 230 and the conductor 240 can be made. Similarly, when the resistance of the oxide 430 in the region overlapping with the conductor 440 is reduced, a sufficient ohmic contact between the oxide 430 and the conductor 440 can be made.

As the treatment for adding a metal element or an impurity, an ion implantation method in which an ionized source gas is subjected to mass separation and then added, an ion doping method in which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that the impurity and the metal element to be added may be referred to as an element, a dopant, an ion, a donor, an acceptor, or the like.

Alternatively, the impurity and the metal element may be added by plasma treatment.

In that case, the plasma treatment is performed with a plasma CVD apparatus, a dry etching apparatus, or an ashing apparatus, so that the impurity and the metal element can be added. Note that a plurality of the above-described treatments may be combined.

Next, a conductive film to be the conductor 240 and the conductor 440 is formed. For example, the conductive film to be the conductor 240 and the conductor 440 can be deposited by a sputtering method, a CVD method, an MBE method, a PLD method, an ALD method, or the like. Note that the conductive film to be the conductor 240 and the conductor 440 is deposited so as to fill the openings formed in the insulator 280 and the like. Therefore, a CVD method (in particular, an MOCVD method) is preferably used. Furthermore, a multilayer film of a conductor deposited by an ALD method or the like and a conductor deposited by a CVD method is preferred in some cases to increase adhesion of the conductor deposited by an MOCVD method. The conductive film to be the conductor 240 and the conductor 440 preferably has a stacked-layer structure of titanium nitride and tungsten, for example.

Then, unnecessary portions of the conductive film to be the conductor 240 and the conductor 440 are removed. For example, part of the conductive film to be the conductor 240 and the conductor 440 is removed by etch-back treatment or CMP treatment until the insulator 286 is exposed, whereby the conductor 240 and the conductor 440 are formed. At this time, the insulator 286 can be used as a stopper layer, and the thickness of the insulator 286 is reduced in some cases.

Next, a conductive film to be the conductor 112 and the conductor 110 is deposited over the insulator 286. Note that the conductive film to be the conductor 112 and the conductor 110 can be formed using, for example, a metal selected from aluminum, chromium, copper, tantalum, titanium, molybdenum, and tungsten, an alloy containing any of the above metals as its component, or an alloy containing any of the above metals in combination. Furthermore, one or more metals selected from manganese and zirconium may be used. Alternatively, a semiconductor typified by polycrystalline silicon doped with an impurity element such as phosphorus, or silicide such as nickel silicide may be used. For example, a two-layer structure in which a titanium film is stacked over an aluminum film; a two-layer structure in which a titanium film is stacked over a titanium nitride film; a two-layer structure in which a tungsten film is stacked over a titanium nitride film; a two-layer structure in which a tungsten film is stacked over a tantalum nitride film or a tungsten nitride film; or a three-layer structure of a titanium film, an aluminum film stacked over the titanium film, and a titanium film further formed thereover can be employed. Alternatively, an alloy film or a nitride film in which aluminum is combined with one or more metals selected from titanium, tantalum, tungsten, molybdenum, chromium, neodymium, and scandium may be used.

Sequentially, the conductive film to be the conductor 112 and the conductor 110 is etched to form the conductor 112 and the conductor 110. Over-etching treatment may be performed as this etching treatment so that part of the insulator 286 may be also removed at the same time.

Then, the insulator 130 covering the top surface and the side surface of the conductor 112 and the conductor 110 is deposited. The insulator 130 can be provided to have a stacked layer or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, a stacked-layer structure of a high-k material such as aluminum oxide and a material with high dielectric strength, such as silicon oxynitride, is preferable. The structure enables the capacitor 100 to have sufficient capacitance owing to the high-k material and have increased dielectric strength, so that the electrostatic breakdown of the capacitor 100 can be inhibited and the reliability of the capacitor 100 can be improved.

Subsequently, a conductive film to be the conductor 120 is deposited over the insulator 130. The conductive film to be the conductor 120 can be formed using a material and a method similar to those for the conductor 110. Then, unnecessary portions of the conductive film to be the conductor 120 are removed by etching. After that, a resist mask is removed, whereby the conductor 120 is formed.

The conductor 120 is preferably provided to cover the side surface and the top surface of the conductor 110 with the insulator 130 therebetween. With the structure, the side surface of the conductor 110 faces the conductor 120 with the insulator 130 therebetween. Accordingly, in the capacitor 100, a capacitor having large capacitance per projected area can be formed because the sum of the area of the top surface and the side surface of the conductor 110 functions as a capacitor.

Next, the insulator 150 covering the capacitor 100 is deposited (see FIG. 25). An insulator to be the insulator 150 can be formed using a material and a method similar to those for the insulator 286 and the like.

Through the above process, the semiconductor device including the capacitor 100, the transistor 200, and the transistor 400 can be fabricated. As illustrated in FIG. 27 to FIG. 32, with the use of the method for fabricating the semiconductor device described in this embodiment, the capacitor 100, the transistor 200, and the transistor 400 can be formed

According to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device with low off-state current can be provided. Alternatively, according to one embodiment of the present invention, a transistor with high on-state current can be provided. Alternatively, according to one embodiment of the present invention, a highly reliable semiconductor device can be provided. Alternatively, according to one embodiment of the present invention, a semiconductor device with reduced power consumption can be provided. Alternatively, according to one embodiment of the present invention, a semiconductor device with high productivity can be provided.

### <Modification Example of Semiconductor Device>

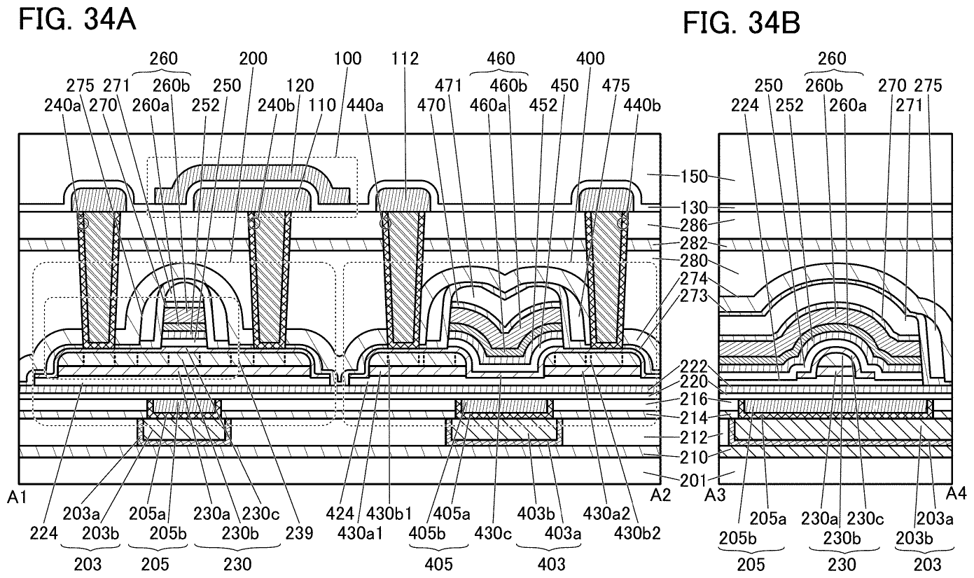

Hereinafter, a modification example of the transistor described in this embodiment will be described with reference to FIG. 34. Note that in the semiconductor device illustrated in FIG. 34, components having the same functions as the components included in the semiconductor device described in <Structure example of semiconductor device> are denoted by the same reference numerals.

The transistor 200 illustrate in FIG. 34 is different from the semiconductor device described in <Structure example of semiconductor device> at least in the shapes of the side surface of the insulator 250, the side surface of the insulator 252, the side surface of the conductor 260, and the side surface of the insulator 271. In addition, the transistor 400 illustrated in FIG. 34 is different from the semiconductor device described in <Structure example of semiconductor device> at least in the shapes of the side surface of the insulator 450, the side surface of the insulator 452, the side surface of the conductor 460, and the side surface of the insulator 471.

Specifically, as illustrated in FIG. 34, the side surface of the insulator 250, the side surface of the insulator 252, the side surface of the conductor 260, and the side surface of the insulator 271 may have a taper angle with respect to the top surface of the oxide 230. Moreover, the side surface of the insulator 450, the side surface of the insulator 452, the side surface of the conductor 460, and the side surface of the insulator 471 may have a taper angle with respect to the top surface of the oxide 430. With the shape, the coverage with the insulator 273 and the insulator 274 can be improved.

The structure, method, and the like described above in this embodiment can be used in combination as appropriate with the structures, methods, and the like described in the other embodiments.

### Embodiment 5

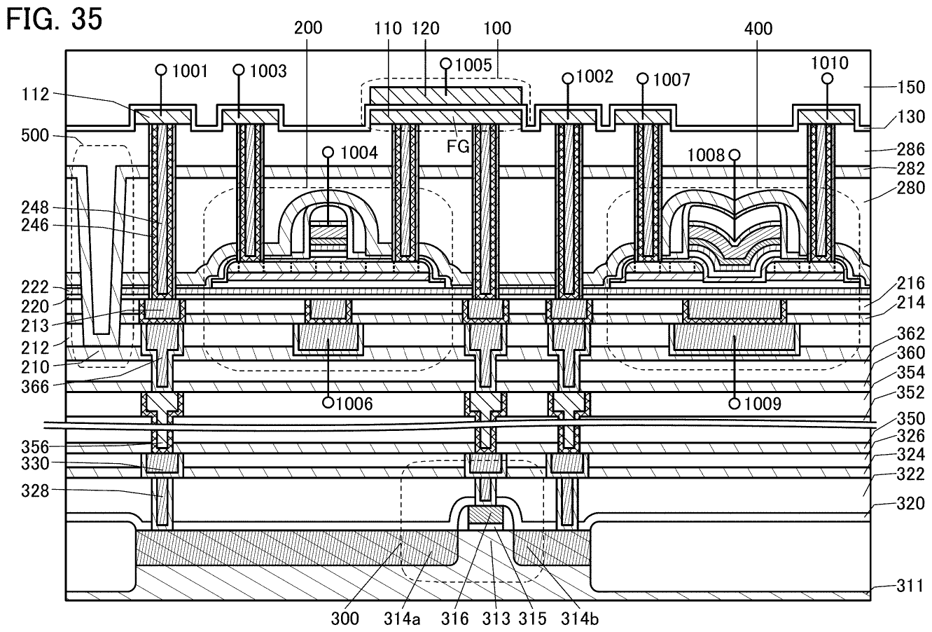

In this embodiment, one embodiment of a semiconductor device will be described with reference to FIG. 35.

### <Memory Device>

The semiconductor device illustrated in FIG. 35 is a memory device including the transistor 400, the transistor 300, the transistor 200, and the capacitor 100. One embodiment of the memory device is described below with reference to FIG. 35.

The transistor 200 is a transistor including a metal oxide in its channel formation region, and any of the transistors described in the above embodiments can be used as the transistor 200. Since the transistors described in the above embodiments can be formed with high yield even when miniaturized, the transistor 200 can be miniaturized. The use of such a transistor in a memory device allows miniaturization or high integration of the memory device. Since the off-state current of the transistor described in the above embodiment is small, a memory device using the transistor can retain stored data for a long time. In other words, since refresh operation is not required or frequency of refresh operation is extremely low, the power consumption of the memory device can be sufficiently reduced.

In FIG. 35, the wiring 1001 is electrically connected to the source of the transistor 300, and the wiring 1002 is electrically connected to the drain of the transistor 300. Furthermore, the wiring 1003 is electrically connected to one of the source and the drain of the transistor 200, the wiring 1004 is electrically connected to the first gate of the transistor 200, and the wiring 1006 is electrically connected to the second gate of the transistor 200. In addition, the gate of the transistor 300 and the other of the source and the drain of the transistor 200 are electrically connected to one electrode of the capacitor 100, and the wiring 1005 is electrically connected to the other electrode of the capacitor 100. The wiring 1007 is electrically connected to the source of the transistor 400, the wiring 1008 is electrically connected to the first gate of the transistor 400, the wiring 1009 is electrically connected to the second gate of the transistor 400, and the wiring 1010 is electrically connected to the drain of the transistor 400. Here, the wiring 1006, the wiring 1007, the wiring 1008, and the wiring 1009 are electrically connected to each other.

The semiconductor device illustrated in FIG. 35 has a feature that the potential of the gate of the transistor 300 can be retained, and thus enable writing, retaining, and reading of data as follows.

Writing and retaining of data are described. First, the potential of the wiring 1004 is set to a potential at which the transistor 200 is in a conduction state, so that the transistor 200 is brought into a conduction state. Accordingly, the potential of the wiring 1003 is supplied to the node FG where the gate of the transistor 300 and the one electrode of the capacitor 100 are electrically connected to each other. That is, a predetermined charge is supplied to the gate of the transistor 300 (writing). Here, one of charges providing two different potential levels (hereinafter, referred to as Low-level charge and High-level charge) is supplied. After that, the potential of the wiring 1004 is set to a potential at which the transistor 200 is in a non-conduction state, so that the transistor 200 is brought into a non-conduction state; thus, the charge is retained in the node FG (retaining).

In the case where the off-state current of the transistor 200 is small, the charge in the node FG is retained for a long time.

Next, reading of data is described. An appropriate potential (reading potential) is supplied to the wiring 1005 while a predetermined potential (constant potential) is supplied to the wiring 1001, whereby the wiring 1002 has a potential corresponding to the amount of charge retained in the node FG. This is because when the transistor 300 is of an n-channel type, an apparent threshold voltage V_{th_H} at the time when the High-level charge is supplied to the gate of the transistor 300 is lower than an apparent threshold voltage V_{th_L} at the time when the Low-level charge is supplied to the gate of the transistor 300. Here, an apparent threshold voltage refers to the potential of the wiring 1005 that is needed to bring the transistor 300 into a conduction state. Thus, the potential of the wiring 1005 is set to a potential V₀ that is between V_{th_H} and V_{th_L}, whereby the charge supplied to the node FG can be determined. For example, in the case where the High-level charge is supplied to the node FG in writing, the transistor 300 is in a conduction state when the potential of the wiring 1005 becomes V₀ (>V_{th_H}). On the other hand, in the case where the Low-level charge is supplied to the node FG, the transistor 300 remains in a non-conduction state even when the potential of the wiring 1005 becomes V₀ (<V_{th_L}). Thus, the data retained in the node FG can be read by determining the potential of the wiring 1002.

### <Structure of Memory Device>

FIG. 35 is a cross-sectional view of a memory device including the capacitor 100, the transistor 200, the transistor 300, and the transistor 400. Note that in the memory device illustrated in FIG. 35, components having the same functions as the components in the semiconductor device and the memory device described in the above embodiments are denoted by the same reference numerals.

The memory device of one embodiment of the present invention includes the transistor 300, the transistor 200, the transistor 400, and the capacitor 100 as illustrated in FIG. 35. The transistor 200 and the transistor 400 are provided above the transistor 300, and the capacitor 100 is provided above the transistor 300, the transistor 200, and the transistor 400.

Note that the capacitor and the transistor included in the semiconductor device described in the above embodiments can be used as the capacitor 100, the transistor 200, the transistor 300, and the transistor 400. Note that the capacitor 100, the transistor 300, the transistor 200, and the transistor 400 illustrated in FIG. 35 are just examples and there structures are not limited thereto; an appropriate transistor is used in accordance with a circuit configuration or a driving method.

Here, a dicing line (also referred to as a scribe line, a dividing line, or a cutting line) that is provided when a large-sized substrate is divided into semiconductor elements so that a plurality of semiconductor devices are obtained in a chip form will be described. Examples of a dividing method include the case where a groove (a dicing line) for dividing the semiconductor elements is formed on the substrate, and then the substrate is cut along the dicing line to divide (split) it into a plurality of semiconductor devices. For example, a structure 500 illustrated in FIG. 35 illustrates a cross section in the vicinity of the dicing line

As illustrated in the structure 500, for example, an opening reaching the insulator 210 is provided in the insulator 280, the insulator 274, the insulator 273, the insulator 222, the insulator 220, the insulator 216, the insulator 214, and the insulator 212, in the vicinity of a region overlapping with the dicing line provided in an end portion of the memory cell including the transistor 200 or the transistor 400. Furthermore, the insulator 282 is provided to cover side surfaces of the insulator 280, the insulator 274, the insulator 273, the insulator 222, the insulator 220, the insulator 216, the insulator 214, and the insulator 212, and the top surface of the insulator 210.

Thus, in the opening, the insulator 210 is in contact with the insulator 282. At this time, the insulator 210 and the insulator 282 are formed using the same material and the same method, whereby the adhesion therebetween can be improved. Aluminum oxide can be used, for example.

With the structure, the insulator 280, the transistor 200, and the transistor 400 can be enclosed with the insulator 210 and the insulator 282. The oxide 360, the insulator 222, and the insulator 282 have a function of inhibiting the diffusion of oxygen, hydrogen, and water; thus, even when the substrate is divided for each circuit region where the semiconductor element of this embodiment is formed, to be processed into a plurality of chips, the entry and diffusion of impurities such as hydrogen and water from the direction of a side surface of the divided substrate to the transistor 200 or the transistor 400 can be prevented.

Furthermore, with the structure, excess oxygen in the insulator 280 can be prevented from being diffused to the outside of the insulator 282 and the insulator 222. Accordingly, excess oxygen in the insulator 280 is efficiently supplied to the oxide where the channel is formed in the transistor 200 or the transistor 400. The oxygen can reduce oxygen vacancies in the oxide where the channel is formed in the transistor 200 or the transistor 400. Thus, the oxide where the channel is formed in the transistor 200 or the transistor 400 can be a metal oxide having a low density of defect states and stable characteristics. That is, a change in electrical characteristics of the transistor 200 or the transistor 400 can be reduced and the reliability can be improved.

The above is the description of the structure example. With the use of this structure, a change in electrical characteristics can be reduced and reliability can be improved in a semiconductor device using a transistor including a metal oxide. Alternatively, the power consumption of a semiconductor device using a transistor including a metal oxide can be reduced. Alternatively, a semiconductor device using a transistor including a metal oxide can be miniaturized or highly integrated. Alternatively, a miniaturized or highly integrated semiconductor device can be provided with high productivity.

### <Structure of Memory Cell Array>

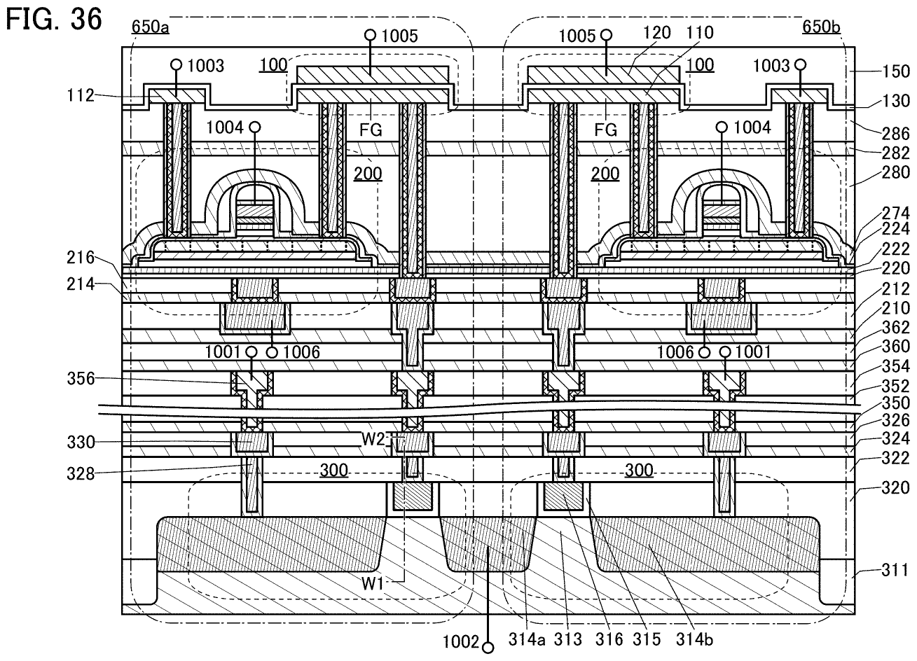

FIG. 36 illustrates an example of a memory cell array of this embodiment. When the transistors 200 are arranged in memory cells in a matrix, a memory cell array can be formed.

Note that the memory device illustrated in FIG. 36 is a semiconductor device forming a memory cell array in which the memory devices illustrated in FIG. 35 are arranged in a matrix. Note that one transistor 400 can control the back gate voltages of a plurality of transistors 200. For this reason, a smaller number of the transistors 400 than the transistors 200 are preferably provided.

Accordingly, in FIG. 36, the transistor 400 illustrated in FIG. 35 is omitted. FIG. 35 is a cross-sectional view which illustrates an extracted part of a row in the case where the memory devices illustrated in FIG. 35 are arranged in a matrix.

In addition, the structure of the transistor 300 is different from that in FIG. 35. In the transistor 300 illustrated in FIG. 36, the semiconductor region 313 (part of the substrate 311) in which a channel is formed has a convex shape. Furthermore, the conductor 316 is provided to cover the side surfaces and the top surface of the semiconductor region 313 with the insulator 315 therebetween. Note that for the conductor 316, a material that adjusts the work function may be used. Such a transistor 300 is also referred to as a FIN-type transistor because it utilizes a convex portion of the semiconductor substrate. Note that an insulator functioning as a mask for forming the convex portion may be included in contact with an upper portion of the convex portion. Furthermore, although the case where the convex portion is formed by processing part of the semiconductor substrate is described here, a semiconductor film having a convex shape may be formed by processing an SOI substrate.

In the memory device illustrated in FIG. 36, a memory cell 650a and a memory cell 650b are positioned adjacent to each other. In each of the memory cell 650a and the memory cell 650b, the transistor 300, the transistor 200, and the capacitor 100 are included and electrically connected to the wiring 1001, the wiring 1002, the wiring 1003, the wiring 1004, the wiring 1005, and the wiring 1006. Also in the memory cell 650a and the memory cell 650b, a node where a gate of the transistor 300 and one electrode of the capacitor 100 are electrically connected to each other is referred to as the node FG. Note that the wiring 1002 is a common wiring for the memory cell 650a and the memory cell 650b which are adjacent to each other.

In the case where memory cells are arranged in an array, data of a desired memory cell needs to be read in reading. For example, in the case where a memory cell array has a NOR-type structure, only data of a desired memory cell can be read by bringing the transistors 300 of memory cells from which data is not read into a non-conduction state. In this case, a configuration may be employed in which only data of a desired memory cell can be read by supplying a potential at which the transistor 300 is brought into a “non-conduction state” regardless of the charge supplied to the node FG, that is, a potential lower than V_{th_H}, to the wiring 1005 connected to the memory cells from which data is not read. Alternatively, in the case where a memory cell array has a NAND-type structure, for example, only data of a desired memory cell can be read by bringing the transistors 300 of memory cells from which data is not read into a conduction state. In this case, a configuration may be employed in which only data of a desired memory cell can be read by supplying a potential at which the transistor 300 is brought into a “conduction state” regardless of the charge supplied to the node FG, that is, a potential higher than V_{th_L}, to the wiring 1005 connected to the memory cells from which data is not read.

With the use of this structure, a change in electrical characteristics can be reduced and reliability can be improved in a semiconductor device using a transistor including an oxide semiconductor. Alternatively, the power consumption of a semiconductor device using a transistor including an oxide semiconductor can be reduced. Alternatively, a semiconductor device using a transistor including an oxide semiconductor can be miniaturized or highly integrated. Alternatively, a miniaturized or highly integrated semiconductor device can be provided with high productivity.

The composition, structure, method, and the like described above in this embodiment can be used in combination as appropriate with the compositions, structures, methods, and the like described in the other embodiments.

### Embodiment 6

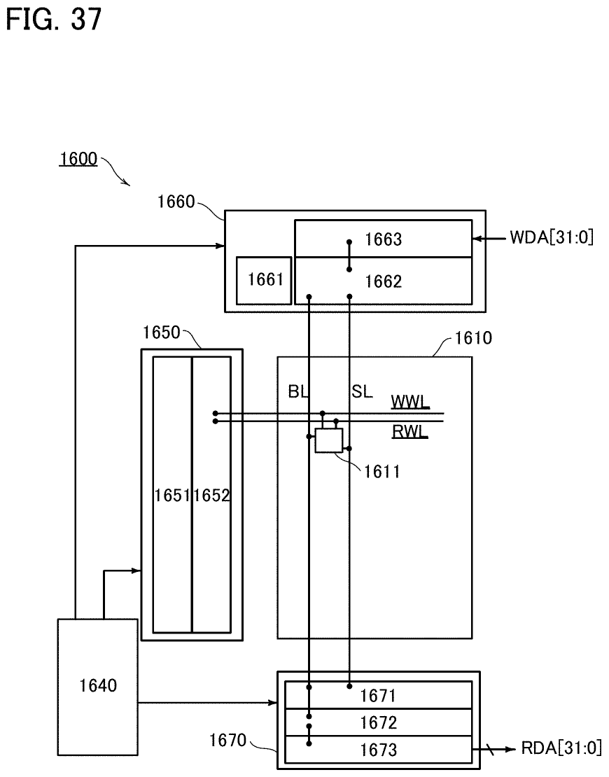

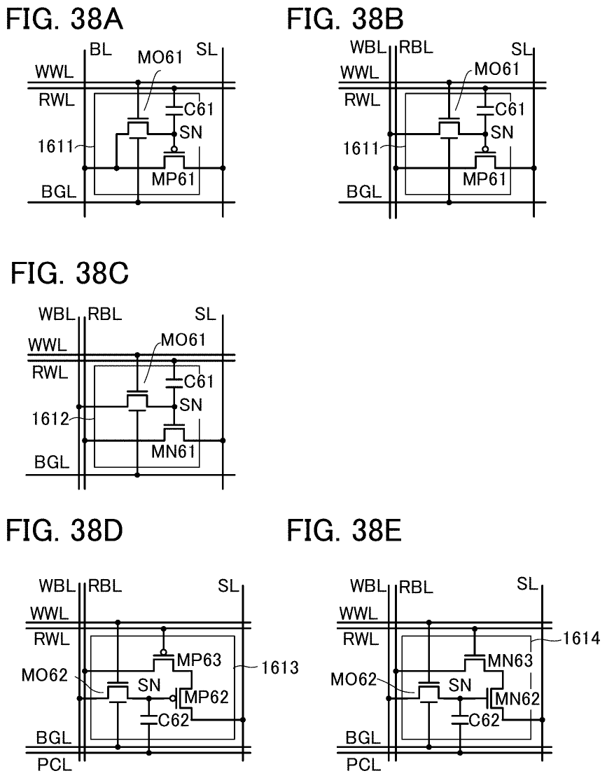

In this embodiment, a NOSRAM is described as an example of a memory device of one embodiment of the present invention, which includes a capacitor and a transistor using an oxide as a semiconductor (hereinafter referred to as an OS transistor) with reference to FIG. 37 and FIG. 38. A NOSRAM (registered trademark) is an abbreviation of “Nonvolatile Oxide Semiconductor RAM”, which indicates RAM including a gain cell (2T or 3T) memory cell.

Note that hereinafter, a memory device using an OS transistor, such as the NOSRAM, is referred to as an OS memory in some cases.

A memory device in which OS transistors are used in memory cells (hereinafter referred to as an “OS memory”) is used in the NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <<NOSRAM>>

FIG. 37 shows a configuration example of a NOSRAM. A NOSRAM 1600 shown in FIG. 37 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, bit lines BL, and source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives a source line SL and a bit line BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated by the DAC 1663 to the selected source line SL, a function of precharging the bit line BL, a function of bringing the bit line BL into an electrically floating state, and the like.

The output driver 1670 includes a selector 1671, an ADC (analog-digital converter circuit) 1672, and an output buffer 1673. The selector 1671 selects a source line SL to be accessed and transmits voltage of the selected source line SL to the ADC 1672. The ADC 1672 has a function of converting an analog voltage into 3-bit digital data. The voltage of the source line SL is converted into 3-bit data in the ADC 1672, and the output buffer 1673 stores the data output from the ADC 1672.

### <Memory Cell>

FIG. 38(A) is a circuit diagram showing a configuration example of the memory cell 1611. The memory cell 1611 is a 2T gain cell and is electrically connected to the word lines WWL and RWL, the bit line BL, the source line SL, and the wiring BGL. The memory cell 1611 includes a node SN, an OS transistor M061, a transistor MP61, and a capacitor C61. The OS transistor M061 is a write transistor. The transistor MP61 is a read transistor and is formed using a p-channel Si transistor, for example. The capacitor C61 is a storage capacitor for retaining the voltage of the node SN. The node SN is a data retaining node and corresponds to a gate of the transistor MP61 here.

The write transistor of the memory cell 1611 is formed using the OS transistor M061; thus, the NOSRAM 1600 can retain data for a long time.

In the example of FIG. 38(A), the bit line BL is a common bit line for writing and reading; however, as shown in FIG. 38(B), a write bit line WBL and a read bit line RBL may be provided.

FIG. 38(C) to FIG. 38(E) show other configuration examples of the memory cell. FIG. 38(C) to FIG. 38(E) show examples where the write bit line WBL and the read bit line RBL are provided; however, as shown in FIG. 38(A), a bit line BL shared in writing and reading may be provided.

A memory cell 1612 shown in FIG. 38(C) is a modification example of the memory cell 1611 where the read transistor is changed into an n-channel transistor (MN61). The transistor MN61 may be an OS transistor or a Si transistor.

The OS transistors M061 in the memory cells 1611 and 1612 may each be an OS transistor with no back gate.

A memory cell 1613 shown in FIG. 38(D) is a 3T gain cell and is electrically connected to the word lines WWL and RWL, the bit lines WBL and RBL, the source line SL, the wiring BGL, and a wiring PCL. The memory cell 1613 includes the node SN, an OS transistor M062, a transistor MP62, a transistor MP63, and a capacitor C62. The OS transistor M062 is a write transistor. The transistor MP62 is a read transistor and the transistor MP63 is a selection transistor.

The memory cell 1614 shown in FIG. 38(E) is a modification example of the memory cell 1613 where the read transistor and the selection transistor are changed into n-channel transistors (MN62 and MN63). Each of the transistors MN62 and MN63 may be an OS transistor or a Si transistor.

The OS transistors provided in the memory cells 1611 to 1614 may each be a transistor with no back gate or a transistor with a back gate.

There is theoretically no limitation on the number of rewriting operations of the NOSRAM 1600 because data is rewritten by charging and discharging of the capacitor C61; and data can be written and read with low energy. Furthermore, since data can be retained for a long time, the refresh rate can be reduced.

In the case where the semiconductor device described in any of the above embodiments is used for the memory cells 1611, 1612, 1613, and 1614, the transistor 200 can be used as the OS transistors M061 and M062, the capacitor 100 can be used as the capacitors C61 and C62, and the transistor 300 can be used as the transistors MP61 and MN62. Thus, the area occupied by each set consisting of one transistor and one capacitor in the top view can be reduced, so that the memory device of this embodiment can be further highly integrated. As a result, storage capacity per unit area of the memory device of this embodiment can be increased.

The structure described in this embodiment can be used in combination with the structures described in the other embodiments as appropriate.

### Embodiment 7

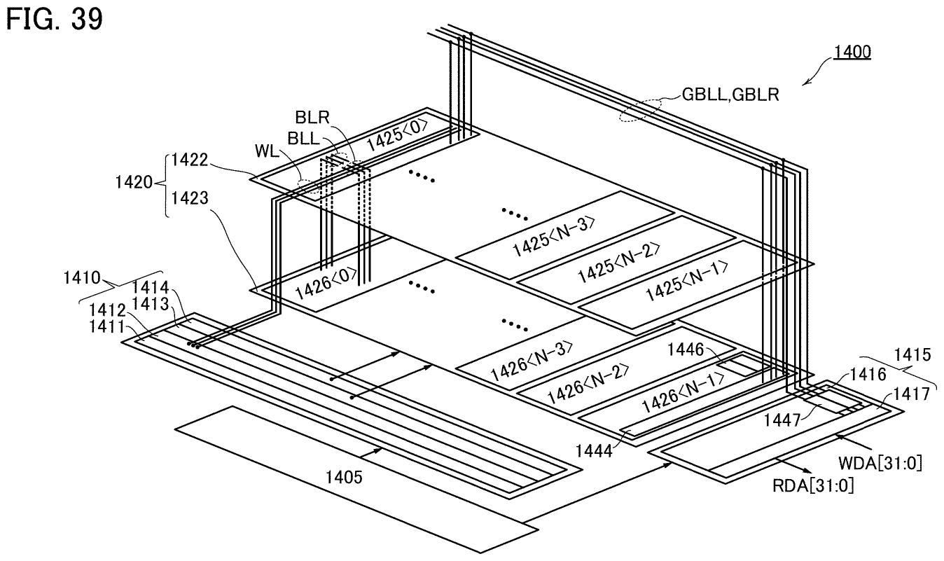

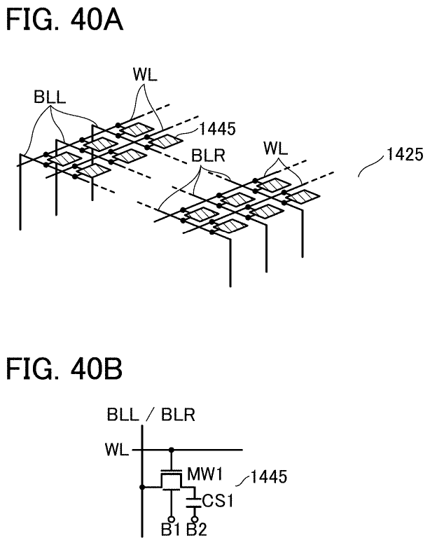

In this embodiment, a DOSRAM will be described as an example of the memory device of one embodiment of the present invention that includes an OS transistor and a capacitor, with reference to FIG. 39 and FIG. 40. A DOSRAM (registered trademark) is an abbreviation of “Dynamic Oxide Semiconductor RAM,” which is a RAM including a 1T (transistor) 1C (capacitor) memory cell. As in the NOSRAM, an OS memory is used in the DOSRAM.

### <<DOSRAM 1400>>

FIG. 39 shows a configuration example of the DOSRAM. As shown in FIG. 39, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1>, where N is an integer greater than or equal to 2. FIG. 40(A) illustrates a configuration example of the local memory cell array 1425. The local memory cell array 1425 includes a plurality of memory cells 1445, a plurality of word lines WL, and a plurality of bit lines BLL and BLR. In the example of FIG. 40(A), the local memory cell array 1425 has an open bit-line architecture but may have a folded bit-line architecture.

FIG. 40(B) shows a circuit configuration example of the memory cell 1445. The memory cell 1445 includes a transistor MW1, a capacitor CS1, and terminals B1 and B2. The transistor MW1 has a function of controlling charging and discharging of the capacitor CS1. A gate of the transistor MW1 is electrically connected to the word line, a first terminal of the transistor MW1 is electrically connected to the bit line, and a second terminal of the transistor MW1 is electrically connected to a first terminal of the capacitor CS1. A second terminal of the capacitor CS1 is electrically connected to the terminal B2. A constant voltage (e.g., a low power supply voltage) is input to the terminal B2.

In the case where the semiconductor device described in any of the above embodiments is used in the memory cell 1445, the transistor 200 can be used as the transistor MW1, and the capacitor 100 can be used as the capacitor CS1. Thus, the area occupied by each set consisting of one transistor and one capacitor in the top view can be reduced, so that the memory device of this embodiment can be further highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with a voltage of the terminal B1. For example, the voltage of the terminal B1 is a fixed voltage (e.g., a negative constant voltage); alternatively, the voltage of the terminal B1 may be changed in response to the operation of the DOSRAM 1400.

The back gate of the transistor MW1 may be electrically connected to the gate, the source, or the drain of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, a bit line pair refers to two bit lines which are compared by a sense amplifier at the same time. A global bit line pair refers to two global bit lines which are compared by a global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data, and retains the amplified data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address signal is written to the global bit line pair by the switch array 1444. The global sense amplifier array 1416 determines and retains the data of the global bit line pair. The data retained in the global sense amplifier array 1416 is output to the input/output circuit 1417. Thus, the data reading operation is completed.

There is theoretically no limitation on the number of rewriting operations of the DOSRAM 1400 because data is rewritten by charging and discharging of the capacitor CS1; and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce the power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

The structure described in this embodiment can be used in combination with the structures described in the other embodiments as appropriate.

### Embodiment 8

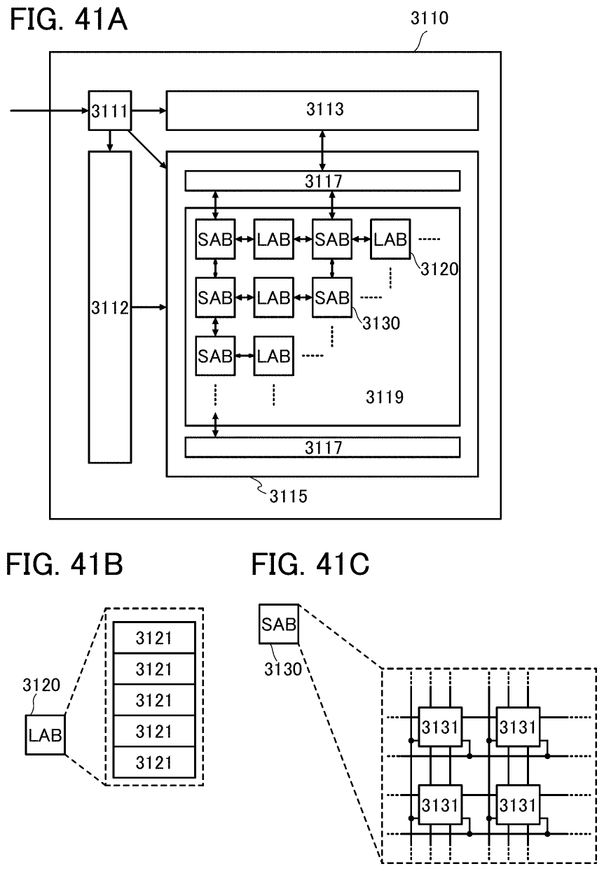

In this embodiment, an FPGA (field programmable gate array) is described as an example of a semiconductor device of one embodiment of the present invention in which an OS transistor and a capacitor are used, with reference to FIG. 41 to FIG. 44. In the FPGA of this embodiment, an OS memory is used for a configuration memory and a register. Here, such an FPGA is referred to as an “OS-FPGA”.

### <<OS-FPGA>>

FIG. 41(A) illustrates a configuration example of an OS-FPGA. An OS-FPGA 3110 illustrated in FIG. 41(A) is capable of NOFF (normally-off) computing that executes context switching by a multi-context configuration and fine-grained power gating. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of programmable logic elements (PLEs) 3121. FIG. 41(B) illustrates an example in which the LAB 3120 includes five PLEs 3121. As illustrated in FIG. 41(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

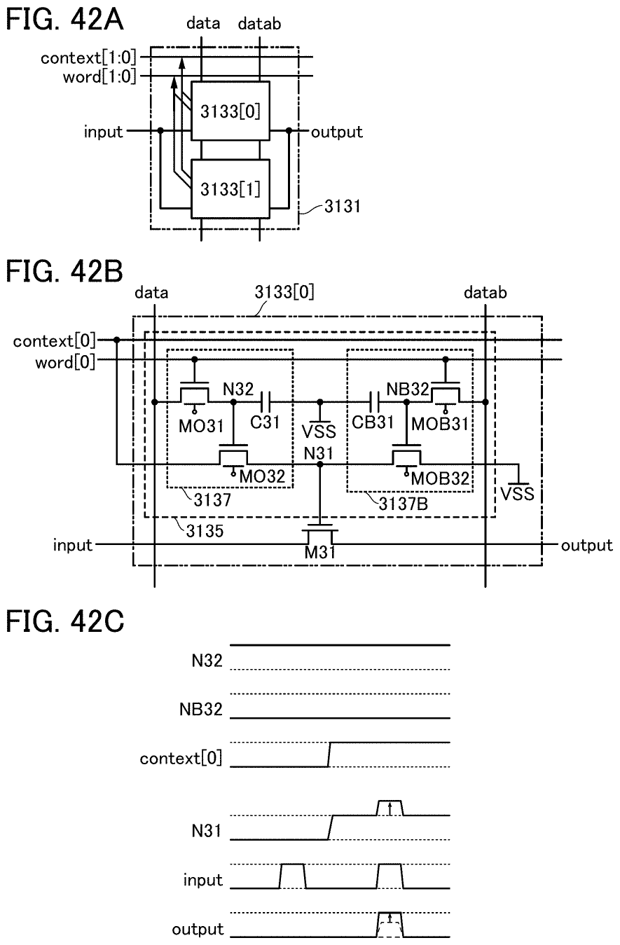

The SB 3131 is described with reference to FIG. 42(A) to FIG. 42(C). To the SB 3131 illustrated in FIG. 42(A), data, datab, and signals context[1:0] and word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes PRSs (programmable routing switches) 3133[0] and 3133[1]. The PRS 3133[0] and the PRS 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 42(B) illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signals context[0] and word[0] are input to the PRS 3133[0], and the signals context[1] and word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes memory circuits 3137 and 3137B. The memory circuits 3137 and 3137B have the same circuit configuration. The memory circuit 3137 includes a capacitor C31 and OS transistors M031 and M032. The memory circuit 3137B includes a capacitor CB31 and OS transistors MOB31 and MOB32.

In the case where the semiconductor device described in any of the above embodiments is used in the SAB 3130, the transistor 200 can be used as the OS transistors M031 and MOB31, and the capacitor 100 can be used as the capacitors C31 and CB31. Thus, the area occupied by each set consisting of one transistor and one capacitor in the top view can be reduced, so that the memory device of this embodiment can be further highly integrated.

The OS transistors M031, M032, MOB31, and MOB32 each include a back gate, and each of these back gates are electrically connected to a power supply line that supplies a fixed voltage.

A gate of the Si transistor M31, a gate of the OS transistor M032, and a gate of the OS transistor MOB32 correspond to a node N31, a node N32, and a node NB32, respectively. The node N32 and the node NB32 are each a charge retention node of the CM 3135. The OS transistor M032 controls the conduction state between the node N31 and a signal line for the signal context[0]. The OS transistor MOB32 controls the conduction state between the node N31 and a low-potential power supply line VSS.

Data retained in the memory circuits 3137 and 3137B have a complementary relationship. Thus, either the OS transistor M032 or the OS transistor MOB32 is turned on.

The operation example of the PRS 3133[0] is described with reference to FIG. 42(C). In the PRS 3133[0], to which configuration data has already been written, the node N32 is at “H”, whereas the node NB32 is at “L”.

The PRS 3133[0] is inactive while the signal context[0] is at “L”. During this period, even when an input terminal (input) of the PRS 3133[0] is transferred to “H”, the gate of the Si transistor M31 is kept at “L” and an output terminal (output) of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

When the input terminal is transferred to “H” during a period in which the PRS 3133[0] is active, the gate voltage of the Si transistor M31 is increased by boosting because the OS transistor M032 of the memory circuit 3137 is a source follower. As a result, the OS transistor M032 of the memory circuit 3137 loses the driving capability, and the gate of the Si transistor M31 is brought into a floating state.

In the PRS 3133 with a multi-context function, the CM 3135 also functions as a multiplexer.

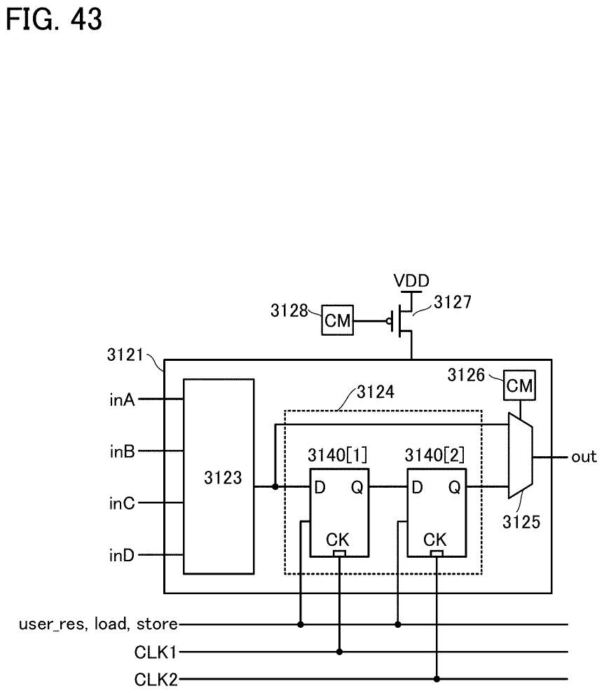

FIG. 43 illustrates a configuration example of the PLE 3121. The PLE 3121 includes a lookup table block (LUT block) 3123, a register block 3124, a selector 3125, and a CM 3126. The LUT block 3123 is configured to multiplex an output out of a pair of 16-bit CMs therein in accordance with inputs inA to inD. The selector 3125 selects an output of the LUT block 3123 or an output of the register block 3124 in accordance with the configuration stored in the CM 3126.

The PLE 3121 is electrically connected to a power supply line for a voltage VDD through a power switch 3127. Whether the power switch 3127 is turned on or off is determined in accordance with configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as [OS-FF]).

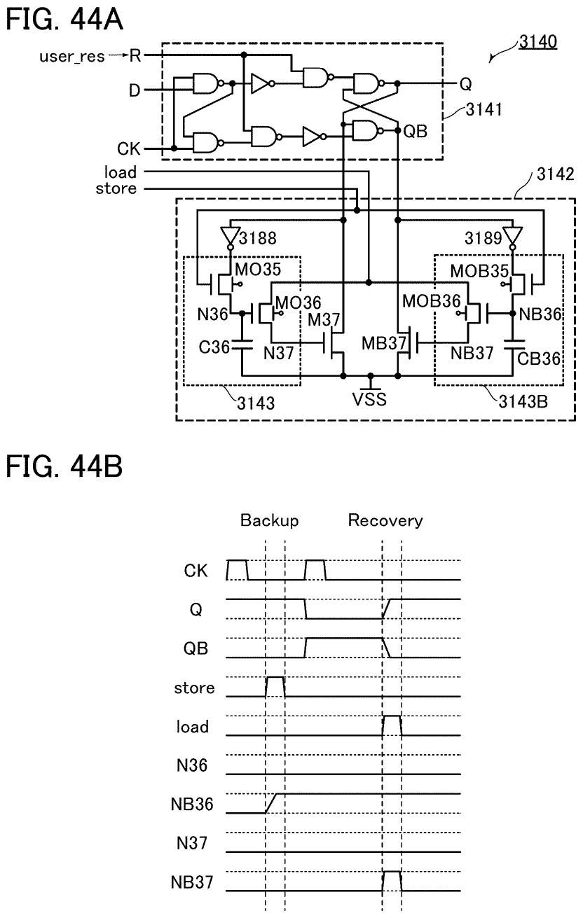

The register block 3124 includes OS-FFs 3140[1] and 3140[2]. Signals user_res, load, and store are input to the OS-FFs 3140[1] and 3140[2]. A clock signal CLK1 is input to the OS-FF 3140[1] and a clock signal CLK2 is input to the OS-FF 3140[2]. FIG. 44(A) illustrates a configuration example of the OS-FF 3140.

The OS-FF 3140 includes an FF 3141 and a shadow register 3142. The FF 3141 includes nodes CK, R, D, Q, and QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in response to the signal store and writes back the backed up data to the nodes Q and QB in response to the signal load.

The shadow register 3142 includes inverter circuits 3188 and 3189, Si transistors M37 and MB37, and memory circuits 3143 and 3143B. The memory circuits 3143 and 3143B each have the same circuit configuration as the memory circuit 3137 of the PRS 3133. The memory circuit 3143 includes a capacitor C36 and OS transistors M035 and M036. The memory circuit 3143B includes a capacitor CB36 and OS transistors MOB35 and MOB36. A node N36 and a node NB36 correspond to a gate of the OS transistor M036 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in any of the above embodiments is used in the LAB 3120, the transistor 200 can be used as the OS transistors M035 and MOB35, and the capacitor 100 can be used as the capacitors C36 and CB36. Thus, the area occupied by each set consisting of one transistor and one capacitor in the top view can be reduced, so that the memory device of this embodiment can be further highly integrated.

The OS transistors M035, M036, MOB35, and MOB36 each include a back gate, and each of these back gates are electrically connected to a power supply line that supplies a fixed voltage.

An example of an operation method of the OS-FF 3140 is described with reference to FIG. 44(B).

### (Backup)

When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power supply is stopped.

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is recovered to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

The structure described in this embodiment can be used in combination with the structures described in the other embodiments as appropriate.

### Embodiment 9

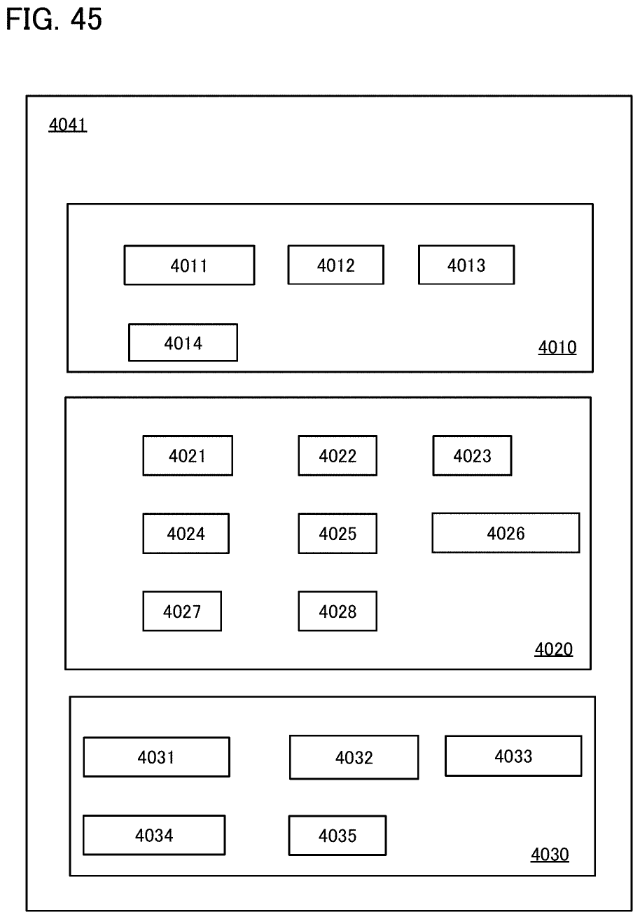

In this embodiment, an AI system in which the semiconductor device described in any of the above-described embodiments is used is described with reference to FIG. 45.

FIG. 45 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data has to be stored piece by piece because of the circuit area limitation and small storage capacity of the SRAM. The DOSRAM 4012 has a larger storage capacity than the SRAM because memory cells of the DOSRAM can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, the NOSRAM has no limitation on the number of times of data writing.

Furthermore, the NOSRAM 4013 can store multilevel data of two or more bits as well as one-bit binary data. The multilevel data storage in the NOSRAM 4013 leads to a reduction of the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. Note that in this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance of program.

The FPGA 4014 is an FPGA including an OS transistor. An OS-FPGA can have a smaller memory area than an FPGA including an SRAM. Thus, adding a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute neural network calculation at high speed with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not need to include all of the following: the DOSRAM 4012, the NOSRAM 4013, and the FPGA 4014. One or more memories selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be performed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation frequency is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute neural network calculation at high speed with low power consumption.

Data used for the neural network calculation is stored in an external storage device [such as an HDD (Hard Disk Drive) or an SDD (Solid State Drive)] in many cases. Therefore, the AI system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus), an I2C (Inter-Integrated Circuit), or the like, for example.

The AI system 4041 can perform learning or make an inference using data obtained via the Internet. For this reason, the AI system 4041 preferably includes the communication module 4035.

The analog arithmetic circuit 4011 may use a multi-level flash memory as an analog memory. However, the flash memory has a limit on the number of rewriting times. In addition, the multi-level flash memory is extremely difficult to embed (to form the arithmetic circuit and the memory on the same die).

Alternatively, the analog arithmetic circuit 4011 may include a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

The structure described in this embodiment can be used in combination with the structures described in the other embodiments as appropriate.

### Embodiment 10

### <Application Example of AI System>

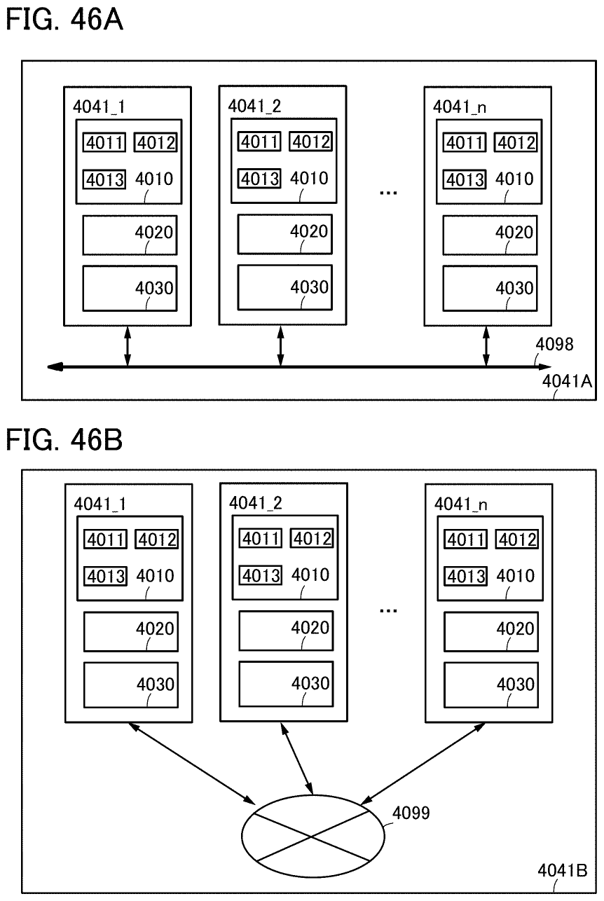

In this embodiment, application examples of the AI system described in the above embodiment are described with reference to FIG. 46.

FIG. 46(A) is an AI system 4041A in which the AI systems 4041 described with FIG. 45 are arranged in parallel and a signal can be transmitted between the systems via a bus line.

The AI system 4041A illustrated in FIG. 46(A) includes a plurality of AI systems 4041_1 to 4041_n (n is a natural number). The AI system 4041_1 to the AI system 4041_n are connected to each other via a bus line 4098.

FIG. 46(B) is an AI system 4041B in which the AI systems 4041 described with FIG. 42 are arranged in parallel as in FIG. 43(A) and a signal can be transmitted between the systems via a network.

The AI system 4041B illustrated in FIG. 46(B) includes the plurality of AI systems 4041_1 to 4041_n. The AI system 4041_1 to the AI system 4041_n are connected to each other via a network 4099.

A structure may be employed in which a communication module is provided in each of the AI system 4041_1 to the AI system 4041_n to perform wireless or wired communication via the network 4099. A communication module can perform communication via an antenna. For example, the communication can be performed in such a manner that an electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

With the structure in FIG. 46(A) or 46(B), analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. When the signal processing or learning is performed by different AI systems, the amount of information processed by each AI system can be reduced. Accordingly, the signal processing or learning can be performed with a smaller amount of arithmetic processing. As a result, recognition accuracy can be increased. The information obtained with each AI system is expected to enable instant understanding of collective biological information that irregularly changes.

The structure described in this embodiment can be used in combination with the structures described in the other embodiments as appropriate.

### Embodiment 11

In this embodiment, an example of an IC into which the AI system described in the above embodiment is incorporated is described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

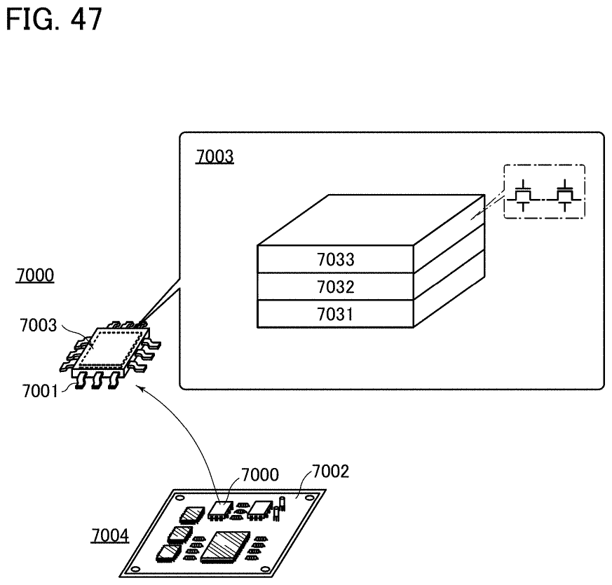

FIG. 47 illustrates the example of the IC into which the AI system is incorporated. An AI system IC 7000 illustrated in FIG. 47 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiment are provided on one die. The circuit portion 7003 has a stacked-layer structure as illustrated in FIG. 21 in the above embodiment, and is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 47, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the A1 system can be formed through the same manufacturing process. Thus, the number of steps in the manufacturing process of the IC described in this embodiment does not need to be increased even when the number of elements is increased, and accordingly the AI system can be incorporated into the IC at low cost.

The structure described in this embodiment can be used in combination with the structures described in the other embodiments as appropriate.

### Embodiment 12

### <Electronic Device>

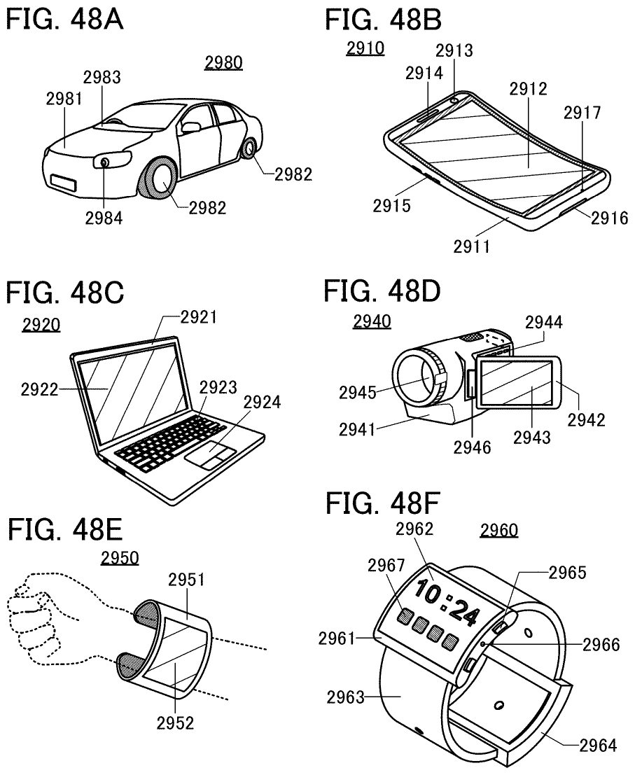

A semiconductor device of one embodiment of the present invention can be used for a variety of electronic devices. FIG. 48 illustrates specific examples of the electronic devices using the semiconductor device of one embodiment of the present invention.

FIG. 48(A) is an external view illustrating an example of a car. An automobile 2980 includes a car body 2981, wheels 2982, a dashboard 2983, lights 2984, and the like. The automobile 2980 also includes an antenna, a battery, and the like.

An information terminal 2910 illustrated in FIG. 48(B) includes a housing 2911, a display portion 2912, a microphone 2917, a speaker portion 2914, a camera 2913, an external connection portion 2916, operation switches 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

A notebook personal computer 2920 illustrated in FIG. 48(C) includes a housing 2921, a display portion 2922, a keyboard 2923, a pointing device 2924, and the like. In addition, the notebook personal computer 2920 includes an antenna, a battery, and the like inside the housing 2921.

A video camera 2940 illustrated in FIG. 48(D) includes a housing 2941, a housing 2942, a display portion 2943, operation switches 2944, a lens 2945, a joint 2946, and the like. The operation switches 2944 and the lens 2945 are provided on the housing 2941, and the display portion 2943 is provided on the housing 2942. The video camera 2940 also includes an antenna, a battery, and the like inside the housing 2941. A structure is employed in which the housing 2941 and the housing 2942 are connected to each other with the joint 2946, and the angle between the housing 2941 and the housing 2942 can be changed with the joint 2946. The orientation of an image displayed on the display portion 2943 may be changed and display and non-display of an image can be switched depending on the angle between the housing 2941 and the housing 2942.

FIG. 48(E) illustrates an example of a bangle-type information terminal. An information terminal 2950 includes a housing 2951, a display portion 2952, and the like. The information terminal 2950 also includes an antenna, a battery, and the like inside the housing 2951. The display portion 2952 is supported by the housing 2951 having a curved surface. A display panel using a flexible substrate is provided in the display portion 2952, whereby the user-friendly information terminal 2950 that is flexible and lightweight can be provided.

FIG. 48(F) illustrates an example of a watch-type information terminal. An information terminal 2960 includes a housing 2961, a display portion 2962, a band 2963, a buckle 2964, operation switches 2965, an input/output terminal 2966, and the like. In addition, the information terminal 2960 includes an antenna, a battery, and the like inside the housing 2961. The information terminal 2960 is capable of executing a variety of applications such as mobile phone calls, e-mailing, viewing and editing texts, music reproduction, Internet communication, and a computer game.

The display surface of the display portion 2962 is curved, and display can be performed along the curved display surface. In addition, the display portion 2962 includes a touch sensor, and operation can be performed by touching the screen with a finger, a stylus, or the like. For example, by touching an icon 2967 displayed on the display portion 2962, an application can be started. The operation switches 2965 can have a variety of functions such as time setting, power on/off operation, turning on/off operation of wireless communication, setting and cancellation of a silent mode, and setting and cancellation of a power saving mode. For example, the functions of the operation switches 2965 can be set by the operation system incorporated in the information terminal 2960.

The information terminal 2960 can execute near field communication conformable to a communication standard. For example, mutual communication with a headset capable of wireless communication enables hands-free calling. Moreover, the information terminal 2960 includes the input/output terminal 2966, and thus can perform direct data transmission with another information terminal through a connector. In addition, charging can be performed via the input/output terminal 2966. Note that the charging operation may be performed by wireless power feeding without through the input/output terminal 2966.

For example, a memory device using the semiconductor device of one embodiment of the present invention can retain control data, a control program, or the like of the above-described electronic device for a long time. With the use of the semiconductor device of one embodiment of the present invention, a highly reliable electronic device can be achieved.

This embodiment can be implemented in combination with the structures described in the other embodiments, example, and the like as appropriate.

### Example

This example confirmed whether the structure of the transistor 200 of one embodiment of the present invention can be actually fabricated or not. Specifically, samples subjected to the steps from the deposition of the insulator 220 to the formation of the insulator 275 (or the formation of the insulator 272 in a later step) in the above-described <Method for fabricating semiconductor device> (FIG. 3 to FIG. 13) were prepared, and then the cross sections of the samples were observed to confirm the above.

### <Structure and Fabrication Method of Samples>

In this example, two kinds of samples were prepared; one is a sample assumed to be a transistor having the structure illustrated in FIG. 1, and the other is a sample assumed to be a transistor having the structure illustrated in FIG. 14. The structures and fabrication methods of the samples prepared in this example will be described below. Note that description below is common for the above two kinds of samples prepared in this example, unless otherwise specified.

A silicon substrate was used as a substrate over which the sample was fabricated. A 400-nm-thick thermal oxidation film was deposited over the silicon substrate, and 40-nm-thick aluminum oxide was deposited thereover by a sputtering method.

The insulator 220 was deposited over the above substrate. For the insulator 220, 150-nm-thick silicon oxide was deposited by a CVD method.

For the insulator 222 over the insulator 220, 20-nm-thick aluminum oxide was deposited by an ALD method.

For the insulator 224 over the insulator 222, 30-nm-thick silicon oxide was deposited by a CVD method.

The oxide 230 (the oxide 230a, the oxide 230b, and the oxide 230c) was formed in the following manner: first, the oxide 230a was deposited over the insulator 224 to a thickness of 5 nm by a sputtering method using a target with In:Ga:Zn=1:3:4 [atomic ratio], the oxide 230b was deposited thereover to a thickness of 20 nm by a sputtering method using a target with In: Ga:Zn=1:1:1 [atomic ratio] (the oxide film 230A and the oxide film 230B), and then dry etching treatment was performed.

Next, the oxide 230c over the oxide 230b was formed in such a manner that a 5-nm-thick film (the oxide film 230C) was deposited by a sputtering method using a target with In:Ga:Zn=1:3:4 [atomic ratio], and dry etching treatment was performed thereon.

The insulator 250 over the oxide 230 (the oxide 230a, the oxide 230b, and the oxide 230c) was formed by performing dry etching treatment on 5-nm-thick silicon oxynitride (the insulating film 250A) deposited by a CVD method.

The insulator 252 over the insulator 250 was formed by performing dry etching treatment on 5-nm-thick aluminum oxide (the insulating film 252A) deposited by a sputtering method.

The conductor 260 (the conductor 260a and the conductor 260b) over the insulator 252 was formed by performing dry etching treatment on 10-nm-thick titanium nitride (the conductive film 260A) deposited by a sputtering method and 30-nm-thick tungsten (the conductive film 260B) deposited thereover by a sputtering method.

The insulator 270 over the conductor 260 was formed by performing dry etching treatment on 7-nm-thick aluminum oxide (the insulating film 270A) deposited by an ALD method.

The insulator 271 over the insulator 270 was formed by performing dry etching treatment on 100-nm-thick silicon oxide (the insulating film 271A) deposited by a CVD method.

As described in <Method for fabricating semiconductor device>, the above-described dry etching treatment for forming the insulator 250, the insulator 252, the conductor 260 (the conductor 260a and the conductor 260b), the insulator 270, and the insulator 271 was performed after the insulating film 250A, the conductive film 260A, the conductive film 260B, the insulating film 270A, and the insulating film 271A were sequentially deposited.

The insulator 273 (see FIG. 1), which is in contact with the top surface of the insulator 222, the side surface of the insulator 224, the side surface of the oxide 230c, the top surface of the oxide 230c, the side surface of the insulator 250, the side surface of the insulator 252, the side surface of the conductor 260, the side surface of the insulator 270, and the top surface of the insulator 271, was formed by performing dry etching treatment on 5-nm-thick aluminum oxide (the insulating film 273A) deposited by an ALD method. The insulator 272 (see FIG. 14), which is in contact with the top surface of the oxide 230c, the side surface of the insulator 250, the side surface of the insulator 252, the side surface of the conductor 260, the side surface of the insulator 270, and the top surface of the insulator 271, was formed by performing dry etching treatment on 5-nm-thick aluminum oxide (the insulating film 272A) by an ALD method.

The insulator 275 over the insulator 273 and the insulator 272 was formed in such a manner that 50-nm-thick silicon oxide (the insulating film 275A) was deposited by a CVD method and dry etching treatment was performed thereon.

As described in <Method for fabricating semiconductor device>, the above-described dry etching treatment for forming the insulator 273 (or the insulator 272) and the insulator 275 was performed after the insulating film 273A (or the insulating film 272A) and the insulating film 275A were sequentially deposited.

The above is the structures and fabrication methods of the samples prepared in this example.

### <Cross-Sectional Observation of Sample>

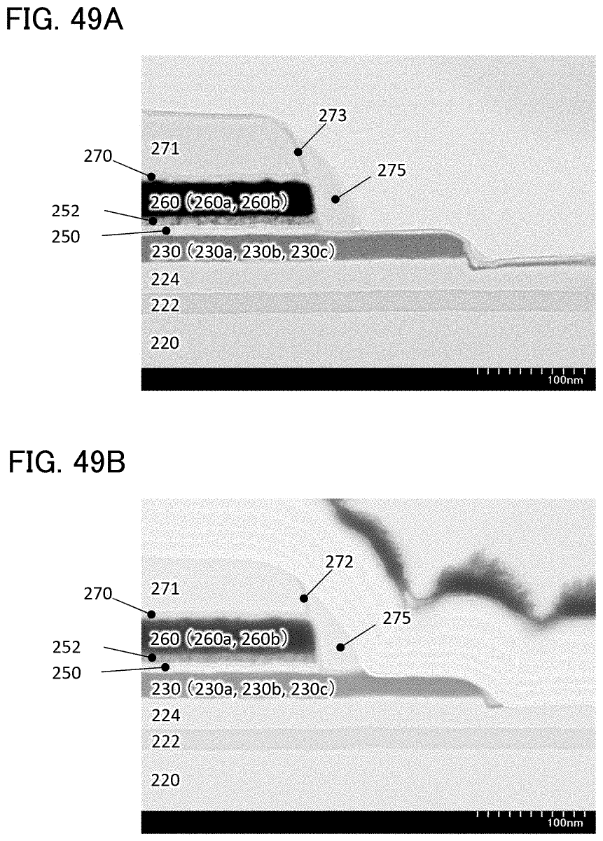

FIG. 49 shows the cross-sectional observation results of the samples prepared in the above-described manner. FIG. 49(A) is a cross section of the sample assumed to be a transistor having the structure illustrated in FIG. 1, and FIG. 49(B) is a cross section of the sample assumed to be a transistor having the structure illustrated in FIG. 14. Note that the cross sections observed in this example are part of a portion indicated by the dashed-dotted line A1-A2 in each of FIG. 1 and FIG. 14, that is, part of a portion corresponding to the transistor 200 in the channel length direction.

The cross-sectional views of the samples shown in FIG. 49 are bright-field images obtained with a scanning transmission electron microscope (STEM) (hereinafter, the images are also referred to as TEM images). The TEM images were obtained using a scanning transmission electron microscope HD-2700, manufactured by Hitachi High-Technologies Corporation, and at the time of image obtaining, the acceleration voltage was 200 kV and the beam diameter was approximately 0.4 nmφ.

As described in Embodiment 1, the transistor illustrated in FIG. 1 includes the insulator 273, whereas the transistor illustrated in FIG. 14 is different therefrom in including the insulator 272 having a function of a side barrier instead of the insulator 273. The shape is different in that the insulator 273 is provided to extend beyond both ends of the oxide 230 (see FIG. 1(B)), whereas the insulator 272 is not provided outside the bottom surface of the insulator 275 (see FIG. 14(B)). From FIG. 49(A), it was found that the insulator 273 remained in the outer region than the end portion of the oxide 230, and a processed shape substantially corresponding to the cross-sectional shape of the transistor illustrated in FIG. 1(B) was obtained in the sample prepared in this example. In addition, from FIG. 49(B), it was found that the insulator 272 was processed at a portion overlapping with the end of the bottom surface of the insulator 275, and a processed shape substantially corresponding to the cross-sectional shape of the transistor illustrated in FIG. 14(B) was obtained in the other sample prepared in this example.

As described above, this example confirms that the structure of the transistor 200 of one embodiment of the present invention can be actually fabricated.

The structure described above in this example can be used in combination with the other example or the other embodiments as appropriate.

### REFERENCE NUMERALS

100: capacitor
100a: capacitor
100b: capacitor
110: conductor
112: conductor
120: conductor
130: insulator
150: insulator
200: transistor
200a: transistor
200b: transistor
203: conductor
203a: conductor
203b: conductor
205: conductor
205a: conductor
205b: conductor
205B: conductive film
207: conductor
207a: conductor
207b: conductor
210: insulator
212: insulator
214: insulator
216: insulator
218: conductor
220: insulator
222: insulator
224: insulator
224A: insulating film
230: oxide
230a: oxide
230A: oxide film
230b: oxide
230B: oxide film
230c: oxide
230C: oxide film
231: region
231a: region
231b: region
232: region
232a: region
232b: region
234: region
236: region
236a: region
236b: region
239: region
240: conductor
240a: conductor
240b: conductor
240c: conductor
246: conductor
248: conductor
250: insulator
250A: insulating film
252: insulator
252A: insulating film
260: conductor
260a: conductor
260A: conductive film
260b: conductor
260B: conductive film
270: insulator
270A: insulating film
271: insulator
271A: insulating film
272: insulator
272A: insulating film
273: insulator
273A: insulating film
274: insulator
274A: insulating film
275: insulator
275A: insulating film
280: insulator
282: insulator
286: insulator
300: transistor
311: substrate
313: semiconductor region
314a: low-resistance region
314b: low-resistance region
315: insulator
316: conductor
320: insulator
322: insulator
324: insulator
326: insulator
328: conductor
330: conductor
350: insulator
352: insulator
354: insulator
356: conductor
360: insulator
362: insulator
364: insulator
366: conductor
370: insulator
372: insulator
374: insulator
376: conductor
380: insulator
382: insulator
384: insulator
386: conductor
600: cell
600a: cell
600b: cell
610: circuit
620: circuit
1001: wiring
1002: wiring
1003: wiring
1004: wiring
1005: wiring
1006: wiring
1400: DOSRAM
1405: controller
1410: row circuit
1411: decoder
1412: word line driver circuit
1413: column selector
1414: sense amplifier driver circuit
1415: column circuit
1416: global sense amplifier array
1417: input/output circuit
1420: MC-SA array
1422: memory cell array
1423: sense amplifier array
1425: local memory cell array
1426: local sense amplifier array
1444: switch array
1445: memory cell
1446: sense amplifier
1447: global sense amplifier
1600: NOSRAM
1610: memory cell array
1611: memory cell
1612: memory cell
1613: memory cell
1614: memory cell
1640: controller
1650: row driver
1651: row decoder
1652: word line driver
1660: column driver
1661: column decoder
1662: driver
1663: DAC
1670: output driver
1671: selector
1672: ADC
1673: output buffer
2000: CDMA
2910: information terminal
2911: housing
2912: display portion
2913: camera
2914: speaker portion
2915: operation switch
2916: external connection portion
2917: microphone
2920: notebook personal computer
2921: housing
2922: display portion
2923: keyboard
2924: pointing device
2940: video camera
2941: housing
2942: housing
2943: display portion
2944: operation switch
2945: lens
2946: joint
2950: information terminal
2951: housing
2952: display portion
2960: information terminal
2961: housing
2962: display portion
2963: band
2964: buckle
2965: operation switch
2966: input/output terminal
2967: icon
2980: automobile
2981: car body
2982: wheel
2983: dashboard
2984: light
3110: OS-FPGA
3111: controller
3112: word driver
3113: data driver
3115: programmable area
3117: IOB
3119: core
3120: LAB
3121: PLE
3123: LUT block
3124: register block
3125: selector
3126: CM
3127: power switch
3128: CM
3130: SAB
3131: SB
3133: PRS
3135: CM
3137: memory circuit
3137B: memory circuit
3140: OS-FF
3141: FF
3142: shadow register
3143: memory circuit
3143B: memory circuit
3188: inverter circuit
3189: inverter circuit
4010: arithmetic portion
4011: analog arithmetic circuit
4012: DOSRAM
4013: NOSRAM
4014: FPGA
4020: control portion
4021: CPU
4022: GPU
4023: PLL
4025: PROM
4026: memory controller
4027: power supply circuit
4028: PMU
4030: input/output portion
4031: external memory control circuit
4032: audio codec
4033: video codec
4034: general-purpose input/output module
4035: communication module
4041: AI system
4041_n: AI system
4041_1: AI system
4041A: AI system
4041B: AI system
4098: bus line
4099: network
7000: AI system IC
7001: lead
7003: circuit portion
7031: Si transistor layer
7032: wiring layer
7033: OS transistor layer

1. A semiconductor device comprising:
an oxide semiconductor comprising a first region, a second region, a third region adjacent to the first region and the second region, and a fourth region adjacent to the second region;
a first insulator over the oxide semiconductor;
a first conductor over the first insulator;
a second insulator over the oxide semiconductor, the first insulator, and the first conductor;
a third insulator facing a side surface of the first insulator and a side surface of the first conductor with the second insulator therebetween;
a fourth insulator over the second insulator and the third insulator; and
a second conductor in contact with the oxide semiconductor,
wherein the first region overlaps with the fourth insulator with the first insulator and the first conductor therebetween,
wherein the second region overlaps with the fourth insulator with the second insulator therebetween,
wherein the third region overlaps with the fourth insulator with the second insulator and the third insulator therebetween,
wherein the fourth region overlaps with the second conductor,
wherein the second insulator contains a metal oxide,
wherein in the second insulator, a film thickness in a region overlapping with the second region is smaller than a film thickness in a region overlapping with the third region, and
wherein the fourth insulator is a film containing hydrogen or nitrogen.

2. The semiconductor device according to claim 1, wherein the second insulator contains aluminum oxide.

3. The semiconductor device according to claim 1, wherein the fourth insulator contains silicon nitride.

4. The semiconductor device according to claim 1,
wherein the film thickness of the second insulator in the region overlapping with the third region is greater than or equal to 3.0 nm, and
wherein the film thickness of the second insulator in the region overlapping with the second region is less than or equal to 3.0 nm.

5. A semiconductor device comprising:
a first transistor comprising a first oxide semiconductor comprising a first region, a second region, a third region adjacent to the first region and the second region, and a fourth region adjacent to the second region, a first insulator over the first oxide semiconductor, and a first conductor over the first insulator;
a second transistor comprising a second oxide semiconductor comprising a fifth region, a sixth region, a seventh region adjacent to the fifth region and the sixth region, and an eighth region adjacent to the sixth region, a second insulator overlapping with the fifth region, and a second conductor over the second insulator;
a third insulator over the first oxide semiconductor, the second oxide semiconductor, the first insulator, the second insulator, the first conductor, and the second conductor;
a fourth insulator facing a side surface of the first insulator and a side surface of the first conductor with the third insulator therebetween;
a fifth insulator facing a side surface of the second insulator and a side surface of the second conductor with the third insulator therebetween; and
a sixth insulator over the third insulator, the fourth insulator, and the fifth insulator,
wherein the first region overlaps with the third insulator with the first insulator and the first conductor therebetween,
wherein the second region and the sixth region overlap with the sixth insulator with the third insulator therebetween,
wherein the third region overlaps with the sixth insulator with the third insulator and the fourth insulator therebetween,
wherein the seventh region overlaps with the sixth insulator with the third insulator and the fifth insulator therebetween,
wherein the fourth region is in contact with a third conductor,
wherein the eighth region is in contact with a fourth conductor,
wherein the fifth region comprises a single-layer region,
wherein the third insulator contains a metal oxide,
wherein in the third insulator, a film thickness in a region overlapping with the second region and the sixth region is smaller than a film thickness in a region overlapping with the third region and the seventh region, and
wherein the sixth insulator is a film containing hydrogen or nitrogen.

6. The semiconductor device according to claim 5, wherein the third insulator contains aluminum oxide.

7. The semiconductor device according to claim 5, wherein the sixth insulator contains silicon nitride.

8. The semiconductor device according to claim 5,
wherein the film thickness of the third insulator in the region overlapping with the third region and the seventh region is greater than or equal to 3.0 nm, and
wherein the film thickness of the third insulator in the region overlapping with the second region and the sixth region is less than or equal to 3.0 nm.
